(19) United States
(12) Patent Application Publication
(10) Pub. No.: US 2024/0036468 A1
(43) Pub. Date: Feb. 1, 2024

(54) RESIST COMPOSITION AND METHOD FOR FORMING RESIST PATTERN

(71) Applicant: TOKYO OHKA KOGYO CO., LTD., Kawasaki-shi (JP)

(72) Inventors: Fumitake Hirayama, Kawasaki-shi (JP); Tomoyuki Hirano, Kawasaki-shi (JP); Yuzo Yoshida, Kawasaki-shi (JP); Shinichi Kohno, Kawasaki-shi (JP); Yusuke Nakagawa, Kawasaki-shi (JP)

(21) Appl. No.: 18/256,899

(22) PCT Filed: Dec. 24, 2021
(86) PCT No.: PCT/JP2021/048250

§ 371 Date: Jun. 9, 2023

(30) Foreign Application Priority Data
Dec. 28, 2020 (JP) 2020-218654

(51) Int. Cl. G03F 7/039; G03F 7/004

(52) U.S. Cl. CPC G03F 7/039; G03F 7/0045

(57) ABSTRACT

A resist composition containing a resin component having a constitutional unit containing a phenolic hydroxyl group and a compound represented by General Formula (b0-1), in which the proportion of the constitutional unit in the resin component is more than 5% by mole and less than 45% by mole with respect to the total (100% by mole) of all constitutional units constituting the resin component. In the formula, R^{b1} represents a hydrocarbon group having 1 or more and 30 or less carbon atoms, n and m represents an integer in a range of 0 to 3, R^{a1} and R^{a2} represents a hydrogen atom or an organic group, Q¹ and Q² represent a fluorine atom or a perfluoroalkyl group having 1 or more and 6 or less carbon atoms, and L represents an ester bond

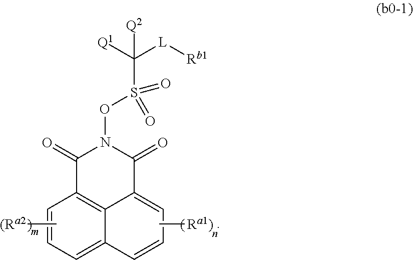

### TECHNICAL FIELD

The present invention relates to a resist composition and a method for forming a resist pattern.

Priority is claimed on Japanese Patent Application No. 2020-218654, filed on Dec. 28, 2020, the content of which is incorporated herein by reference.

### BACKGROUND ART

In lithography techniques, steps in which, for example, a resist film formed of a resist material is formed on a substrate, and the resist film is subjected to selective exposure, followed by a developing treatment, thereby forming a resist pattern having a predetermined shape on the resist film, are carried out. A resist material in which exposed portions of the resist film become soluble in a developing solution is called positive-tone, and a resist material in which exposed portions of the resist film become insoluble in a developing solution is called negative-tone.

In recent years, in the production of semiconductor elements and liquid crystal display elements, with advances in lithography techniques, rapid progress in the field of pattern fining has been achieved. Typically, pattern fining techniques involve shortening the wavelength (increasing the energy) of the light source for exposure. Specifically, ultraviolet rays represented by a g-line and an i-line have been used in the related art; however, nowadays KrF excimer laser light and ArF excimer laser light are used in mass production of semiconductor elements. In addition, studies are also being carried out on an extreme ultraviolet ray (EUV), an electron beam (EB), an X-ray, and the like, which have a wavelength shorter (energy higher) than these excimer laser light.

Resist materials have been required to have lithography characteristics such as sensitivity to these light sources for exposure and resolution capable of reproducing a fine-sized pattern.

As a resist material that satisfies these requirements, a chemical amplification-type resist composition that contains a base material component that exhibits changed solubility in a developing solution under action of acid, and an acid generator component that generates acid upon exposure has been conventionally used in the related art.

For example, in a case where the developing solution is an alkali developing solution (alkali developing process), as a positive-tone chemical amplification-type resist composition, a composition which contains a resin component (a base resin) exhibiting increased solubility in an alkali developing solution under action of acid and an acid generator component has been typically used. In a case where a resist film formed using such a resist composition is selectively exposed at the time of resist pattern formation, in exposed portions, acid is generated from the acid generator component, and the polarity of the base resin increases under the action of the generated acid, thereby making exposed portions of the resist film soluble in the alkali developing solution. Accordingly, a positive-tone pattern in which unexposed portions of the resist film remain as a pattern is formed by performing alkali development.

On the other hand, in a case where such a chemical amplification-type resist composition is applied to a solvent developing process using a developing solution containing an organic solvent (organic developing solution), since the solubility in an organic developing solution is relatively decreased at the time of an increase in the polarity of the base resin, the unexposed portions of the resist film is dissolved and removed by the organic developing solution, and a negative-tone resist pattern in which exposed portions of the resist film remain as a pattern is formed. Such a solvent developing process for forming a negative-tone resist pattern is also referred to as a “negative-tone developing process”.

In recent years, photofabrication has become the mainstream of precision microfabrication technology. The photofabrication refers to a processing technology in which the chemical amplification-type resist composition is applied onto the surface of a processing object to form a resist film, a resist pattern having a predetermined shape is formed on the resist film, and using this as a mask, electroforming or the like which is mainly based on chemical etching, electrolytic etching, or electroplating is carried out to manufacture various precision parts.

In such photofabrication, a thick resist film having, for example, a film thickness of the order of microns may be formed on the surface of the processing object to form a thick resist pattern, and etching or the like may be carried out, depending on the use application. For example, in the development of a three-dimensional structure device (three-dimensional NAND), an attempt has been made to increase memory capacity by vertically stacking several tens of layers of cells fabricated using a thick-film resist pattern.

Patent Document 1 describes a resist composition for forming a thick-film resist pattern, which contains a base material component having a constitutional unit derived from hydroxystyrene, an acid generator, and a dissolution inhibitor.

### CITATION LIST

### Patent Document

### [Patent Document 1]

Japanese Unexamined Patent Application, First Publication No. 2020-86439

### SUMMARY OF INVENTION

### Technical Problem

A thick-film resist pattern is required to have both moderate etching resistance for improving throughput and the critical dimension uniformity (CDU) of the pattern size.

In a resist for a thick film, it is known that the throughput at the time of etching is improved by reducing the ratio of a constitutional unit derived from hydroxystyrene in a base material component. However, in a case where the ratio of a constitutional unit derived from hydroxystyrene in the base material component is reduced, the Tg of the base material component is decreased, which results in a problem of CDU decrease.

The present invention has been made in consideration of the above circumstances, and an object of the present invention is to provide a resist composition having good throughput at the time of etching and good CDU, and a method for forming a resist pattern using the resist composition.

### Solution to Problem

In order to achieve the above-described object, the present invention employs the following configurations.

That is, a first aspect according to the present invention is a resist composition that generates acid upon exposure and exhibits changed solubility in a developing solution under action of acid, the resist composition containing a resin component (A1) exhibiting changed solubility in a developing solution under action of acid and an acid generator component (B) generating an acid upon exposure, in which the resin component (A1) has a constitutional unit (a10) represented by General Formula (a10-1), the acid generator component (B) contains a compound (B0) represented by General Formula (b0-1), and a proportion of the constitutional unit (a10) in the resin component (A1) is more than 5% by mole and less than 45% by mole with respect to the total (100% by mole) of all constitutional units constituting the resin component (A1).

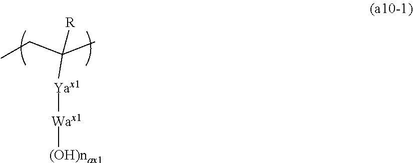

[In the formula, R represents a hydrogen atom, an alkyl group having 1 to 5 carbon atoms, or a halogenated alkyl group having 1 to 5 carbon atoms. Ya^{x1} represents a single bond or a divalent linking group. Wa^{x1} represents an aromatic hydrocarbon group which may have a substituent. nₐₓ₁ represents an integer of 1 or more.]

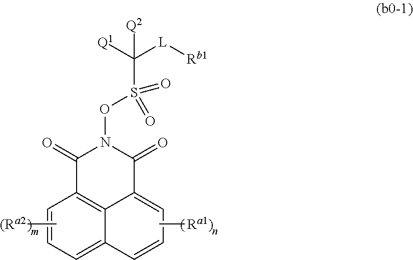

[In the formula, R^{b1} represents a hydrocarbon group having 1 or more and 30 or less carbon atoms; in a case where the hydrocarbon group as R^{b1} contains one or more methylene groups, at least part of the methylene groups may be substituted with a group selected from the group consisting of —O—, —S—, —CO—, —OO—O—, —SO—, —SO₂—, —CR^{b4}R^{b5}—, and —NR^{b6}—; in a case where the hydrocarbon group as R^{b1} contains a hydrocarbon ring, at least one of carbon atoms constituting the hydrocarbon ring may be substituted with a hetero atom selected from the group consisting of N, O, P, S, and Se, or an atomic group containing the hetero atom; R^{b4} and R^{b5} each independently represent a hydrogen atom or a halogen atom, at least one of R^{b4} and R^{b5} represents a halogen atom, and R^{b6} represents a hydrogen atom or a hydrocarbon group having 1 or more and 6 or less carbon atoms; n and m of (R^{a1})n and (R^{a2})m represent an integer in a range of 0 to 3, R^{a1} and R^{a2} each independently represent a hydrogen atom or an organic group; Q¹ and Q² each independently represent a fluorine atom or a perfluoroalkyl group having 1 or more and 6 or less carbon atoms; and L represents an ester bond.]

The second aspect according to the present invention is a method for forming a resist pattern, including a step of forming a resist film on a support using the resist composition according to the first aspect, a step of exposing the resist film, and a step of developing the exposed resist film to form a resist pattern.

### Advantageous Effects of Invention

According to the present invention, it is possible to provide a resist composition having good throughput at the time of etching and good CDU, and a method for forming a resist pattern using the resist composition.

### DESCRIPTION OF EMBODIMENTS

In the present specification and the scope of the present patent claims, the term “aliphatic” is a relative concept used with respect to the term “aromatic” and defines a group or compound that has no aromaticity.

The “alkyl group” includes a monovalent saturated hydrocarbon group that is linear, branched, or cyclic, unless otherwise specified. The same applies to the alkyl group of the alkoxy group.

The “alkylene group” includes a divalent saturated hydrocarbon group that is linear, branched, or cyclic, unless otherwise specified.

Examples of the “halogen atom” include a fluorine atom, a chlorine atom, a bromine atom, and an iodine atom.

The term “constitutional unit” means a monomer unit (monomeric unit) that constitutes a polymeric compound (a resin, a polymer, or a copolymer).

In a case where “may have a substituent” is described, both of a case where a hydrogen atom (—H) is substituted with a monovalent group and a case where a methylene group (—CH₂—) is substituted with a divalent group are included.

The “exposure” is used as a general concept that includes irradiation with any form of radiation.

The “acid decomposable group” indicates a group having an acid decomposability, in which at least parts of bonds in the structure of the acid decomposable group can be cleaved under action of acid.

Examples of the acid decomposable group having a polarity that is increased under action of acid include groups which is decomposed under action of acid to generate a polar group.

Examples of the polar group include a carboxy group, a hydroxyl group, an amino group, and a sulfo group (—SO₃H).

More specific examples of the acid decomposable group include a group obtained by protecting the above-described polar group with an acid dissociable group (for example, a group obtained by protecting a hydrogen atom of the OH-containing polar group with an acid dissociable group).

The “acid dissociable group” indicates both (i) a group having an acid dissociability, in which a bond between the acid dissociable group and an atom adjacent to the acid dissociable group can be cleaved under action of acid; and (ii) a group in which some bonds are cleaved under action of acid, and then a decarboxylation reaction occurs, thereby cleaving the bond between the acid dissociable group and the atom adjacent to the acid dissociable group.

It is necessary that the acid dissociable group that constitutes the acid decomposable group be a group that exhibits a lower polarity than the polar group generated by the dissociation of the acid dissociable group. Thus, in a case where the acid dissociable group is dissociated under action of acid, a polar group that exhibits a higher polarity than the acid dissociable group is generated, thereby increasing the polarity. As a result of the above, the polarity of the entire component (A1) is increased. By the increase in the polarity, the solubility in a developing solution relatively changes. The solubility is increased in a case where the developing solution is an alkali developing solution, whereas the solubility is decreased in a case where the developing solution is an organic developing solution.

The “base material component” is an organic compound having a film-forming ability. The organic compounds used as the base material component are roughly classified into a non-polymer and a polymer. As the non-polymer, those having a molecular weight of 500 or more and less than 4,000 are usually used. Hereinafter, a “low molecular weight compound” refers to a non-polymer having a molecular weight of 500 or more and less than 4,000. As the polymer, those having a molecular weight of 1,000 or more are usually used. Hereinafter, a “resin”, a “polymeric compound”, or a “polymer” refers to a polymer having a molecular weight of 1,000 or more. As the molecular weight of the polymer, a polystyrene-equivalent mass average molecular weight determined by gel permeation chromatography (GPC) is used.

The “constitutional unit derived from” means a constitutional unit that is formed by the cleavage of a multiple bond between carbon atoms, for example, an ethylenic double bond.

In the “acrylic acid ester”, the hydrogen atom bonded to the carbon atom at the α-position may be substituted with a substituent. The substituent (R″x) that is substituted for the hydrogen atom bonded to the carbon atom at the α-position is an atom other than a hydrogen atom or a group. Further, itaconic acid diester in which the substituent (R″) is substituted with a substituent having an ester bond or an α-hydroxyacryl ester in which the substituent (R^{αx}) is substituted with a hydroxyalkyl group or a group in which a hydroxyl group thereof is modified can be mentioned as an acrylic acid ester. A carbon atom at the α-position of acrylic acid ester indicates the carbon atom bonded to the carbonyl group of acrylic acid, unless otherwise specified.

Hereinafter, an acrylic acid ester in which the hydrogen atom bonded to the carbon atom at the α-position is substituted with a substituent is also referred to as the α-substituted acrylic acid ester”.

The “derivative” includes those in which the hydrogen atom at the α-position of an object compound has been substituted with other substituents such as an alkyl group and a halogenated alkyl group; and derivatives thereof. Examples of the derivatives thereof include a derivative in which the hydrogen atom of the hydroxyl group of the object compound in which the hydrogen atom at the α-position may be substituted with a substituent is substituted with an organic group; and a derivative in which a substituent other than a hydroxyl group is bonded to the object compound in which the hydrogen atom at the α-position may be substituted with a substituent. The α-position refers to the first carbon atom adjacent to the functional group unless otherwise specified.

Examples of the substituent that is substituted for the hydrogen atom at the α-position of hydroxystyrene include the same one as R^{αx}.

In the present specification and the scope of the present patent claims, asymmetric carbon atoms may be present or enantiomers or diastereomers may be present depending on the structure represented by the chemical formula. In that case, these isomers are represented by one chemical formula. These isomers may be used alone or in the form of a mixture.

(Resist Composition)

The resist composition according to the first aspect according to the present invention contains a resin component (A1) having a constitutional unit (a10) represented by General Formula (a10-1) (hereinafter, also referred to as a “component (A1)”) and an acid generator (B) (hereinafter, also referred to as a “component (B)”). In the resist composition according to the present embodiment, the component (B) includes a compound (B0) represented by General Formula (b0-1). In addition, in the resist composition according to the present embodiment, the proportion of the constitutional unit (a10) in the component (A1) is more than 5% by mole and less than 45% by mole with respect to the total (100% by mole) of all constitutional units constituting the component (A1).

The resist composition according to the present embodiment is suitable for resist pattern formation that is carried out by exposure using exposure light sources of ultraviolet rays such as a g-line and an i-line, KrF excimer laser, and the like.

In addition, the resist composition according to the present embodiment is suitable for forming, on a support, a resist film having a thickness of, for example, 1 to 20 μm, and in particular, it is suitable for forming a resist pattern by forming a thick resist film. A thick film referred to here means a film having a thickness of 1 μm or more. The resist composition according to the present embodiment is suitable for forming a resist film having a thickness preferably in a range of 3 μm or more, and within this range, more preferably a thickness of 3.5 μm or more and still more preferably a thickness of 5 μm or more.

In a case where a resist film is formed using such a resist composition and the formed resist film is subjected to selective exposure, acid is generated at exposed portions of the resist film, and the generated acid acts on the component (A) so that the component (A) exhibits changed solubility in a developing solution, whereas the component (A) does not exhibit changed solubility in a developing solution at the unexposed portions of the resist film, thereby generating the difference in solubility in the developing solution between exposed portions and the unexposed portions of the resist film. Therefore, by subjecting the resist film to development, exposed portions of the resist film are dissolved and removed to form a positive-tone resist pattern in a case where the resist composition is a positive-tone type, whereas unexposed portions of the resist film are dissolved and removed to form a negative-tone resist pattern in a case where the resist composition is a negative-tone type.

In the present specification, a resist composition which forms a positive-tone resist pattern by dissolving and removing exposed portions of the resist film is called a positive-tone resist composition, and a resist composition which forms a negative-tone resist pattern by dissolving and removing unexposed portions of the resist film is called a negative-tone resist composition. The resist composition according to the present embodiment may be a positive-tone resist composition or a negative-tone resist composition. Further, in the resist pattern formation, the resist composition according to the present embodiment may be applied to an alkali developing process using an alkali developing solution in the developing treatment, or a solvent developing process using a developing solution containing an organic solvent (organic developing solution) in the developing treatment.

<Component (A)>

The component (A) is a base material component that exhibits changed solubility in a developing solution under action of acid.

In the present invention, the “base material component” is an organic compound having a film-forming ability, and an organic compound having a molecular weight of 500 or more is preferably used. In a case where the molecular weight of the organic compound is 500 or more, the film-forming ability is improved, and in addition, a nano-level resist pattern is easily formed.

The organic compounds used as the base material component are roughly classified into a non-polymer and a polymer.

As the non-polymer, those having a molecular weight of 500 or more and less than 4,000 are usually used. Hereinafter, a “low molecular weight compound” refers to a non-polymer having a molecular weight of 500 or more and less than 4,000.

As the polymer, those having a molecular weight of 1,000 or more are usually used. Hereinafter, a “resin”, a “polymeric compound”, or a “polymer” refers to a polymer having a molecular weight of 1,000 or more.

As the molecular weight of the polymer, a weight average molecular weight in terms of the polystyrene equivalent value determined by gel permeation chromatography (GPC) is used.

In the resist composition according to the present embodiment, at least the polymeric compound (A1) having the constitutional unit (a10) represented by General Formula (a0-1) is used in the component (A), and a polymeric compound and/or a low molecular weight compound other than the component (A1) may be further used in combination.

That is, in a case where the resist composition according to the present embodiment is a “positive-tone resist composition for an alkali developing process” that forms a positive-tone resist pattern in an alkali developing process or a “negative-tone resist composition for a solvent developing process” that forms a negative-tone resist pattern in a solvent developing process, a base material component (A-1) (hereinafter referred to as a “component (A-1)”) having a polarity that is increased under action of acid is preferably used as the component (A). In the alkali developing process and the solvent developing process, since the polarity of the base material component before and after the exposure is changed by using the component (A-1), an excellent development contrast between exposed portions and unexposed portions can be obtained.

In a case of applying an alkali developing process, the component (A-1) is insoluble in an alkali developing solution prior to exposure; however, it has a polarity that is increased under action of acid and then exhibits increased solubility in an alkali developing solution, for example, in a case where acid is generated from the component (B) upon exposure. Therefore, in the resist pattern formation, in a case where a resist film formed by applying the resist composition onto a support is subjected to the selective exposure, exposed portions of the resist film change from an insoluble state to a soluble state in an alkali developing solution, whereas unexposed portions of the resist film remain insoluble in an alkali developing solution, and thus, a positive-tone resist pattern is formed by alkali developing.

On the other hand, in a case of applying a solvent developing process, the component (A-1) has a high solubility in an organic developing solution prior to exposure; however, it has an increased polarity under action of acid and then exhibits decreased solubility in an organic developing solution in a case where acid is generated from the component (B) upon exposure. Therefore, in the resist pattern formation, by carrying out selective exposure of a resist film formed by applying the resist composition onto a support, exposed portions of the resist film change from a soluble state to an insoluble state in an organic developing solution, whereas unexposed portions of the resist film remain soluble and do not change, thereby a contrast between exposed portions and unexposed portions can be obtained, and thus a negative-tone resist pattern is formed by developing in the organic developing solution.

That is, in a case where the resist composition according to the present embodiment is a “negative-tone resist composition for an alkali developing process” that forms a negative-tone resist pattern in an alkali developing process or a “positive-tone resist composition for a solvent developing process” that forms a positive-tone resist pattern in a solvent developing process, a base material component (A-2) soluble in an alkali developing solution (hereinafter referred to as a “component (A-2)”) is preferably used as the component (A), and a crosslinking agent component is further blended. In the resist composition, in a case where acid is generated from the component (B) upon exposure, the acid acts to cause crosslinking between the component (A-2) and a crosslinking agent component, and as a result, the solubility in an alkali developing solution is decreased (the solubility in an organic developing solution is increased). Therefore, in the resist pattern formation, by conducting selective exposure of a resist film formed by applying the resist composition to a support, the exposed portions of the resist film change to an insoluble state in an alkali developing solution (a soluble state in an organic developing solution), whereas the unexposed portions of the resist film remain soluble in an alkali developing solution (an insoluble state in an organic developing solution), and thus a negative-tone resist pattern is formed by carrying out development with the alkali developing solution. Further, in this case, a positive-tone resist pattern is formed by developing with the organic developing solution.

As the component (A-2), a resin soluble in an alkali developing solution (hereinafter, referred to as “alkali-soluble resin”) is preferably used.

From the viewpoint that a good resist pattern with less swelling can be formed, the alkali-soluble resins is preferably, for example, a resin having a constitutional unit derived from at least one selected from an α-(hydroxyalkyl) acrylic acid or an alkyl ester of an α-(hydroxyalkyl) acrylic acid (preferably an alkyl ester having 1 to 5 carbon atoms) disclosed in Japanese Unexamined Patent Application, First Publication No. 2000-206694; an acrylic resin or polycycloolefin resin in which a hydrogen atom bonded to a carbon atom at an α-position having a sulfonamide group may be substituted with a substituent disclosed in U.S. Pat. No. 6,949,325; an acrylic resin containing a fluorinated alcohol, in which a hydrogen atom bonded to a carbon atom at an α-position may be substituted with a substituent disclosed in U.S. Pat. No. 6,949,325, Japanese Unexamined Patent Application, First Publication No. 2005-336452, and Japanese Unexamined Patent Application, First Publication No. 2006-317803; or a polycycloolefin resin containing a fluorinated alcohol disclosed in Japanese Unexamined Patent Application, First Publication No. 2006-259582.

The α-(hydroxyalkyl) acrylic acid refers to one or both of an acrylic acid in which a hydrogen atom is bonded to the carbon atom at the α-position to which a carboxy group is bonded or an α-hydroxyalkyl acrylic acid in which a hydroxyalkyl group (preferably a hydroxyalkyl group having 1 to 5 carbon atoms) is bonded to the carbon atom the α-position, among acrylic acids in which a hydrogen atom bonded to the carbon atom at the α-position may be substituted with a substituent.

As the crosslinking agent component, for example, an amine-based crosslinking agent such as a glycoluril having a methylol group or an alkoxymethyl group, or a melamine-based crosslinking agent is preferably used since a good resist pattern with less swelling is easily formed. The blending amount of the crosslinking agent component is preferably 1 to 50 parts by mass with respect to 100 parts by mass of the alkali-soluble resin.

In the resist composition according to the present embodiment, the component (A) may be used alone or in a combination of two or more kinds thereof.

In the resist composition according to the present embodiment, the component (A) is preferably the component (A-1). That is, the resist composition according to the present embodiment is preferably a “positive-tone resist composition for an alkali developing process” that forms a positive-tone resist pattern in an alkali developing process or a “negative-tone resist composition for a solvent developing process” that forms a negative-tone resist pattern in a solvent developing process. As the component (A), at least one of a polymeric compound or a low molecular weight compound can be used.
In regard to component (A1)

The component (A1) is a polymeric compound having a constitutional unit (a10) represented by General Formula (a10-1).

The component (A1) is preferably a copolymer further having, in addition to the constitutional unit (a10), a constitutional unit (a11) containing an aromatic ring (excluding an aromatic ring to which a hydroxy group is bonded) in the side chain.

In addition, the component (A1) may have a constitutional unit other than the constitutional unit (a10) and the constitutional unit (a11).

In regard to constitutional unit (a10):

The constitutional unit (a10) is a constitutional unit represented by General Formula (a10-1).

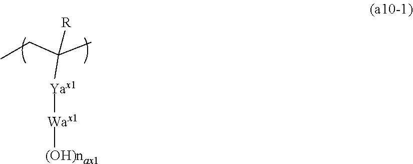

[In the formula, R represents a hydrogen atom, an alkyl group having 1 to 5 carbon atoms, or a halogenated alkyl group having 1 to 5 carbon atoms. Ya^{x1} represents a single bond or a divalent linking group. Wa^{x1} represents an aromatic hydrocarbon group which may have a substituent. nₐₓ₁ represents an integer of 1 or more.]

[In the formula, R represents a hydrogen atom, an alkyl group having 1 to 5 carbon atoms, or a halogenated alkyl group having 1 to 5 carbon atoms. Ya^{x1} represents a single bond or a divalent linking group. Wad represents an aromatic hydrocarbon group which may have a substituent. nₐₓ₁ represents an integer of 1 or more.]

In General Formula (a10-1), R represents a hydrogen atom, an alkyl group having 1 to 5 carbon atoms, or a halogenated alkyl group having 1 to 5 carbon atoms.

The alkyl group having 1 to 5 carbon atoms as R is preferably a linear or branched alkyl group having 1 to 5 carbon atoms, and specific examples thereof include a methyl group, an ethyl group, a propyl group, an isopropyl group, an n-butyl group, an isobutyl group, a tert-butyl group, a pentyl group, an isopentyl group, and a neopentyl group.

The halogenated alkyl group having 1 to 5 carbon atoms as R is a group obtained by substituting part or all of hydrogen atoms of an above-described alkyl group having 1 to 5 carbon atoms with a halogen atom. The halogen atom is particularly preferably a fluorine atom.

R is preferably a hydrogen atom, an alkyl group having 1 to 5 carbon atoms, or a fluorinated alkyl group having 1 to 5 carbon atoms, and in terms of industrial availability, R is more preferably a hydrogen atom, a methyl group, or trifluoromethyl group, still more preferably a hydrogen atom or a methyl group, and particularly preferably a hydrogen atom.

In General Formula (a10-1), Ya^{x1} represents a single bond or a divalent linking group.

In the chemical formulae described above, the divalent linking group as Ya^{x1} is not particularly limited, and suitable examples thereof include a divalent hydrocarbon group which may have a substituent, and a divalent linking group having hetero atoms.
Divalent hydrocarbon group which may have substituent:

In a case where Ya^{x1} represents a divalent hydrocarbon group which may have a substituent, the hydrocarbon group may be an aliphatic hydrocarbon group or an aromatic hydrocarbon group.
Aliphatic hydrocarbon group as Ya^{x1}

The aliphatic hydrocarbon group indicates a hydrocarbon group that has no aromaticity. The aliphatic hydrocarbon group may be saturated or unsaturated. In general, it is preferable that the aliphatic hydrocarbon group is saturated.

Examples of the aliphatic hydrocarbon group include a linear or branched aliphatic hydrocarbon group, and an aliphatic hydrocarbon group containing a ring in the structure thereof.
Linear or branched aliphatic hydrocarbon group

The linear aliphatic hydrocarbon group preferably has 1 to 10 carbon atoms, more preferably 1 to 6 carbon atoms, still more preferably 1 to 4 carbon atoms, and most preferably 1 to 3 carbon atoms.

The linear aliphatic hydrocarbon group is preferably a linear alkylene group, and specific examples thereof include a methylene group [—CH₂—], an ethylene group [—(CH₂)₂—], a trimethylene group [—(CH₂)₃—], a tetramethylene group [—(CH₂)₄—], and a pentamethylene group [—(CH₂)₅—].

The branched aliphatic hydrocarbon group has preferably 2 to 10 carbon atoms, more preferably 3 to 6 carbon atoms, still more preferably 3 or 4 carbon atoms, and most preferably 3 carbon atoms.

The branched aliphatic hydrocarbon group is preferably a branched alkylene group, and specific examples thereof include alkylalkylene groups, for example, alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)—, and —C(CH₂CH₃)₂—; alkylethylene groups such as —CH(CH₃)CH₂—, —CH(CH₃)CH(CH₃)—, —C(CH₃)₂CH₂—, —CH(CH₂CH₃)CH₂—, and —C(CH₂CH₃)₂—CH₂—; alkyltrimethylene groups such as —CH(CH₃)CH₂CH₂—, and —CH₂CH(CH₃)CH₂—; and alkyltetramethylene groups such as —CH(CH₃)CH₂CH₂CH₂—, and —CH₂CH(CH₃)CH₂CH₂—. The alkyl group in the alkylalkylene group is preferably a linear alkyl group having 1 to 5 carbon atoms.

The linear or branched aliphatic hydrocarbon group may or may not have a substituent. Examples of the substituent include a fluorine atom, a fluorinated alkyl group having 1 to 5 carbon atoms, which has been substituted with a fluorine atom, and a carbonyl group.
Aliphatic hydrocarbon group containing ring in structure thereof

Examples of the aliphatic hydrocarbon group containing a ring in the structure thereof include a cyclic aliphatic hydrocarbon group which may contain a substituent containing a hetero atom in the ring structure thereof (a group obtained by removing two hydrogen atoms from an aliphatic hydrocarbon ring), a group obtained by bonding a cyclic aliphatic hydrocarbon group to the terminal of a linear or branched aliphatic hydrocarbon group, and a group obtained by interposing a cyclic aliphatic hydrocarbon group in a linear or branched aliphatic hydrocarbon group. Examples of the linear or branched aliphatic hydrocarbon group include the same ones as those described above.

The cyclic aliphatic hydrocarbon group preferably has 3 to 20 carbon atoms and more preferably 3 to 12 carbon atoms.

The cyclic aliphatic hydrocarbon group may be a polycyclic group or a monocyclic group. The monocyclic alicyclic hydrocarbon group is preferably a group obtained by removing two hydrogen atoms from a monocycloalkane. The monocycloalkane preferably has 3 to 6 carbon atoms, and specific examples thereof include cyclopentane and cyclohexane. The polycyclic alicyclic hydrocarbon group is preferably a group obtained by removing two hydrogen atoms from a polycycloalkane, and the polycycloalkane is preferably a group having 7 to 12 carbon atoms. Specific examples of the polycyclic alicyclic hydrocarbon group include adamantane, norbornane, isobornane, tricyclodecane, and tetracyclododecane.

The cyclic aliphatic hydrocarbon group may have or may not have a substituent. Examples of the substituent include an alkyl group, an alkoxy group, a halogen atom, a halogenated alkyl group, a hydroxyl group, and a carbonyl group.

The alkyl group as the substituent is preferably an alkyl group having 1 to 5 carbon atoms, and more preferably a methyl group, an ethyl group, a propyl group, an n-butyl group, or a tert-butyl group.

The alkoxy group as the substituent is preferably an alkoxy group having 1 to 5 carbon atoms, more preferably a methoxy group, an ethoxy group, an n-propoxy group, an iso-propoxy group, an n-butoxy group, or a tert-butoxy group, and still more preferably a methoxy group or an ethoxy group.

The halogen atom as the substituent is preferably a fluorine atom.

Examples of the halogenated alkyl group as the substituent include a group obtained by substituting part or all of hydrogen atoms in the above-described alkyl group with the above-described halogen atom.

In the cyclic aliphatic hydrocarbon group, part of carbon atoms constituting the ring structure thereof may be substituted with a substituent containing a hetero atom. The substituent containing a hetero atom is preferably —O—, —C(═O)—O—, —S—, —S(═O)₂—, or —S(═O)₂—O—.
Aromatic hydrocarbon group as Ya^{x1}

The aromatic hydrocarbon group is a hydrocarbon group having at least one aromatic ring.

The aromatic ring is not particularly limited as long as it is a cyclic conjugated system having (4n+2) π electrons, and may be monocyclic or polycyclic. The aromatic ring preferably has 5 to 30 carbon atoms, more preferably 5 to 20 carbon atoms, still more preferably 6 to 15 carbon atoms, and particularly preferably 6 to 12 carbon atoms. However, the number of carbon atoms in the substituent is not included in the number of carbon atoms.

Specific examples of the aromatic ring include aromatic hydrocarbon rings such as benzene, naphthalene, anthracene, and phenanthrene; and an aromatic heterocyclic ring obtained by substituting part of carbon atoms constituting the above-described aromatic hydrocarbon ring with a hetero atom. Examples of the hetero atom in the aromatic heterocyclic rings include an oxygen atom, a sulfur atom, and a nitrogen atom. Specific examples of the aromatic heterocyclic ring include a pyridine ring and a thiophene ring.

Specific examples of the aromatic hydrocarbon group include a group (an arylene group or a heteroarylene group) obtained by removing two hydrogen atoms from the above-described aromatic hydrocarbon ring or the above-described aromatic heterocyclic ring; a group obtained by removing two hydrogen atoms from an aromatic compound having two or more aromatic rings (such as biphenyl or fluorene); and a group (for example, a group obtained by further removing one hydrogen atom from an aryl group in arylalkyl groups such as a benzyl group, a phenethyl group, a 1-naphthylmethyl group, a 2-naphthylmethyl group, a 1-naphthylethyl group, or a 2-naphthylethyl group) obtained by substituting one hydrogen atom of a group (an aryl group or a heteroaryl group) obtained by removing one hydrogen atom from the above aromatic hydrocarbon ring or the above aromatic heterocyclic ring, with an alkylene group. The alkylene group bonded to the aryl group or the heteroaryl group preferably has 1 to 4 carbon atoms, more preferably 1 or 2 carbon atoms, and particularly preferably 1 carbon atom.

With respect to the aromatic hydrocarbon group, the hydrogen atom contained in the aromatic hydrocarbon group may be substituted with a substituent. For example, the hydrogen atom bonded to the aromatic ring in the aromatic hydrocarbon group may be substituted with a substituent. Examples of substituents include an alkyl group, an alkoxy group, a halogen atom, a halogenated alkyl group, and a hydroxyl group.

The alkyl group as the substituent is preferably an alkyl group having 1 to 5 carbon atoms, and more preferably a methyl group, an ethyl group, a propyl group, an n-butyl group, or a tert-butyl group.

Examples of the alkoxy group, the halogen atom, and the halogenated alkyl group, as the substituent, include the same groups as those exemplified as the substituent that is substituted for a hydrogen atom contained in the cyclic aliphatic hydrocarbon group.
Divalent linking group containing hetero atom:

In a case where Ya^{x1} represents a divalent linking group containing a hetero atom, preferred examples of the linking group include —O—, —C(═O)—O—, —O—C(═O)—, —C(═O)—, —O—C(═O)—O—, —C(═O)—NH—, —NH—, —NH—C(═NH)— (H may be substituted with a substituent such as an alkyl group, an acyl group, or the like), —S—, —S(═O)₂—, —S(═O)₂—O—, and a group represented by General Formula —Y²¹—O—Y²², —Y²¹—C(═O)—O—, —C(═O)—O—Y²¹—, —[Y²¹—C(═O)—O]_{m″}—Y²²—, —Y²¹—O—C(═O)—Y²²— or —Y²¹—S(═O)₂—O—Y²²—[in the formulae, Y²¹ and Y²² each independently represent a divalent hydrocarbon group which may have a substituent, O represents an oxygen atom, and m″ represents an integer in a range of 0 to 3].

In a case where the divalent linking group containing a hetero atom is —C(═O)—NH—, —C(═O)—NH—C(═O)—, —NH—, or —NH—C(═NH)—, H may be substituted with a substituent such as an alkyl group, an acyl group, or the like. The substituent (an alkyl group, an acyl group, or the like) preferably has 1 to 10 carbon atoms, more preferably 1 to 8 carbon atoms, and particularly preferably 1 to 5 carbon atoms.

In General Formulae —²¹—O—Y²²—, —Y²¹—O—, Y²¹—C(═O)—O—, —C(═O)—O—Y²¹—, —[Y²¹—C(═O)]_{m″}—Y²²—, —Y²¹—O—C(═O)—Y²²—, and —Y²¹—S(═O)₂—O—Y²²—, Y²¹, and Y²² each independently represent a divalent hydrocarbon group which may have a substituent. Examples of the divalent hydrocarbon group include the same one as “the divalent hydrocarbon groups which may have a substituent”, described in the explanation of the above-described divalent linking group as Ya^{x1}.

Y²¹ is preferably a linear aliphatic hydrocarbon group, more preferably a linear alkylene group, still more preferably a linear alkylene group having 1 to 5 carbon atoms, and particularly preferably a methylene group or an ethylene group.

Y²² is preferably a linear or branched aliphatic hydrocarbon group and more preferably a methylene group, an ethylene group, or an alkylmethylene group. The alkyl group in the alkylmethylene group is preferably a linear alkyl group having 1 to 5 carbon atoms, more preferably a linear alkyl group having 1 to 3 carbon atoms, and most preferably a methyl group.

In the group represented by General Formula —[Y²¹—C(═O)—O]_{m″}—Y²²—, m″ represents an integer in a range of 0 to 3, preferably an integer in a range of 0 to 2, more preferably 0 or 1, and particularly preferably 1. In other words, it is particularly preferable that the group represented by General Formula —[Y²¹—C(═O)—O]₃⁻—Y²²— represents a group represented by General Formula —Y²¹—C(═O)—O—Y²²—. Among these, a group represented by General Formula —(CH₂)_{a′}—C(═O)—O—(CH₂)_{b′}— is preferable. In the formula, a′ represents an integer in a range of 1 to 10, preferably an integer in a range of 1 to 8, more preferably an integer in a range of 1 to 5, still more preferably 1 or 2, and most preferably 1. b′ represents an integer in a range of 1 to 10, preferably an integer in a range of 1 to 8, more preferably an integer in a range of 1 to 5, still more preferably 1 or 2, and most preferably 1.

Among the above, Ya^{x1} is preferably a single bond, an ester bond [—C(═O)—O—, —O—C(═O)—], an ether bond (—O—), a linear or branched alkylene group, or a combination thereof, and more preferably a single bond or an ester bond [—C(═O)—O—, —O—C(═O)—].

In General Formula (a10-1), Wa^{x1} represents an aromatic hydrocarbon group which may have a substituent.

Examples of the aromatic hydrocarbon group as Wa^{x1} include a group obtained by removing (nₐₓ₁+1) hydrogen atoms from an aromatic ring which may have a substituent. Here, the aromatic ring is not particularly limited as long as it is a cyclic conjugated system having (4n+2) π electrons, and may be monocyclic or polycyclic. The aromatic ring preferably has 5 to 30 carbon atoms, more preferably 5 to 20 carbon atoms, still more preferably 6 to 15 carbon atoms, and particularly preferably 6 to 12 carbon atoms. Specific examples of the aromatic ring include aromatic hydrocarbon rings such as benzene, naphthalene, anthracene, and phenanthrene; and aromatic heterocyclic rings obtained by substituting part of carbon atoms constituting the above-described aromatic hydrocarbon ring with a hetero atom. Examples of the hetero atom in the aromatic heterocyclic rings include an oxygen atom, a sulfur atom, and a nitrogen atom. Specific examples of the aromatic heterocyclic ring include a pyridine ring and a thiophene ring.

Examples of the aromatic hydrocarbon group as Wa^{x1} also include a group obtained by removing (nₐₓ₁+1) hydrogen atoms from an aromatic compound including an aromatic ring (for example, biphenyl or fluorene) which may have two or more substituents.

Among the above, Wa^{x1} is preferably a group obtained by removing (nₐₓ₁+1) hydrogen atoms from benzene, naphthalene, anthracene, or biphenyl, more preferably a group obtained by removing (nₐₓ₁+1) hydrogen atoms from benzene or naphthalene, and still more preferably a group obtained by removing (nₐₓ₁+1) hydrogen atoms from benzene.

The aromatic hydrocarbon group as Wa^{x1} may or may not have a substituent. Examples of the substituent include an alkyl group, an alkoxy group, a halogen atom, and a halogenated alkyl group. Examples of the alkyl group, the alkoxy group, the halogen atom, and the halogenated alkyl group, as the substituent, include the same ones as those described as the above-described substituent of the cyclic aliphatic hydrocarbon group as Ya^{x1}. The substituent is preferably a linear or branched alkyl group having 1 to 5 carbon atoms, more preferably a linear or branched alkyl group having 1 to 3 carbon atoms, still more preferably an ethyl group or a methyl group, and particularly preferably a methyl group. The aromatic hydrocarbon group as Wa^{x1} preferably has no substituent.

In General Formula (a10-1), nₐₓ₁ represents an integer of 1 or more, preferably an integer in a range of 1 to 10, more preferably an integer in a range of 1 to 5, still more preferably 1, 2, or 3, and particularly preferably 1 or 2.

Specific examples of the constitutional unit (a10) represented by General Formula (a10-1) are shown below.

In the formulae shown below, Ra represents a hydrogen atom, a methyl group, or a trifluoromethyl group.

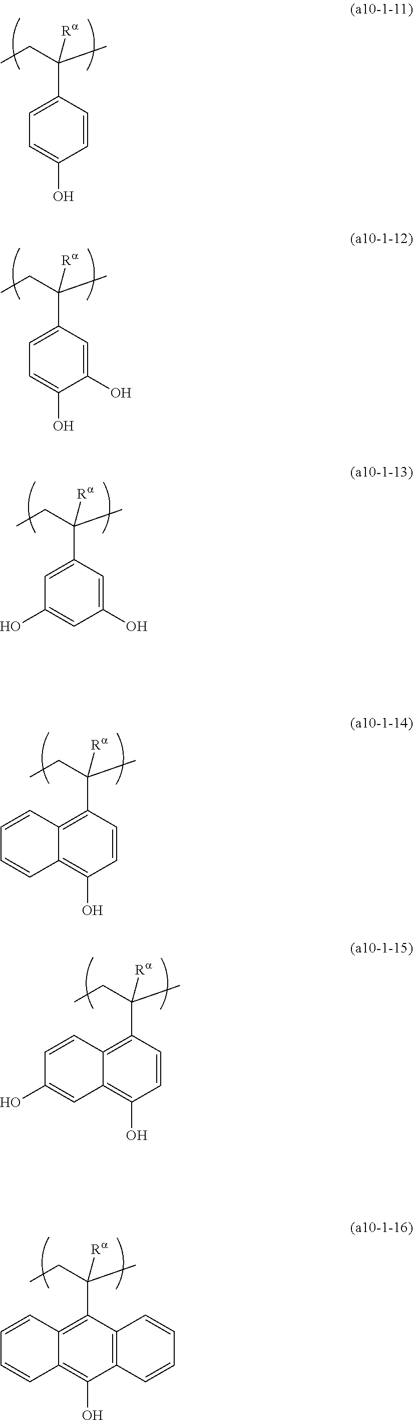

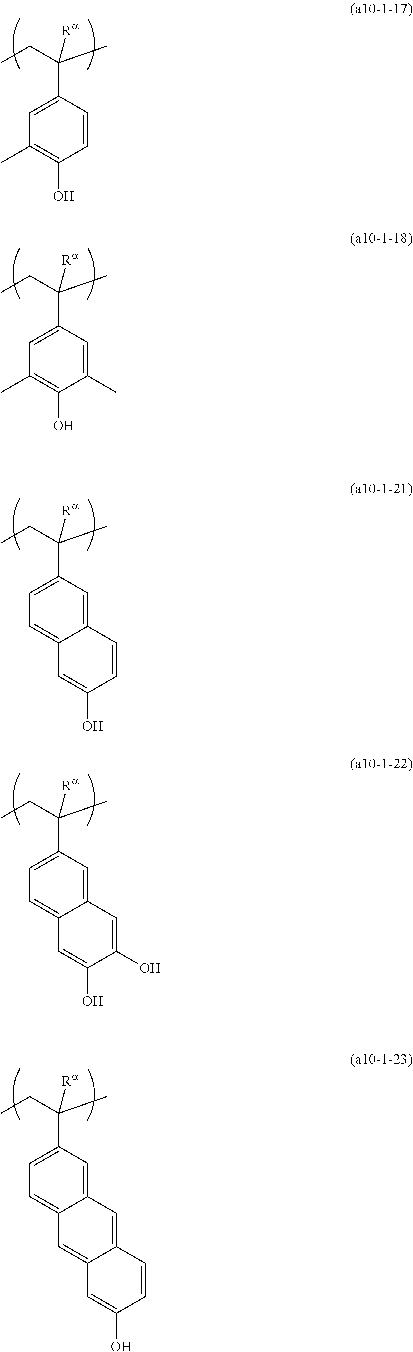

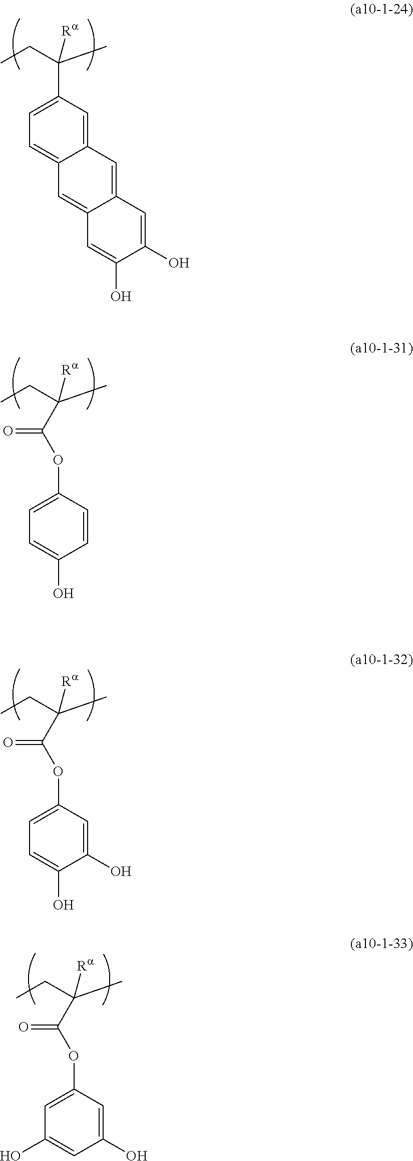

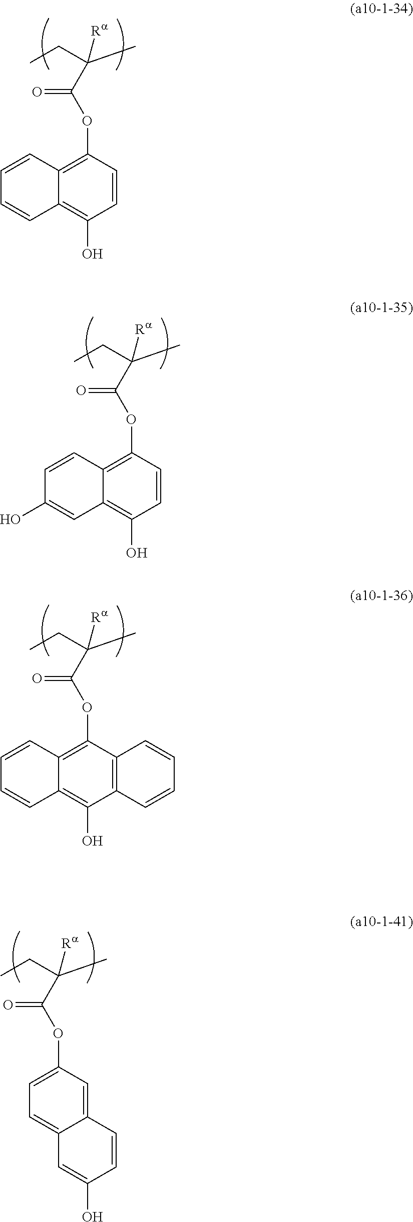

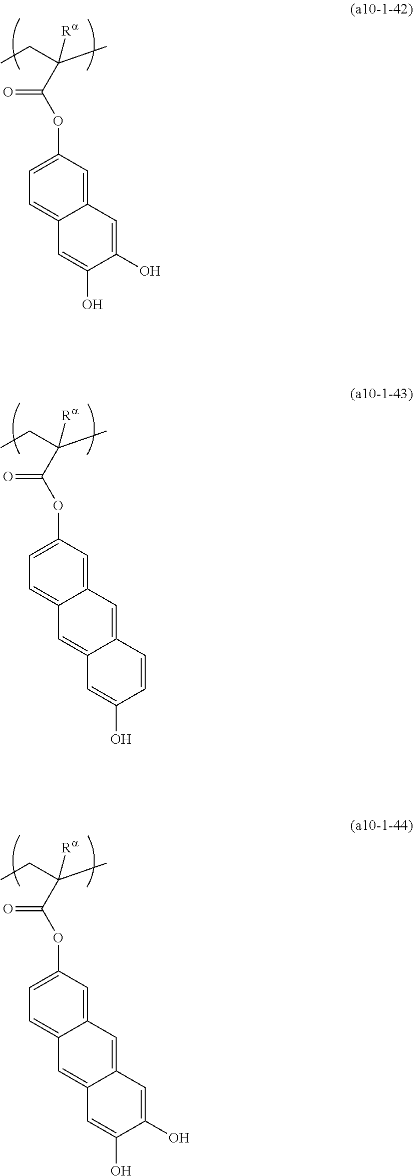

The constitutional unit (a10) contained in the component (A1) may be one kind or may be two or more kinds.

The proportion of the constitutional unit (a10) in the component (A1) is in a range of more than 5% by mole and less than 45% by mole, preferably in a range of 6% to 44% by mole, more preferably in a range of 7% to 43% by mole, still more preferably in a range of 8% to 42% by mole, and particularly preferably in a range of 9% to 41% by mole, with respect to the total (100% by mole) of all constitutional units constituting the component (A1).

In a case where the proportion of the constitutional unit (a10) is set to be more than 5% by mole, development characteristics and lithography characteristics such as CDU are improved. On the other hand, in a case where the proportion of the constitutional unit (a10) is set to be less than 45% by mole, the throughput at the time of etching is improved, and the balance with other constitutional units is obtained easily.

In a case where the proportion of the constitutional unit (a10) is set to be equal to or larger than the lower limit value of the preferred range described above, lithography characteristics such as development characteristics and CDU are further improved. On the other hand, in a case where the proportion of the constitutional unit (a10) is set to be equal to or smaller than the upper limit value of the above-described preferred range, the throughput at the time of etching is improved easily, and the balance with other constitutional units is obtained easily.

«Constitutional Unit (a1)»

In the present embodiment, the component (A1) preferably contains a constitutional unit (a1) containing an acid decomposable group having a polarity that is increased under action of acid.

The “acid decomposable group” indicates a group having an acid decomposability, in which at least parts of bonds in the structure of the acid decomposable group can be cleaved under action of acid.

Examples of the acid decomposable group having a polarity that is increased under action of acid include groups which are decomposed under action of acid to generate a polar group.

Examples of the polar group include a carboxy group, a hydroxyl group, an amino group, and a sulfo group (—SO₃H). Among these, a polar group containing —OH in the structure thereof (hereinafter, also referred to as an “OH-containing polar group”) is preferable, a carboxy group or a hydroxyl group is more preferable, and a carboxy group is particularly preferable.

More specific examples of the acid decomposable group include a group (for example, a group obtained by protecting a hydrogen atom of the OH-containing polar group with an acid dissociable group) obtained by protecting the above-described polar group with an acid dissociable group.

Here, the “acid dissociable group” indicates any one of (i) a group having an acid dissociability, in which a bond between the acid dissociable group and an atom adjacent to the acid dissociable group can be cleaved under action of acid; and (ii) a group in which part of bonds are cleaved under action of acid, and then a decarboxylation reaction occurs, thereby cleaving the bond between the acid dissociable group and the atom adjacent to the acid dissociable group.

It is necessary that the acid dissociable group that constitutes the acid decomposable group be a group that exhibits a lower polarity than the polar group generated by the dissociation of the acid dissociable group. Thus, in a case where the acid dissociable group is dissociated under action of acid, a polar group that exhibits a higher polarity than the acid dissociable group is generated, thereby increasing the polarity. As a result of the above, the polarity of the entire component (A1) is increased. By the increase in the polarity, the solubility in a developing solution relatively changes. The solubility is increased in a case where the developing solution is an alkali developing solution, whereas the solubility is decreased in a case where the developing solution is an organic developing solution.

Examples of the acid dissociable group include those which have been proposed so far as acid dissociable groups for the base resin for a chemical amplification-type resist composition.

Specific examples of the acid dissociable group of the base resin proposed for a chemical amplification-type resist composition include an “acetal-type acid dissociable group”, a “tertiary alkyl ester-type acid dissociable group”, and a “tertiary alkyloxycarbonyl acid dissociable group”, which will be described below.

Acetal-type acid dissociable group:

Examples of the acid dissociable group for protecting a carboxy group or a hydroxyl group as a polar group include the acid dissociable group represented by General Formula (a1-r-1) shown below (hereinafter, also referred to as an “acetal-type acid dissociable group”).

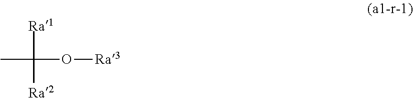

[In the formula, Ra′¹ and Ra′² represent a hydrogen atom or an alkyl group. Ra′³ represents a hydrocarbon group, and Ra′³ may be bonded to Ra′¹ or Ra′² to form a ring.]

In General Formula (a1-r-1), it is preferable that at least one of Ra′¹ and Ra′² represents a hydrogen atom and more preferable that both of them represent hydrogen atoms.

In a case where Ra′¹ or Ra′² represents an alkyl group, examples of the alkyl group include the same one as the alkyl group mentioned as the substituent which may be bonded to the carbon atom at the α-position in the description on the α-substituted acrylic acid ester, and the alkyl group preferably has 1 to 5 carbon atoms. Specific examples thereof preferably include a linear or branched alkyl group. More specific examples thereof include a methyl group, an ethyl group, a propyl group, an isopropyl group, an n-butyl group, an isobutyl group, a tert-butyl group, a pentyl group, an isopentyl group, and a neopentyl group. Among these, a methyl group or an ethyl group is more preferable, and a methyl group is particularly preferable.

In General Formula (a1-r-1), examples of the hydrocarbon group as Ra′³ include a linear or branched alkyl group and a cyclic hydrocarbon group.

The linear alkyl group has preferably 1 to 5 carbon atoms, more preferably 1 to 4 carbon atoms, and still more preferably 1 or 2 carbon atoms. Specific examples thereof include a methyl group, an ethyl group, an n-propyl group, an n-butyl group, and an n-pentyl group. Among these, a methyl group, an ethyl group, or an n-butyl group is preferable, and a methyl group or an ethyl group is more preferable.

The branched alkyl group has preferably 3 to 10 carbon atoms and more preferably 3 to 5 carbon atoms. Specific examples thereof include an isopropyl group, an isobutyl group, a tert-butyl group, an isopentyl group, a neopentyl group a 1,1-diethylpropyl group, and a 2,2-dimethylbutyl group. Among these, an isopropyl group is preferable.

In a case where Ra′³ represents a cyclic hydrocarbon group, the cyclic hydrocarbon group may be an aliphatic hydrocarbon group or an aromatic hydrocarbon group and may be a polycyclic group or a monocyclic group.

The aliphatic hydrocarbon group which is a monocyclic group is preferably a group obtained by removing one hydrogen atom from a monocycloalkane. The monocycloalkane preferably has 3 to 6 carbon atoms, and specific examples thereof include cyclopentane and cyclohexane.

The aliphatic hydrocarbon group which is a polycyclic group is preferably a group obtained by removing one hydrogen atom from a polycycloalkane. The polycycloalkane preferably has 7 to 12 carbon atoms, and specific examples thereof include adamantane, norbornane, isobornane, tricyclodecane, and tetracyclododecane. In a case where the cyclic hydrocarbon group as Ra′³ is an aromatic hydrocarbon group, the aromatic hydrocarbon group is a hydrocarbon group having at least one aromatic ring.

The aromatic ring is not particularly limited as long as it is a cyclic conjugated system having (4n+2) π electrons, and may be monocyclic or polycyclic. The aromatic ring preferably has 5 to 30 carbon atoms, more preferably 5 to 20 carbon atoms, still more preferably 6 to 15 carbon atoms, and particularly preferably 6 to 12 carbon atoms.

Specific examples of the aromatic ring include aromatic hydrocarbon rings such as benzene, naphthalene, anthracene, and phenanthrene; and an aromatic heterocyclic ring obtained by substituting part of carbon atoms constituting the above-described aromatic hydrocarbon ring with a hetero atom. Examples of the hetero atom in the aromatic heterocyclic rings include an oxygen atom, a sulfur atom, and a nitrogen atom. Specific examples of the aromatic heterocyclic ring include a pyridine ring and a thiophene ring.

Specific examples of the aromatic hydrocarbon group as Ra′³ include a group obtained by removing one hydrogen atom from the above-described aromatic hydrocarbon ring or aromatic heterocyclic ring (an aryl group or a heteroaryl group); a group obtained by removing one hydrogen atom from an aromatic compound having two or more aromatic rings (biphenyl, fluorene or the like); and a group obtained by substituting one hydrogen atom of the above-described aromatic hydrocarbon ring or aromatic heterocyclic ring with an alkylene group (an arylalkyl group such as a benzyl group, a phenethyl group, a 1-naphthylmethyl group, a 2-naphthylmethyl group, a 1-naphthylethyl group, or a 2-naphthylethyl group). The number of carbon atoms in the alkylene group bonded to the aromatic hydrocarbon ring or aromatic heterocyclic ring is preferably in a range of 1 to 4, more preferably 1 or 2, and particularly preferably 1.

The cyclic hydrocarbon group as Ra′³ may have a substituent. Examples of the substituent include, —R^{P1}, —R^{P2}—O—R^{P1}, —R^{P2}—CO—R^{P1}, —R^{P2}—CO—OR^{P1}, —R^{P2}—O—CO—R^{P1}, —R^{P2}—OH, —R^{P2}—CN, and —R^{P2}—COOH (hereinafter, these substituents are also collectively referred to as “Ra⁰⁵”.).

Here, R^{P1} represents a monovalent chain-like saturated hydrocarbon group having 1 to 10 carbon atoms, a monovalent aliphatic cyclic saturated hydrocarbon group having 3 to 20 carbon atoms, or a monovalent aromatic hydrocarbon group having 6 to carbon atoms. In addition, R^{P2} represents a single bond, a divalent chain-like saturated hydrocarbon group having 1 to 10 carbon atoms, a divalent aliphatic cyclic saturated hydrocarbon group having 3 to 20 carbon atoms, or a divalent aromatic hydrocarbon group having 6 to 30 carbon atoms. However, part or all of hydrogen atoms contained in the chain-like saturated hydrocarbon group, the aliphatic cyclic saturated hydrocarbon group, and the aromatic hydrocarbon group of R^{P1} and R^{P2} may be substituted with a fluorine atom. In the aliphatic cyclic hydrocarbon group, one or more of the above-described substituents may be included as a single kind, or one or more of the above-described substituents may be included as a plurality of kinds.

Examples of the monovalent chain-like saturated hydrocarbon group having 1 to carbon atoms include a methyl group, an ethyl group, a propyl group, a butyl group, a pentyl group, a hexyl group, a heptyl group, an octyl group, and a decyl group.

Examples of the monovalent aliphatic cyclic saturated hydrocarbon group having 3 to 20 carbon atoms include monocyclic aliphatic saturated hydrocarbon groups such as a cyclopropyl group, a cyclobutyl group, a cyclopentyl group, a cyclohexyl group, a cycloheptyl group, a cyclooctyl group, a cyclodecyl group, and cyclododecyl group; and polycyclic aliphatic saturated hydrocarbon groups such as a bicyclo[2.2.2]octanyl group, a tricyclo[5.2.1.02,6]decanyl group, a tricyclo [3.3.1.13,7]decanyl group, a tetracyclo[6.2.1.13,6.02,7] dodecanyl group, and an adamantyl group.

Examples of the monovalent aromatic hydrocarbon group having 6 to 30 carbon atoms include a group obtained by removing one hydrogen atom from an aromatic hydrocarbon ring such as benzene, biphenyl, fluorene, naphthalene, anthracene, or phenanthrene.

In a case where Ra′³ is bonded to Ra′¹ or Ra′² to form a ring, the cyclic group is preferably a 4-membered to 7-membered ring, and more preferably a 4-membered to 6-membered ring. Specific examples of the cyclic group include a tetrahydropyranyl group and a tetrahydrofuranyl group.

Tertiary alkyl ester-type acid dissociable group:

Among the polar groups, examples of the acid dissociable group for protecting a carboxy group include an acid dissociable group represented by General Formula (a1-r-2).

Among the acid dissociable groups represented by General Formula (a1-r-2), for convenience, a group which is constituted of alkyl groups is referred to as a “tertiary alkyl ester-type acid dissociable group”.

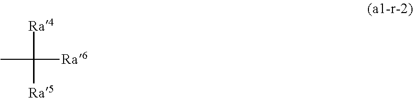

[In the formula, Ra′⁴ to Ra′⁶ each represents a hydrocarbon group, and Ra′⁵ and Ra′⁶ may be bonded to each other to form a ring.]

Examples of the hydrocarbon group as Ra′⁴ include a linear or branched alkyl group, a chain-like or cyclic alkenyl group, and a cyclic hydrocarbon group.

Examples of the linear or branched alkyl group and the cyclic hydrocarbon group (the aliphatic hydrocarbon group which is a monocyclic group, the aliphatic hydrocarbon group which is a polycyclic group, or the aromatic hydrocarbon group) as Ra′⁴ include the same one as Ra′³ described above.

The chain-like or cyclic alkenyl group as Ra′⁴ is preferably an alkenyl group having 2 to 10 carbon atoms.

Examples of the hydrocarbon group as Ra′⁵ or Ra′⁶ include the same one as Ra′³ described above.

Suitable examples thereof include groups represented by General Formula (a1-r2-1), General Formula (a1-r2-2), and General Formula (a1-r2-3) in a case where Ra′⁵ to Ra′⁶ are bonded to each other to form a ring.

On the other hand, suitable examples thereof include a group represented by General Formula (a1-r2-4) in a case where Ra′⁴ to Ra′⁶ are not bonded to each other and represent an independent hydrocarbon group.

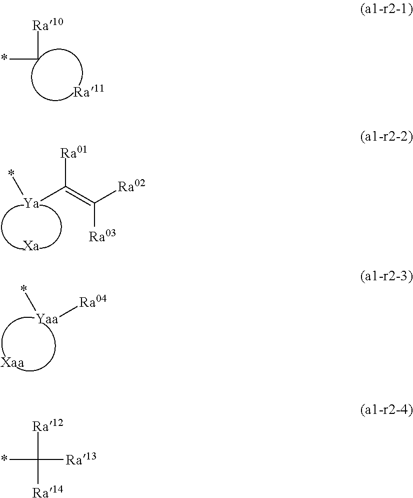

[In General Formula (a1-r2-1), Ra′¹⁰ represents an alkyl group having 1 to 10 carbon atoms or a group represented by General Formula (a1-r2-r1). Ra′¹¹ represents a group that forms an aliphatic cyclic group together with a carbon atom to which Ra′¹⁰ is bonded. In General Formula (a1-r2-2), Ya represents a carbon atom. Xa is a group that forms a cyclic hydrocarbon group together with Ya. Part or all of hydrogen atoms contained in the cyclic hydrocarbon group may be substituted. Ra⁰¹ to Ra⁰³ each independently represent a hydrogen atom, a monovalent chain-like saturated hydrocarbon group having 1 to 10 carbon atoms, or a monovalent aliphatic cyclic saturated hydrocarbon group having 3 to 20 carbon atoms. Part or all of hydrogen atoms contained in the chain-like saturated hydrocarbon group and the aliphatic cyclic saturated hydrocarbon group may be substituted. Two or more of Ra⁰¹ to Ra⁰³ may be bonded with each other to form a cyclic structure. In General Formula (a1-r2-3), Yaa represents a carbon atom. Xaa is a group that forms an aliphatic cyclic group together with Yaa. Ra⁰⁴ represents an aromatic hydrocarbon group which may have a substituent. In General Formula (a1-r2-4), Ra′¹² and Ra′¹³ each independently represent a monovalent chain-like saturated hydrocarbon group having 1 to 10 carbon atoms or a hydrogen atom. Part or all of hydrogen atoms contained in the chain-like saturated hydrocarbon group may be substituted. Ra′¹⁴ represents a hydrocarbon group which may have a substituent. * represents a bonding site (the same applies hereinafter).]

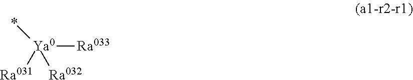

In the formula, Ya⁰ represents a quaternary carbon atom. [Ra⁰³¹, Ra⁰³², and Ra⁰³³ each independently represent a hydrocarbon group which may have a substituent. Here, one or more of Ra⁰³¹, Ra⁰³², and Ra⁰³³ are hydrocarbon groups having at least one polar group.]

In General Formula (a1-r2-1) described above, as the alkyl group having 1 to 10 carbon atoms as Ra′¹⁰, the groups mentioned as the linear or branched alkyl group as Ra′³ in General Formula (a1-r-1) are preferable. Ra′¹⁰ is preferably an alkyl group having 1 to 5 carbon atoms.

In General Formula (a1-r2-r1), Ya⁰ represents a quaternary carbon atom. That is, there are four adjacent carbon atoms bonded to Ya⁰ (carbon atom).

[In General Formula (a1-r2-r1), Ra⁰³¹, Ra⁰³²⁵ and Ra⁰³³ each independently represent a hydrocarbon group which may have a substituent. The hydrocarbon groups as Ra⁰³¹, Ra⁰³², and Ra⁰³³ each independently include a linear or branched alkyl group, a chain-like or cyclic alkenyl group, and a cyclic hydrocarbon group.

The linear alkyl groups as Ra⁰³¹, R⁰³², and Ra⁰³³ have preferably 1 to 5 carbon atoms, more preferably 1 to 4 carbon atoms, and still more preferably 1 or 2 carbon atoms. Specific examples thereof include a methyl group, an ethyl group, an n-propyl group, an n-butyl group, and an n-pentyl group. Among these, a methyl group, an ethyl group, or an n-butyl group is preferable, and a methyl group or an ethyl group is more preferable.

The branched alkyl groups as Ra⁰³¹, Ra⁰³², and Ra⁰³³ have preferably 3 to 10 carbon atoms and more preferably 3 to 5 carbon atoms. Specific examples thereof include an isopropyl group, an isobutyl group, a tert-butyl group, an isopentyl group, a neopentyl group a 1,1-diethylpropyl group, and a 2,2-dimethylbutyl group. Among these, an isopropyl group is preferable.

The chain-like or cyclic alkenyl groups as Ra⁰³¹, Ra⁰³², and Ra⁰³³ are preferably an alkenyl group having 2 to 10 carbon atoms.

The cyclic hydrocarbon group as Ra⁰³¹, Ra⁰³², and Ra⁰³³ may be an aliphatic hydrocarbon group or an aromatic hydrocarbon group and may be a polycyclic group or a monocyclic group.

The aliphatic hydrocarbon group which is a monocyclic group is preferably a group obtained by removing one hydrogen atom from a monocycloalkane. The monocycloalkane preferably has 3 to 6 carbon atoms, and specific examples thereof include cyclopentane and cyclohexane.

The aliphatic hydrocarbon group which is a polycyclic group is preferably a group obtained by removing one hydrogen atom from a polycycloalkane. The polycycloalkane preferably has 7 to 12 carbon atoms, and specific examples thereof include adamantane, norbornane, isobornane, tricyclodecane, and tetracyclododecane.

The aromatic hydrocarbon groups as Ra⁰³¹, Ra⁰³², and Ra⁰³³ are a hydrocarbon group having at least one aromatic ring. The aromatic ring is not particularly limited as long as it is a cyclic conjugated system having (4n+2) π electrons, and may be monocyclic or polycyclic. The aromatic ring preferably has 5 to 30 carbon atoms, more preferably 5 to 20 carbon atoms, still more preferably 6 to 15 carbon atoms, and particularly preferably 6 to 12 carbon atoms. Specific examples of the aromatic ring include aromatic hydrocarbon rings such as benzene, naphthalene, anthracene, and phenanthrene; and an aromatic heterocyclic ring obtained by substituting part of carbon atoms constituting the above-described aromatic hydrocarbon ring with a hetero atom. Examples of the hetero atom in the aromatic heterocyclic rings include an oxygen atom, a sulfur atom, and a nitrogen atom. Specific examples of the aromatic heterocyclic ring include a pyridine ring and a thiophene ring. Specific examples of the aromatic hydrocarbon group include a group obtained by removing one hydrogen atom from the above-described aromatic hydrocarbon ring or aromatic heterocyclic ring (an aryl group or a heteroaryl group); a group obtained by removing one hydrogen atom from an aromatic compound having two or more aromatic rings (biphenyl, fluorene or the like); and a group obtained by substituting one hydrogen atom of the above-described aromatic hydrocarbon ring or aromatic heterocyclic ring with an alkylene group (an arylalkyl group such as a benzyl group, a phenethyl group, a 1-naphthylmethyl group, a 2-naphthylmethyl group, a 1-naphthylethyl group, or a 2-naphthylethyl group). The alkylene group bonded to the aromatic hydrocarbon ring or aromatic heterocyclic ring preferably has 1 to 4 carbon atoms, more preferably 1 or 2 carbon atoms, and particularly preferably 1 carbon atom.

In a case where the hydrocarbon groups represented by Ra⁰³¹, Ra⁰³², and Ra⁰³³ are substituted, examples of the substituent include a hydroxy group, a carboxy group, a halogen atom (a fluorine atom, a chlorine atom, a bromine atom, and the like), an alkoxy group (a methoxy group, an ethoxy group, a propoxy group, a butoxy group, and the like), an alkyloxycarbonyl group.

Among the above examples, as Ra⁰³¹, Ra⁰³², and Ra⁰³³, the hydrocarbon group which may have a substituent is preferably a linear or branched alkyl group which may have a substituent and more preferably a linear alkyl group.

Here, one or more of Ra⁰³¹, Ra⁰³², and Ra³³ are hydrocarbon groups having at least a polar group.

The “hydrocarbon group having a polar group” includes any one of a hydrocarbon group in which a methylene group (—CH₂—) constituting the hydrocarbon group is substituted with a polar group and a hydrocarbon group in which at least one hydrogen atom constituting the hydrocarbon group is substituted with a polar group.

As such a “hydrocarbon group having a polar group”, a functional group represented by General Formula (a1-p1) is preferable.

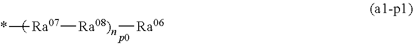

[In the formula, Ra⁰⁷ represents a divalent hydrocarbon group having 2 to 12 carbon atoms. Ra⁰¹ represents a divalent linking group including a hetero atom. Ra⁰⁶ represents a monovalent hydrocarbon group having 1 to 12 carbon atoms. nₚ₀ represents an integer in a range of 1 to 6.]

In General Formula (a1-p1), Ra⁰⁷ represents a divalent hydrocarbon group having 2 to 12 carbon atoms.

Ra⁰⁷ has 2 to 12 carbon atoms, has preferably 2 to 8 carbon atoms, more preferably 2 to 6 carbon atoms, still more preferably 2 to 4 carbon atoms, and particularly preferably 2 carbon atoms.

The hydrocarbon group as Ra⁰⁷ is preferably a chain-like or cyclic aliphatic hydrocarbon group and more preferably a chain-like hydrocarbon group.

Examples of Ra⁰⁷ include linear alkanediyl groups such as an ethylene group, a propane-1,3-diyl group, a butane-1,4-diyl group, a pentane-1,5-diyl group, a hexane-1,6-diyl group, a heptane-1,7-diyl group, an octane-1,8-diyl group, a nonane-1,9-diyl group, a decane-1,10-diyl group, an undecane-1,11-diyl group, and a dodecane-1,12-diyl group; branched alkanediyl groups such as a propane-1,2-diyl group, a 1-methylbutane-1,3-diyl group, a 2-methylpropane-1,3-diyl group, a pentane-1,4-diyl group, and a 2-methylbutane-1,4-diyl group; cycloalkanediyl groups such as a cyclobutane-1,3-diyl group, a cyclopentane-1,3-diyl group, a cyclohexane-1,4-diyl group, a cyclooctane-1,5-diyl group; and polycyclic divalent alicyclic hydrocarbon groups such as a norbornane-1,4-diyl group, a norbornane-2,5-diyl group, an adamantine-1,5-diyl group, and an adamantane-2,6-diyl group.

Among them, an alkanediyl group is preferable, and a linear alkanediyl group is more preferable.

In General Formula (a1-p1), Ra⁰⁸ represents a divalent linking group including a hetero atom.

Examples of Ra⁰⁸ include —O—, —C(═O)—O—, —C(═O)—, —O—C(═O)—O—, —C(═O)—NH—, —NH—, —NH—C(═NH)-(H may be substituted with a substituent such as an alkyl group and an acyl group), —S—, —S(═O)₂—, and —S(═O)₂—O—.

Among these, —O—, —C(═O)—O—, —C(═O)—, or —O—C(═O)—O— is preferable, and —O— or —C(═O)— is particularly preferable, from the viewpoint of the solubility in a developing solution.

In General Formula (a1-p1), Ra⁰⁶ represents a monovalent hydrocarbon group having 1 to 12 carbon atoms.

Ra⁰⁶ has 1 to 12 carbon atoms and has preferably 1 to 8 carbon atoms, more preferably 1 to 5 carbon atoms, still more preferably 1 to 3 carbon atoms, particularly preferably 1 or 2 carbon atoms, and most preferably 1 carbon atom, from the viewpoint of the solubility in a developing solution.

Examples of the hydrocarbon group as Ra⁰⁶ include a chain-like hydrocarbon group or a cyclic hydrocarbon group, or a hydrocarbon group obtained by combining a chain-like hydrocarbon group or a cyclic hydrocarbon group.

Examples of the chain-like hydrocarbon group include a methyl group, an ethyl group, an n-propyl group, an isopropyl group, an n-butyl group, a sec-butyl group, a tert-butyl group, an n-pentyl group, an n-hexyl group, an n-heptyl group, a 2-ethylhexyl group, an n-octyl group, an n-nonyl group, an n-decyl group, an n-undecyl group, and an n-dodecyl group.

The cyclic hydrocarbon group may be an alicyclic hydrocarbon group or an aromatic hydrocarbon group.

Examples of the alicyclic hydrocarbon group may be either monocyclic or polycyclic, and examples of the monocyclic alicyclic hydrocarbon group include cycloalkyl groups such as a cyclopropyl group, a cyclobutyl group, a cyclopentyl group, a cyclohexyl group, a methylcyclohexyl group, a dimethylcyclohexyl group, a cycloheptyl group, a cyclooctyl group, a cycloheptyl group, and a cyclodecyl group.

Examples of the polycyclic alicyclic hydrocarbon group include a decahydronaphthyl group, an adamantyl group, a 2-alkyladamantan-2-yl group, a 1-(adamantan-1-yl)alkane-1-yl group, a norbornyl group, a methylnorbornyl group, and an isobornyl group.

Examples of the aromatic hydrocarbon group include a phenyl group, a naphthyl group, an anthryl group, a p-methylphenyl group, a p-tert-butylphenyl group, a p-adamantylphenyl group, a tolyl group, a xylyl group, a cumenyl group, a mesityl group, a biphenyl group, a phenanthryl group, a 2,6-diethylphenyl group, and a 2-methyl-6-ethylphenyl group.

From the viewpoint of solubility in a developing solution, Ra⁰⁶ is preferably a chain-like hydrocarbon group, more preferably an alkyl group, and still more preferably a linear alkyl group.

In General Formula (a1-p1) nₚ₀ represents an integer in a range of 1 to 6, is preferably an integer in a range of 1 to 3, more preferably 1 or 2, and still more preferably 1.

Specific examples of the hydrocarbon group having at least a polar group are described below.

In the following formulae, * is a bonding site for bonding to the quaternary carbon atom (Ya⁰).

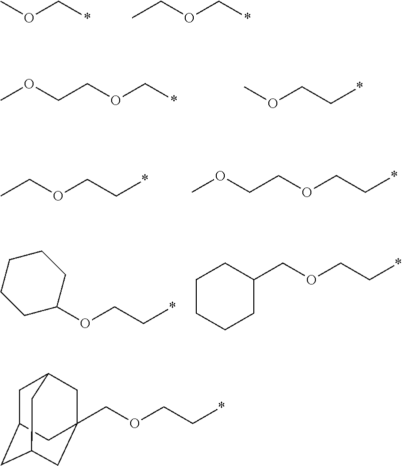

In General Formula (a1-r2-r1), the number of hydrocarbon groups having at least a polar group among Ra⁰³¹, Ra⁰³², and Ra⁰³³ is one or more. The number of hydrocarbon groups may be appropriately determined in consideration of the solubility in a developing solution at the time of resist pattern formation, for example, one or two are preferable, and one is particularly preferable among Ra⁰³¹, Ra⁰³², and Ra⁰³³.

The above-described hydrocarbon group having at least a polar group may have a substituent other than the polar group. Examples of the substituent include a halogen atom (a fluorine atom, a chlorine atom, a bromine atom, or the like) and a halogenated alkyl group having 1 to 5 carbon atoms.

In General Formula (a1-r2-1), Ra′¹¹ (a group that forms an aliphatic cyclic group together with a carbon atom to which Ra′¹⁰ is bonded) is preferably the group mentioned as the aliphatic hydrocarbon group which is a monocyclic group or a polycyclic group as Ra′³ in General Formula (a1-r-1).

In General Formula (a1-r2-2), examples of the cyclic hydrocarbon group that is formed by Xa together with Ya include a group in which one or more hydrogen atoms are further removed from a cyclic monovalent hydrocarbon group (an aliphatic hydrocarbon group) as Ra′³ in General Formula (a1-r-1).

The cyclic hydrocarbon group that is formed by Xa together with Ya may have a substituent. Examples of this substituent include the same one as the substituent which may be contained in the cyclic hydrocarbon group as Ra′³.

In General Formula (a1-r2-2), as Ra⁰¹ to Ra⁰³, examples of the monovalent chain-like saturated hydrocarbon group having 1 to 10 carbon atoms include a methyl group, an ethyl group, a propyl group, a butyl group, a pentyl group, a hexyl group, a heptyl group, an octyl group, and a decyl group.

Examples of the monovalent aliphatic cyclic saturated hydrocarbon group having 3 to 20 carbon atoms, as Ra⁰¹ to Ra⁰³, include monocyclic aliphatic saturated hydrocarbon groups such as a cyclopropyl group, a cyclobutyl group, a cyclopentyl group, a cyclohexyl group, a cycloheptyl group, a cyclooctyl group, a cyclodecyl group, and cyclododecyl group; and polycyclic aliphatic saturated hydrocarbon groups such as a bicyclo[2.2.2]octanyl group, a tricyclo[5.2.1.02,6]decanyl group, a tricyclo[3.3.1.13,7]decanyl group, a tetracyclo[6.2.1.13,6.02,7] dodecanyl group, and an adamantyl group.

Among them, Ra⁰¹ to Ra⁰³ are preferably a hydrogen atom or a monovalent chain-like saturated hydrocarbon group having 1 to 10 carbon atoms, from the viewpoint of the easy synthesis of a monomer compound from which the constitutional unit (a1) is derived, among them, a hydrogen atom, a methyl group, and an ethyl group are more preferable, and a hydrogen atom is particularly preferable.

Examples of the substituent contained in the chain-like saturated hydrocarbon group represented by Ra⁰¹ to Ra⁰³ or the aliphatic cyclic saturated hydrocarbon group include the same group as Ra⁰⁵ described above.

Examples of the group containing a carbon-carbon double bond generated by forming a cyclic structure, which is obtained by bonding two or more of Ra⁰¹ to Ra⁰³ to each other, include a cyclopentenyl group, a cyclohexenyl group, a methylcyclopentenyl group, a methylcyclohexenyl group, a cyclopentylideneethenyl group, and a cyclohexylideneethenyl group. Among these, a cyclopentenyl group, a cyclohexenyl group, and a cyclopentylideneethenyl group are preferable from the viewpoint of easy synthesis of a monomer compound from which the constitutional unit (a1) is derived.

In General Formula (a1-r2-3), an aliphatic cyclic group that is formed by Xaa together with Yaa is preferably the group mentioned as the aliphatic hydrocarbon group which is a monocyclic group or a polycyclic group as Ra′³ in General Formula (a1-r-1).

In General Formula (a1-r2-3), Examples of the aromatic hydrocarbon group as Ra⁰⁴ include a group obtained by removing one or more hydrogen atoms from an aromatic hydrocarbon ring having 5 to 30 carbon atoms. Among them, Ra⁰⁴ is preferably a group obtained by removing one or more hydrogen atoms from an aromatic hydrocarbon ring having 6 to 15 carbon atoms, more preferably a group obtained by removing one or more hydrogen atoms from benzene, naphthalene, anthracene, or phenanthrene, still more preferably a group obtained by removing one or more hydrogen atoms from benzene, naphthalene, or anthracene, particularly preferably a group obtained by removing one or more hydrogen atoms from benzene or naphthalene, and most preferably a group obtained by removing one or more hydrogen atoms from benzene.

Examples of the substituent which may be contained in Ra⁰⁴ in General Formula (a1-r2-3) include a methyl group, an ethyl group, propyl group, a hydroxy group, a carboxy group, a halogen atom (a fluorine atom, a chlorine atom, a bromine atom, and the like), an alkoxy group (a methoxy group, an ethoxy group, a propoxy group, a butoxy group, and the like), and an alkyloxycarbonyl group.

In General Formula (a1-r2-4), Ra′¹² and Ra′¹³ each independently represent a monovalent chain-like saturated hydrocarbon group having 1 to 10 carbon atoms or a hydrogen atom. Examples of the monovalent chain-like saturated hydrocarbon group having 1 to 10 carbon atoms as Ra′¹² and Ra′¹³ include the same one as the monovalent chain-like saturated hydrocarbon group having 1 to 10 carbon atoms as Ra⁰¹ to Ra⁰³ as described above. Part or all of hydrogen atoms contained in the chain-like saturated hydrocarbon group may be substituted.

Among the above, Ra′¹² and Ra′¹³ are preferably a hydrogen atom or an alkyl group having 1 to 5 carbon atoms, more preferably an alkyl group having 1 to 5 carbon atoms, still more preferably a methyl group or an ethyl group, and particularly preferably a methyl group.

In a case where the chain-like saturated hydrocarbon groups represented by Ra′¹² and Ra′¹³ are substituted, examples of the substituent include the same group as Ra⁰⁵ described above.

In General Formula (a1-r2-4), Ra′¹⁴ represents a hydrocarbon group which may have a substituent. Examples of the hydrocarbon group as Ra′¹⁴ include a linear or branched alkyl group and a cyclic hydrocarbon group.

The linear alkyl group as Ra′¹⁴ has preferably 1 to 5 carbon atoms, more preferably 1 to 4 carbon atoms, and still more preferably 1 or 2 carbon atoms. Specific examples thereof include a methyl group, an ethyl group, an n-propyl group, an n-butyl group, and an n-pentyl group. Among these, a methyl group, an ethyl group, or an n-butyl group is preferable, and a methyl group or an ethyl group is more preferable.

The branched alkyl group as Ra′¹⁴ preferably has 3 to 10 carbon atoms and more preferably 3 to 5 carbon atoms. Specific examples thereof include an isopropyl group, an isobutyl group, a tert-butyl group, an isopentyl group, a neopentyl group a 1,1-diethylpropyl group, and a 2,2-dimethylbutyl group. Among these, an isopropyl group is preferable.

In a case where Ra′¹⁴ represents a cyclic hydrocarbon group, the cyclic hydrocarbon group may be an aliphatic hydrocarbon group or an aromatic hydrocarbon group and may be a polycyclic group or a monocyclic group.

The aliphatic hydrocarbon group which is a monocyclic group is preferably a group obtained by removing one hydrogen atom from a monocycloalkane. The monocycloalkane preferably has 3 to 6 carbon atoms, and specific examples thereof include cyclopentane and cyclohexane.

The aliphatic hydrocarbon group which is a polycyclic group is preferably a group obtained by removing one hydrogen atom from a polycycloalkane. The polycycloalkane preferably has 7 to 12 carbon atoms, and specific examples thereof include adamantane, norbornane, isobornane, tricyclodecane, and tetracyclododecane.

Examples of the aromatic hydrocarbon group as Ra′¹⁴ include the same one as the aromatic hydrocarbon group as Ra⁰⁴. Among them, Ra′¹⁴ is preferably a group obtained by removing one or more hydrogen atoms from an aromatic hydrocarbon ring having 6 to 15 carbon atoms, more preferably a group obtained by removing one or more hydrogen atoms from benzene, naphthalene, anthracene, or phenanthrene, still more preferably a group obtained by removing one or more hydrogen atoms from benzene, naphthalene, or anthracene, particularly preferably a group obtained by removing one or more hydrogen atoms from naphthalene or anthracene, and most preferably a group obtained by removing one or more hydrogen atoms from naphthalene.

Examples of the substituent which may be contained in Ra′¹⁴ include the same one as the substituent which may be contained in Ra⁰⁴.

In a case where Ra′¹⁴ in General Formula (a1-r2-4) is a naphthyl group, the position at which the tertiary carbon atom in General Formula (a1-r2-4) is bonded may be any one of the 1-position and the 2-position of the naphthyl group.

In a case where Ra′¹⁴ in General Formula (a1-r2-4) is an anthryl group, the position at which the tertiary carbon atom in General Formula (a1-r2-4) is bonded may be any one of the 1-position, the 2-position, and 9-position of the anthryl group.

Specific examples of the group represented by General Formula (a1-r2-1) are shown below.

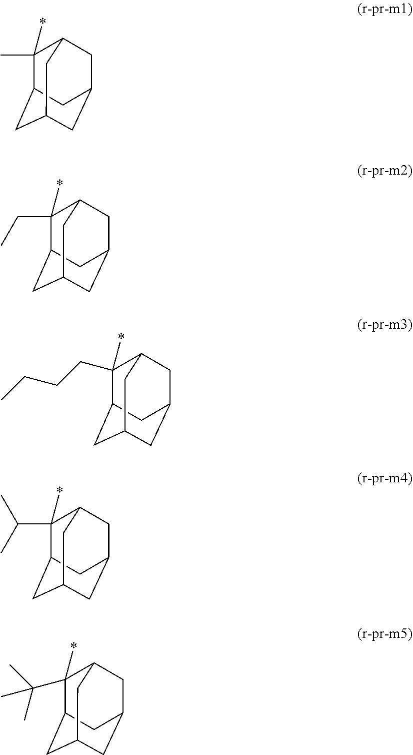

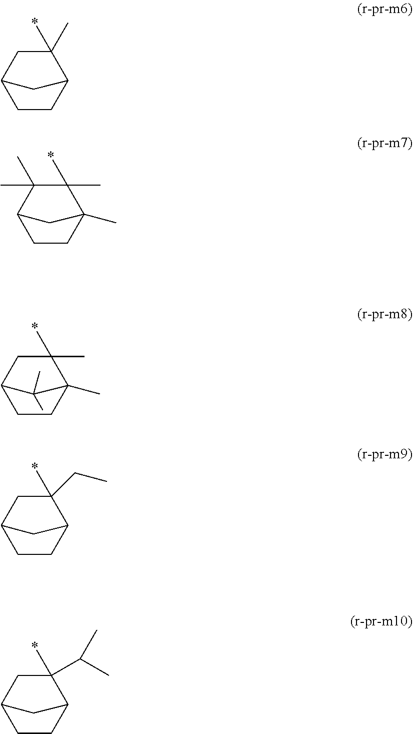

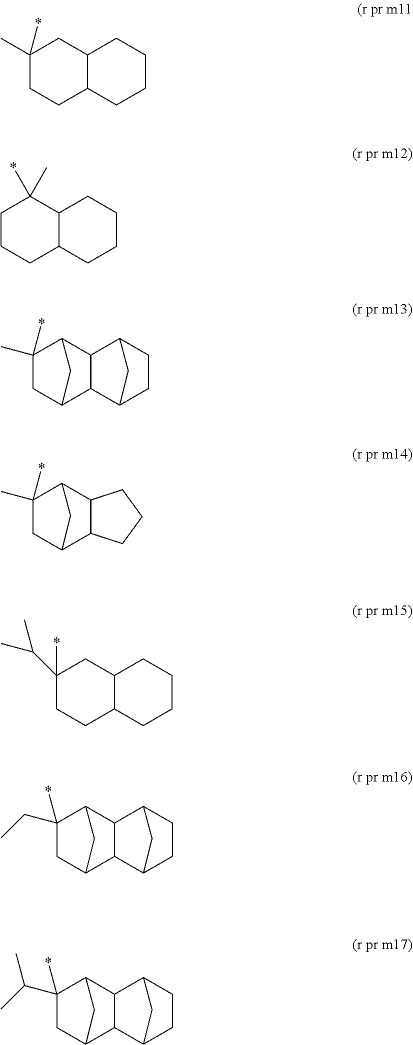

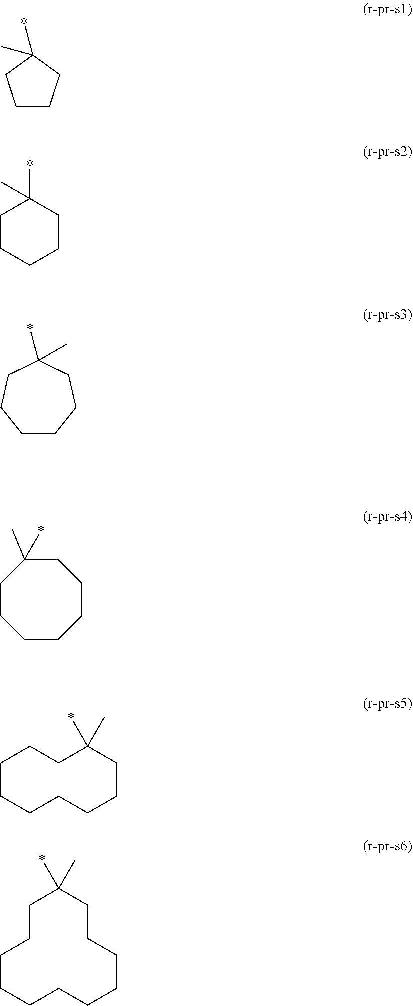

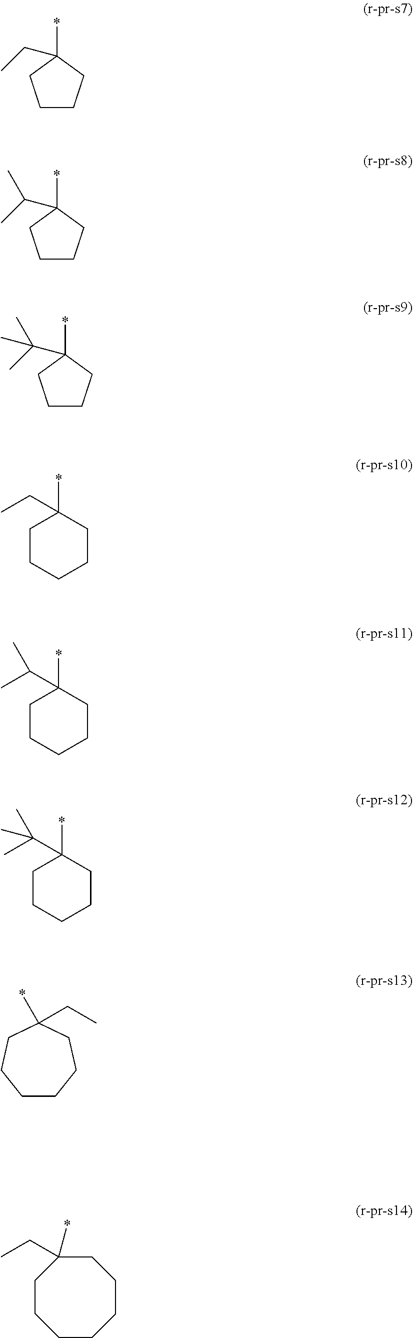

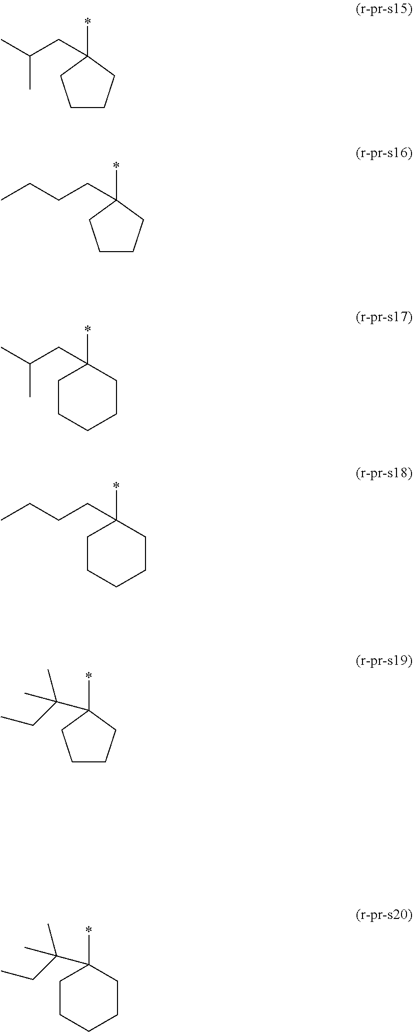

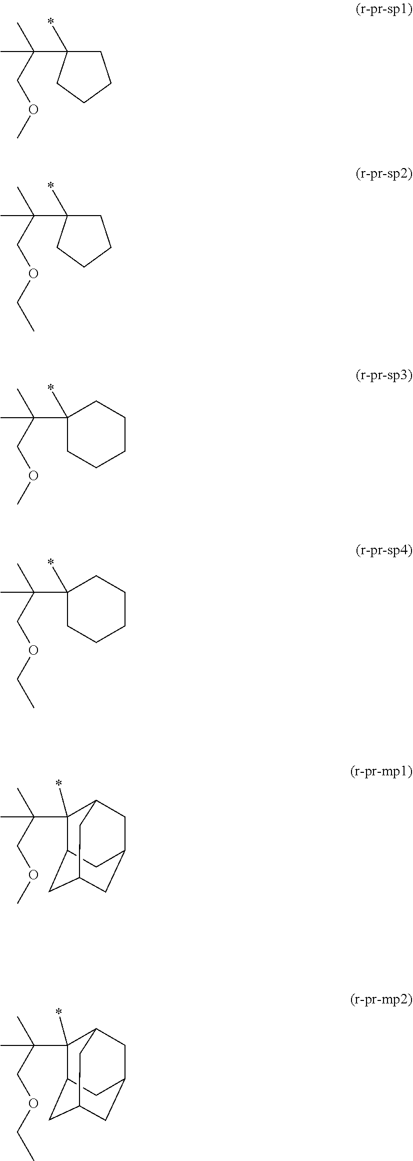

Specific examples of the group represented by General Formula (a1-r2-2) are shown below.

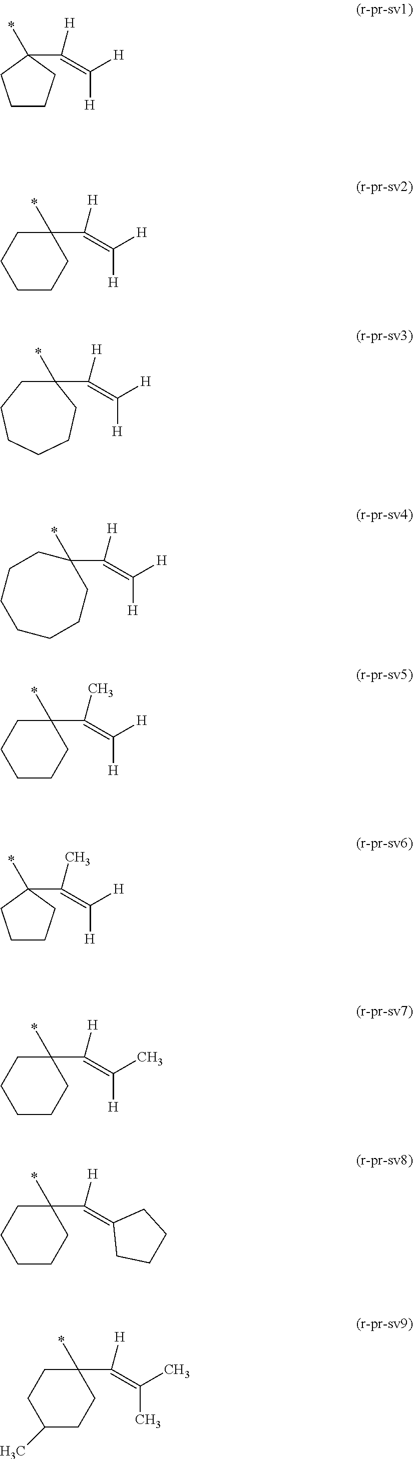

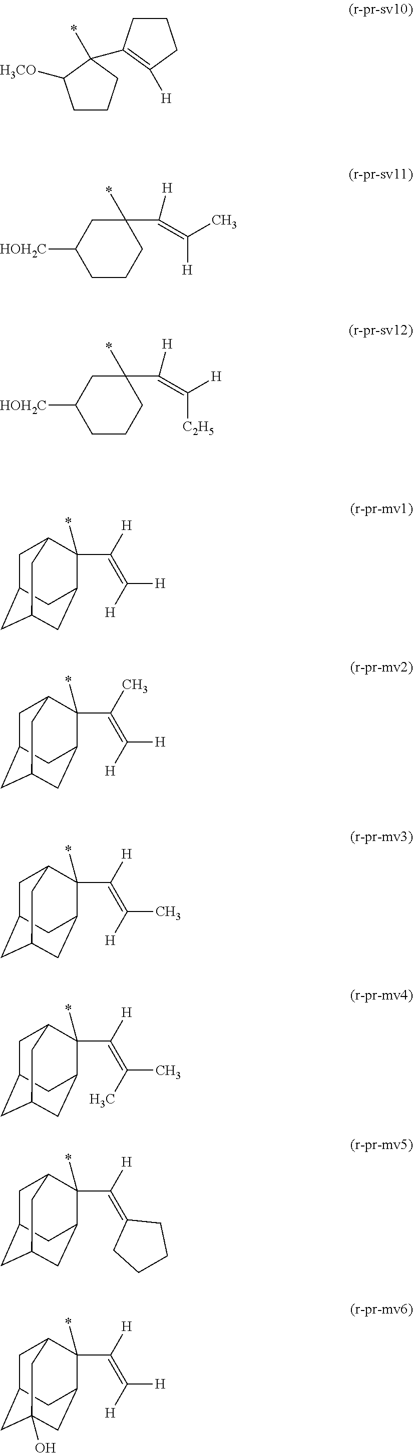

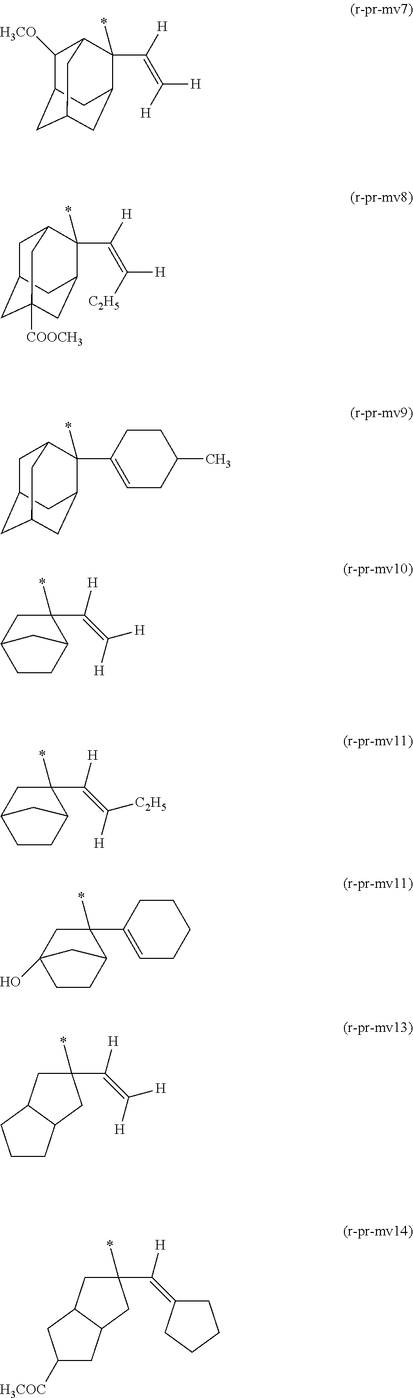

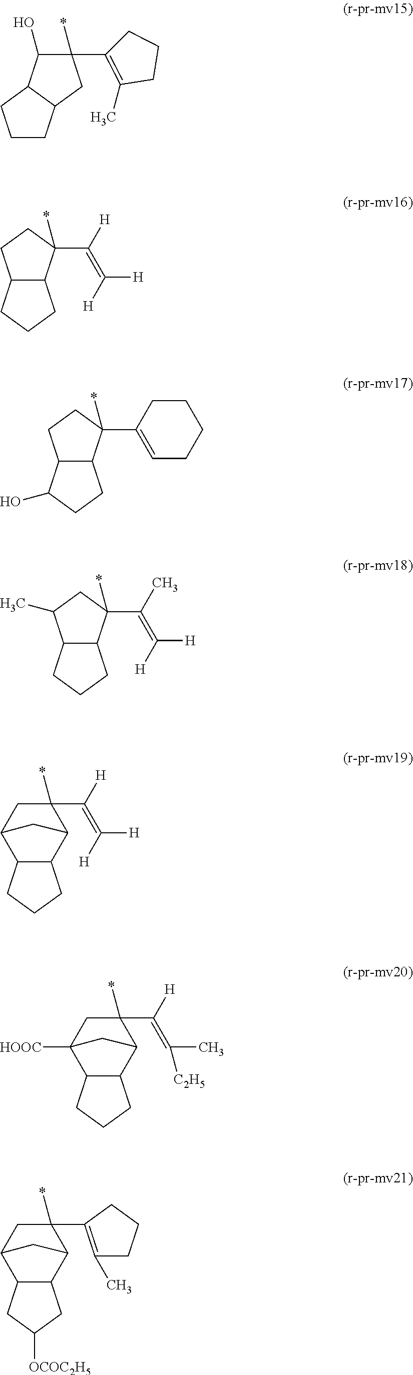

Specific examples of the group represented by General Formula (a1-r2-3) are shown below.

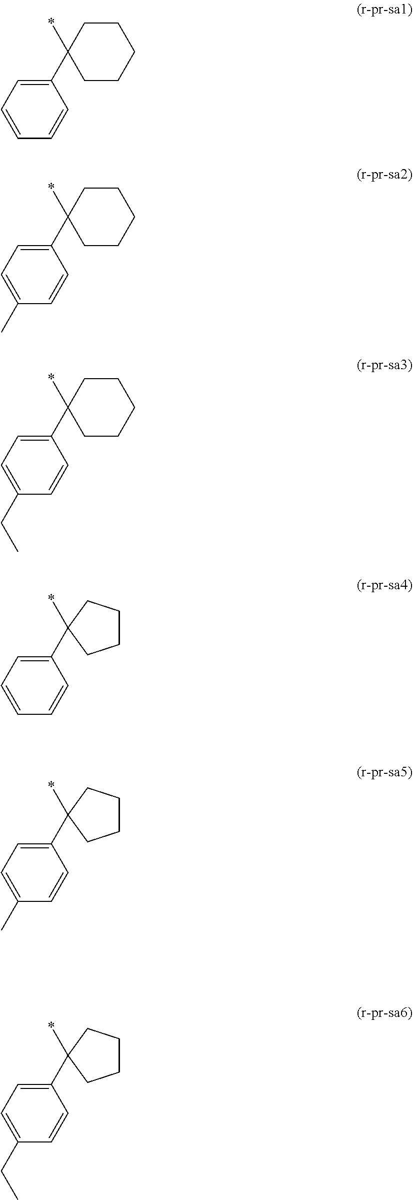

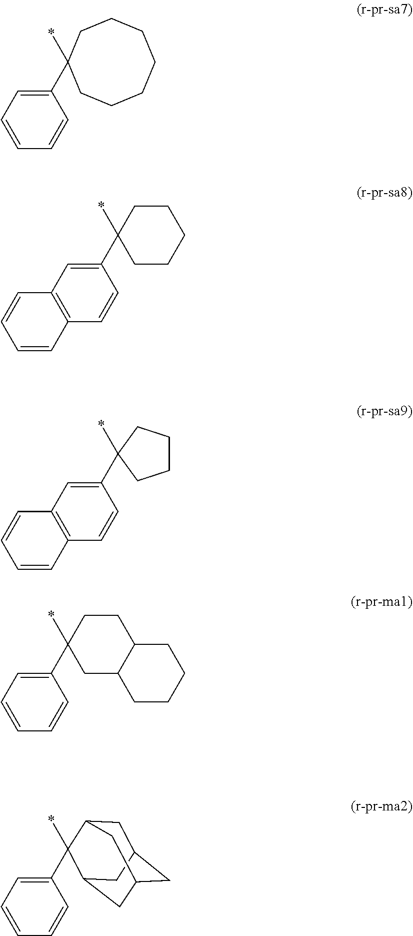

Specific examples of the group represented by General Formula (a1-r2-4) are shown below.

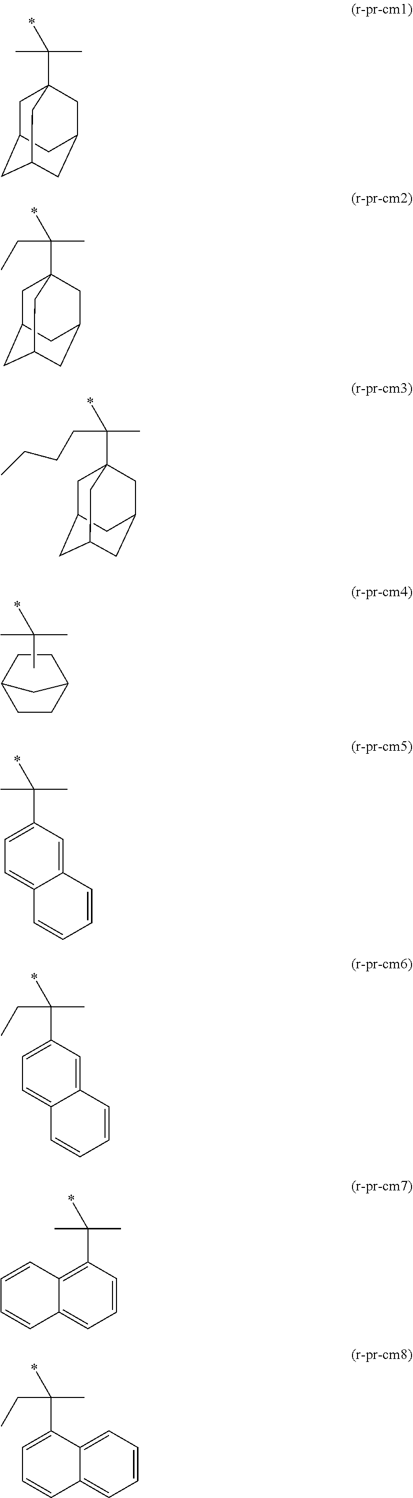

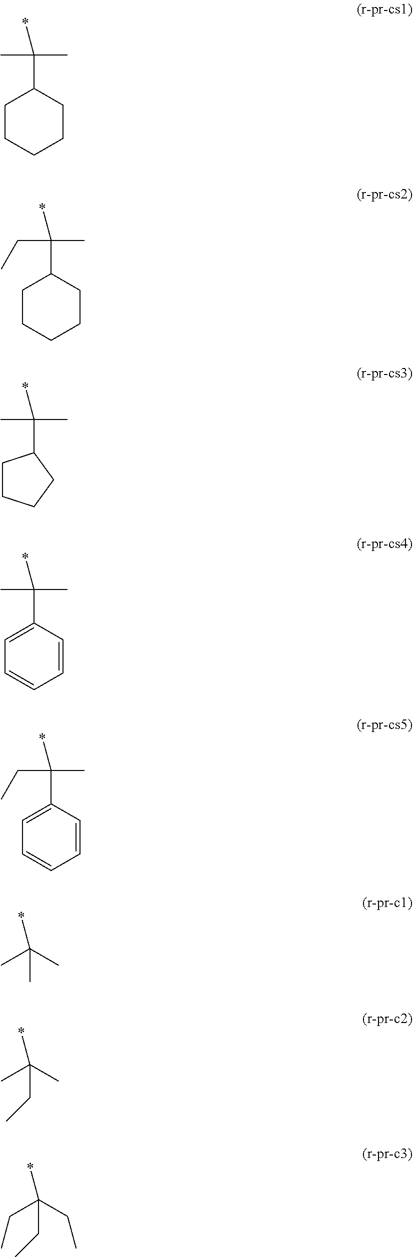

Tertiary alkyloxycarbonyl acid dissociable group:

Among the polar groups, examples of the acid dissociable group for protecting a hydroxyl group include an acid dissociable group (hereinafter, for convenience, also referred to as a “tertiary alkyloxycarbonyl acid dissociable group”) represented by General Formula (a1-r-3).

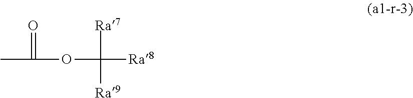

[In the formula, Ra′⁷ to Ra′⁹ each represents an alkyl group.]

In General Formula (a1-r-3), Ra′⁷ to Ra′⁹ are each preferably an alkyl group having 1 to 5 carbon atoms and more preferably an alkyl group having 1 to 3 carbon atoms.

Further, the total number of carbon atoms in each of the alkyl groups is preferably in a range of 3 to 7, more preferably in a range of 3 to 5, and most preferably 3 or 4.

Examples of the constitutional unit (a1) include a constitutional unit derived from acrylic acid ester in which the hydrogen atom bonded to the carbon atom at the α-position may be substituted with a substituent; a constitutional unit derived from acrylamide; a constitutional unit in which at least a part of hydrogen atoms in a hydroxyl group of a constitutional unit derived from hydroxystyrene or a hydroxystyrene derivative are protected by the substituent including an acid decomposable group; and a constitutional unit in which at least a part of hydrogen atoms in —C(═O)—OH of a constitutional unit derived from vinylbenzoic acid or a vinylbenzoic acid derivative are protected by the substituent including an acid decomposable group.

Among the above, the constitutional unit (a1) is preferably a constitutional unit derived from acrylic acid ester in which the hydrogen atom bonded to the carbon atom at the α-position may be substituted with a substituent.

Preferred specific examples of such a constitutional unit (a1) include constitutional units represented by General Formula (a1-1) or (a1-2).

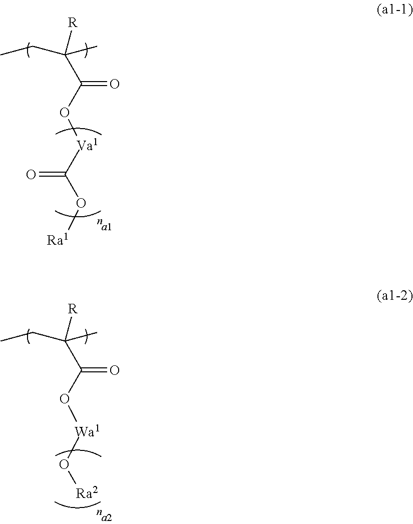

[In the formula, R represents a hydrogen atom, an alkyl group having 1 to 5 carbon atoms, or a halogenated alkyl group having 1 to 5 carbon atoms. Va¹ represents a divalent hydrocarbon group which may have an ether bond. nₐ₁ represents an integer in a range of 0 to 2. Ra¹ is an acid dissociable group represented by General Formula (a1-r-1) or (a1-r-2). W^{a1} represents an (nₐ₂+1)-valent hydrocarbon group, nₐ₂ represents an integer in a range of 1 to 3, and R^{a2} represents an acid dissociable group represented by General Formula (a1-r-1) or (a1-r-3).]

In General Formula (a1-1), the alkyl group having 1 to 5 carbon atoms as R is preferably a linear or branched alkyl group having 1 to 5 carbon atoms, and specific examples thereof include a methyl group, an ethyl group, a propyl group, an isopropyl group, an n-butyl group, an isobutyl group, a tert-butyl group, a pentyl group, an isopentyl group, and a neopentyl group. The halogenated alkyl group having 1 to 5 carbon atoms is a group obtained by substituting part or all of hydrogen atoms in the alkyl group having 1 to 5 carbon atoms with a halogen atom. Examples of the halogen atom include a fluorine atom, a chlorine atom, a bromine atom, and an iodine atom, where a fluorine atom is particularly preferable.

R is preferably a hydrogen atom, an alkyl group having 1 to 5 carbon atoms, or a fluorinated alkyl group having 1 to 5 carbon atoms, and in terms of industrial availability, is more preferably a hydrogen atom or a methyl group, and still more preferably a hydrogen atom.

In General Formula (a1-1), the divalent hydrocarbon group as Va¹ may be an aliphatic hydrocarbon group or an aromatic hydrocarbon group.

The aliphatic hydrocarbon group as the divalent hydrocarbon group represented by Va¹ may be saturated or unsaturated. In general, it is preferable that the aliphatic hydrocarbon group is saturated.

Specific examples of the aliphatic hydrocarbon group include a linear or branched aliphatic hydrocarbon group, and an aliphatic hydrocarbon group containing a ring in the structure thereof.

The linear aliphatic hydrocarbon group preferably has 1 to 10 carbon atoms, more preferably 1 to 6 carbon atoms, still more preferably 1 to 4 carbon atoms, and most preferably 1 to 3 carbon atoms.

The linear aliphatic hydrocarbon group is preferably a linear alkylene group, and specific examples thereof include a methylene group [—CH₂—], an ethylene group [—(CH₂)₂—], a trimethylene group [—(CH₂)₃—], a tetramethylene group [—(CH₂)₄—], and a pentamethylene group [—(CH₂)₅—].

The branched aliphatic hydrocarbon group has preferably 2 to 10 carbon atoms, more preferably 3 to 6 carbon atoms, still more preferably 3 or 4 carbon atoms, and most preferably 3 carbon atoms.

The branched aliphatic hydrocarbon group is preferably a branched alkylene group, and specific examples thereof include alkylalkylene groups, for example, alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)—, and —C(CH₂CH₃)₂—; alkylethylene groups such as —CH(CH₃)CH₂—, —CH(CH₃)CH(CH₃)—, —C(CH₃)₂CH₂—, —CH(CH₂CH₃)CH₂—, and —C(CH₂CH₃)₂—CH₂—; alkyltrimethylene groups such as —CH(CH₃)CH₂CH₂—, and —CH₂CH(CH₃)CH₂—; and alkyltetramethylene groups such as —CH(CH₃)CH₂CH₂CH₂—, and —CH₂CH(CH₃)CH₂CH₂—. The alkyl group in the alkylalkylene group is preferably a linear alkyl group having 1 to 5 carbon atoms.

Examples of the aliphatic hydrocarbon group containing a ring in the structure thereof include an alicyclic hydrocarbon group (a group obtained by removing two hydrogen atoms from an aliphatic hydrocarbon ring), a group in which the alicyclic hydrocarbon group is bonded to the terminal of the linear or branched aliphatic hydrocarbon group, and a group in which the alicyclic hydrocarbon group is interposed in the linear or branched aliphatic hydrocarbon group. Examples of the linear or branched aliphatic hydrocarbon group include the same one as the above-described linear aliphatic hydrocarbon group or the above-described branched aliphatic hydrocarbon group.

The alicyclic hydrocarbon group preferably has 3 to 20 carbon atoms and more preferably 3 to 12 carbon atoms.

The alicyclic hydrocarbon group may be monocyclic or polycyclic. The monocyclic alicyclic hydrocarbon group is preferably a group obtained by removing two hydrogen atoms from a monocycloalkane. The monocycloalkane preferably has 3 to 6 carbon atoms, and specific examples thereof include cyclopentane and cyclohexane. The polycyclic alicyclic hydrocarbon group is preferably a group obtained by removing two hydrogen atoms from a polycycloalkane, and the polycycloalkane is preferably a group having 7 to 12 carbon atoms. Specific examples thereof include adamantane, norbornane, isobornane, tricyclodecane, and tetracyclododecane.

The aromatic hydrocarbon group as the divalent hydrocarbon group represented by Va¹ is a hydrocarbon group having an aromatic ring.

The aromatic hydrocarbon group preferably has 3 to 30 carbon atoms, more preferably 5 to 30 carbon atoms, still more preferably 5 to 20 carbon atoms, particularly preferably 6 to 15 carbon atoms, and most preferably 6 to 12 carbon atoms. However, the number of carbon atoms in the substituent is not included in the number of carbon atoms.

Specific examples of the aromatic ring contained in the aromatic hydrocarbon group include aromatic hydrocarbon rings such as benzene, biphenyl, fluorene, naphthalene, anthracene, and phenanthrene; and an aromatic heterocyclic ring obtained by substituting part of carbon atoms constituting the above-described aromatic hydrocarbon rings with a hetero atom. Examples of the hetero atom in the aromatic heterocyclic rings include an oxygen atom, a sulfur atom, and a nitrogen atom.

Specific examples of the aromatic hydrocarbon group include a group obtained by removing two hydrogen atoms from the above-described aromatic hydrocarbon ring (an arylene group); and a group obtained by substituting one hydrogen atom of a group (an aryl group) obtained by removing one hydrogen atom from the aromatic hydrocarbon ring with an alkylene group (for example, a group obtained by further removing one hydrogen atom from an aryl group in an arylalkyl group such as a benzyl group, a phenethyl group, a 1-naphthylmethyl group, a 2-naphthylmethyl group, a 1-naphthylethyl group, or a 2-naphthylethyl group). The alkylene group (an alkyl chain in the arylalkyl group) preferably has 1 to 4 carbon atoms, more preferably 1 or 2 carbon atoms, and particularly preferably 1 carbon atom.

In General Formula (a1-1), R^{a1} is an acid dissociable group represented by General Formula (a1-r-1) or (a1-r-2).

In General Formula (a1-2), the (nₐ₂+1)-valent hydrocarbon group as W^{a1} may be an aliphatic hydrocarbon group or an aromatic hydrocarbon group. The aliphatic hydrocarbon group indicates a hydrocarbon group that has no aromaticity and may be saturated or unsaturated. In general, it is preferable that the aliphatic hydrocarbon group is saturated. Examples of the aliphatic hydrocarbon group include a linear or branched aliphatic hydrocarbon group, an aliphatic hydrocarbon group containing a ring in the structure thereof, and a combination of the linear or branched aliphatic hydrocarbon group and the aliphatic hydrocarbon group containing a ring in the structure thereof.

The valency of (nₐ₂+1) is preferably divalent, trivalent, or tetravalent, and more preferably divalent or trivalent.

In General Formula (a1-2), Ra² is an acid dissociable group represented by General Formula (a1-r-1) or (a1-r-3).

Specific examples of the constitutional unit represented by General Formula (a1-1) are shown below. In each of the formulae shown below, Ra represents a hydrogen atom, a methyl group, or a trifluoromethyl group.

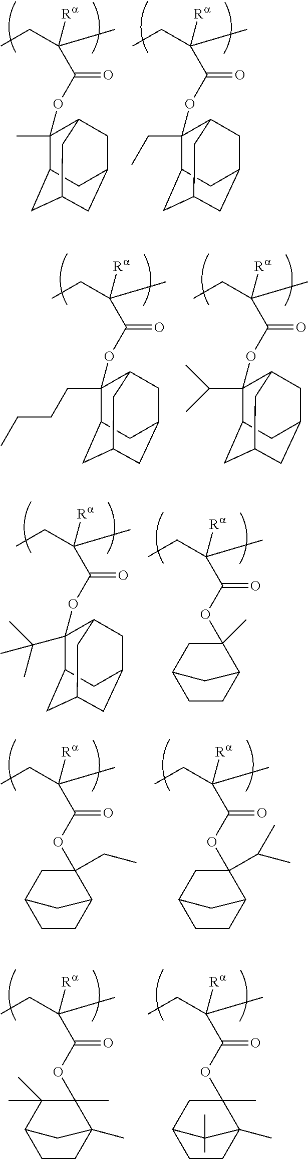

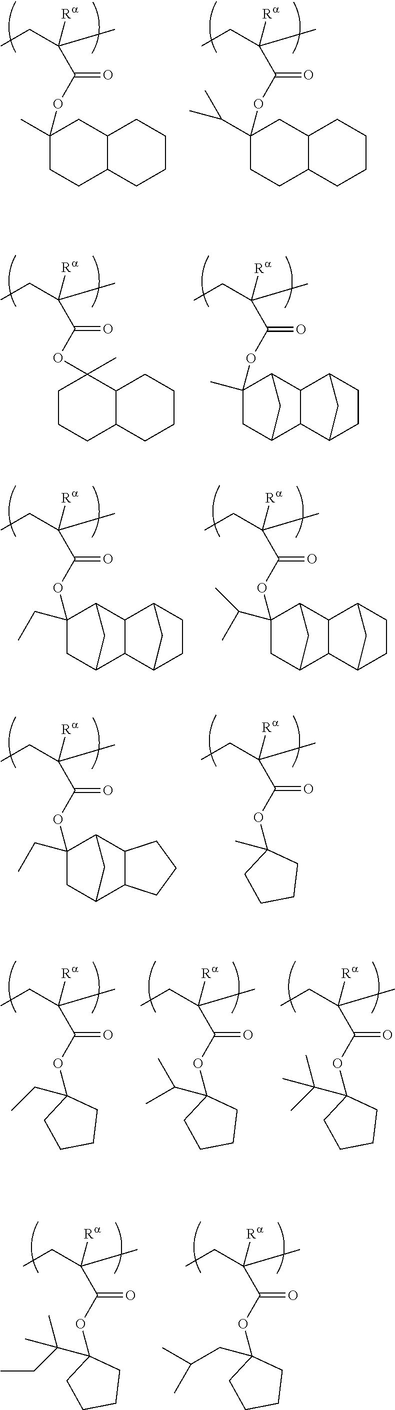

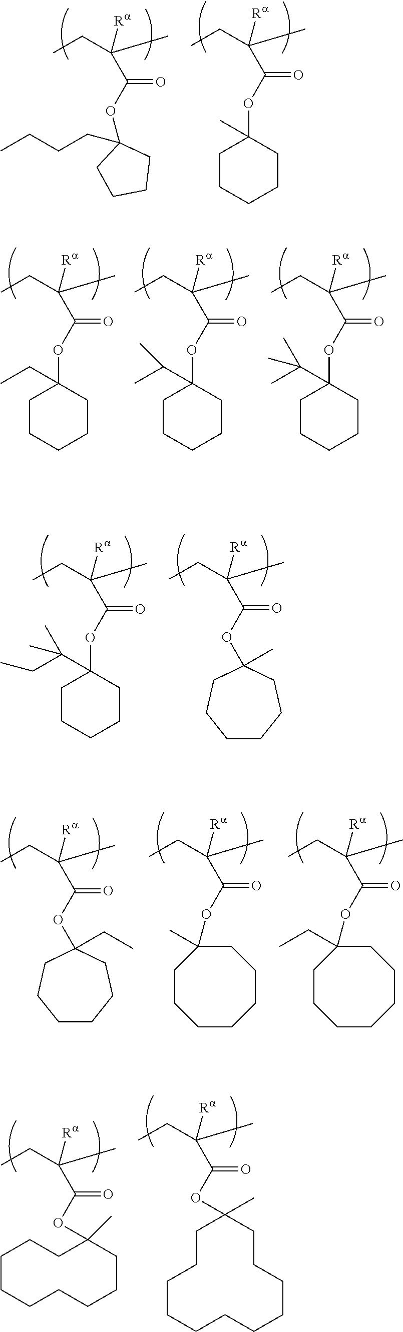

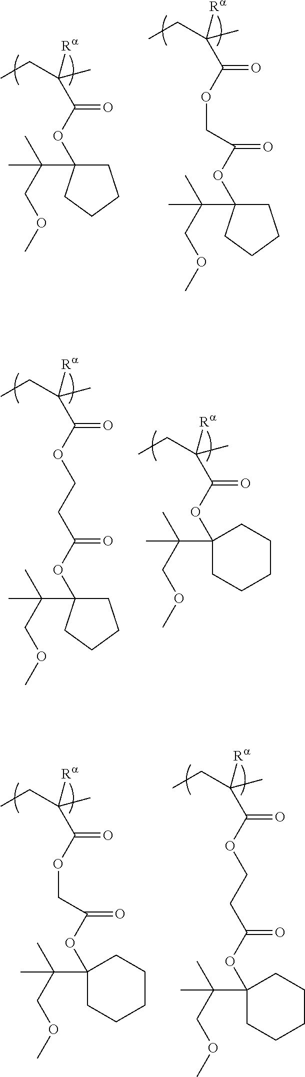

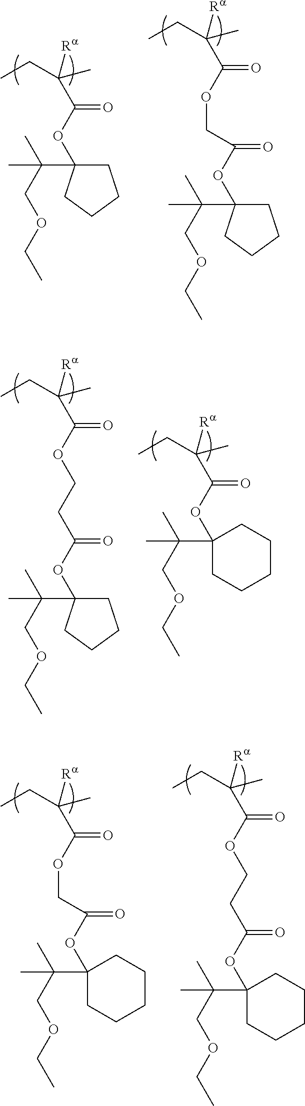

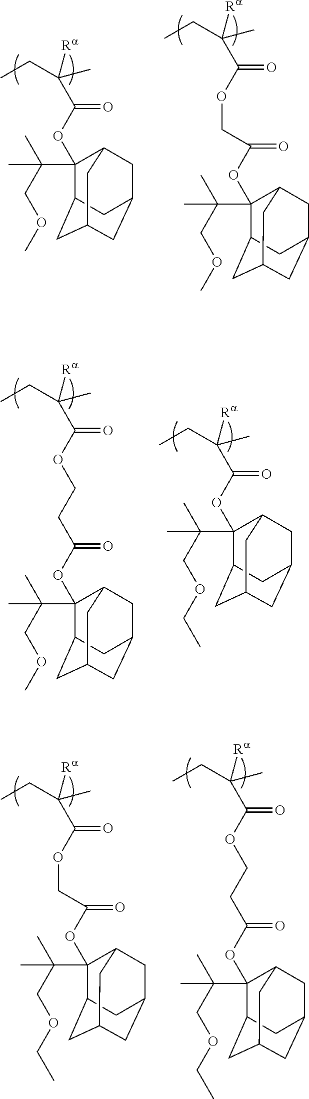

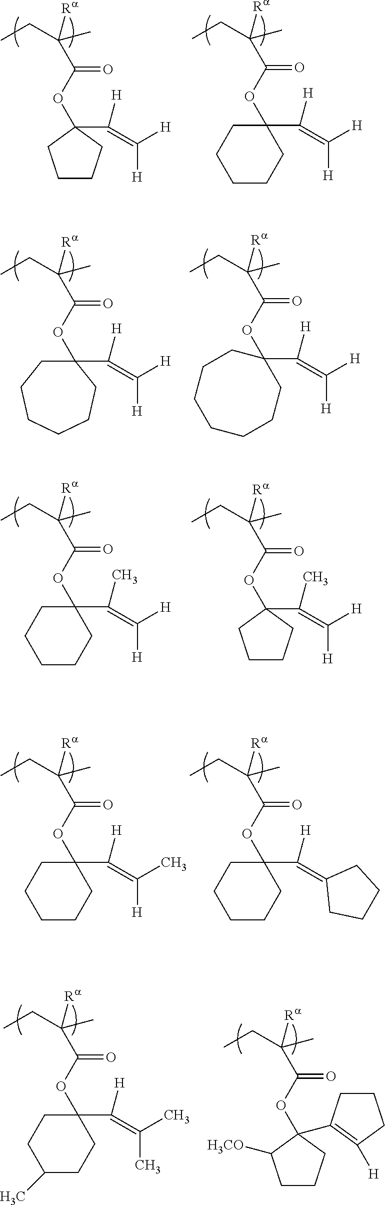

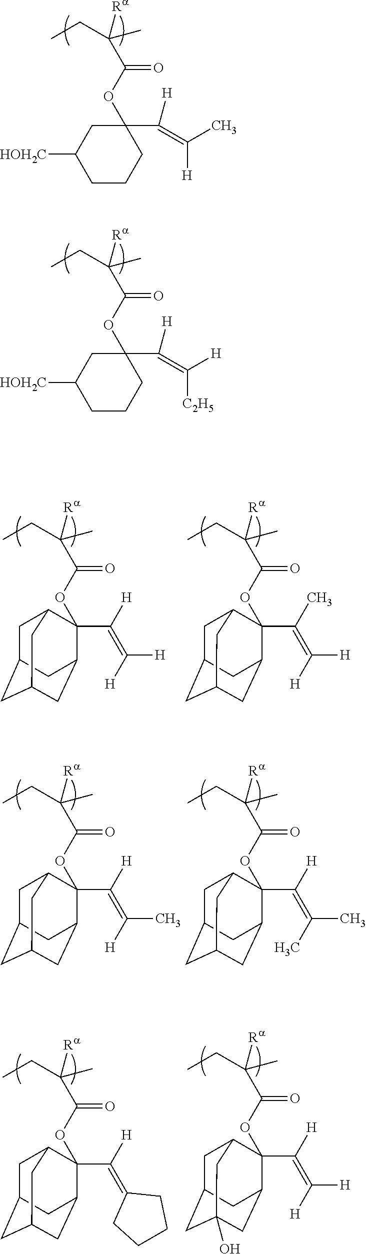

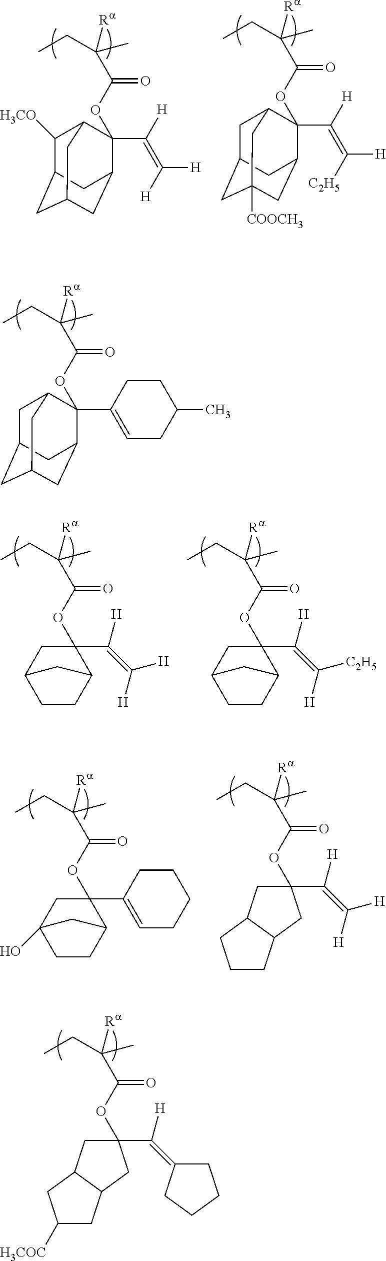

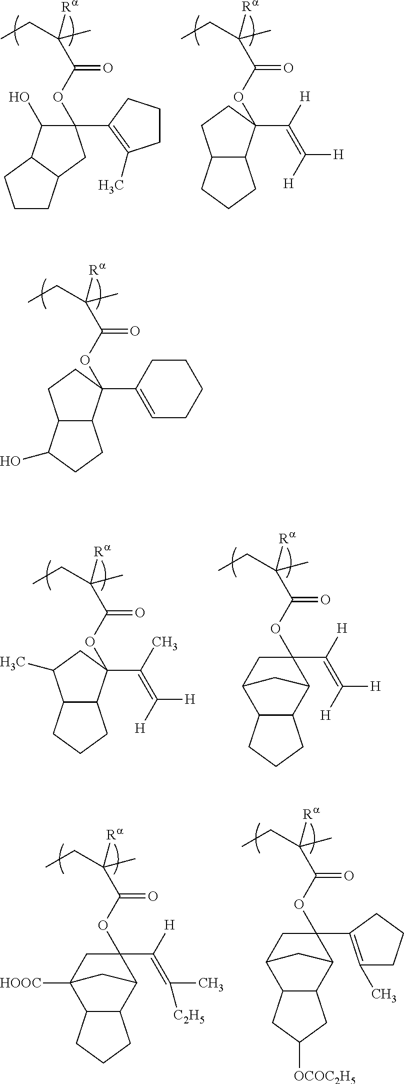

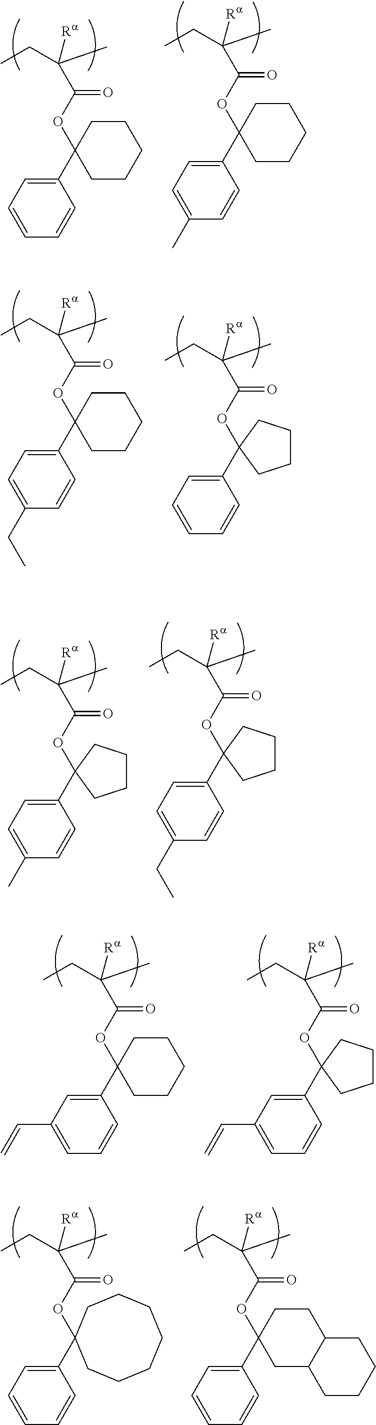

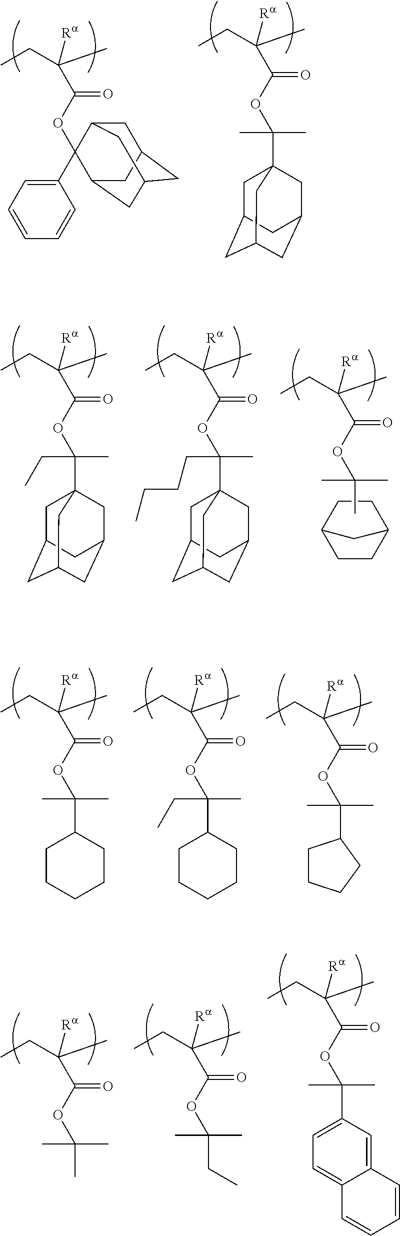

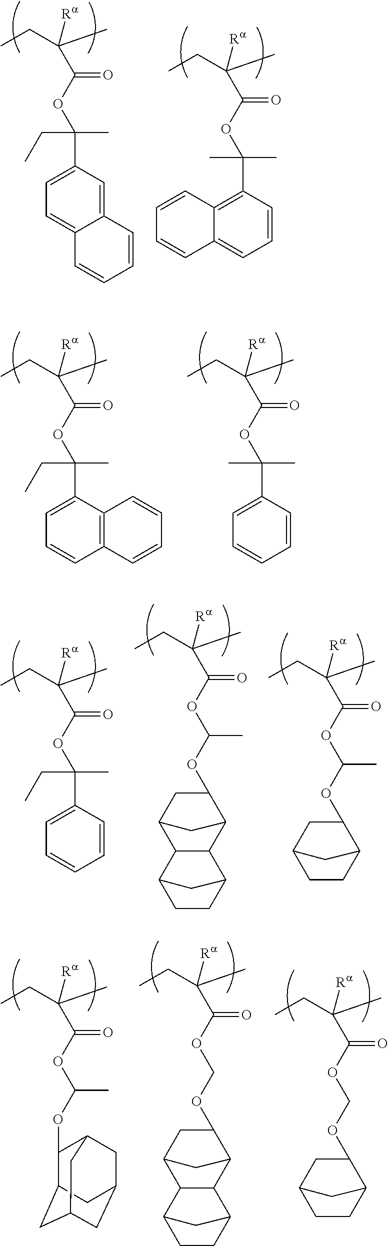

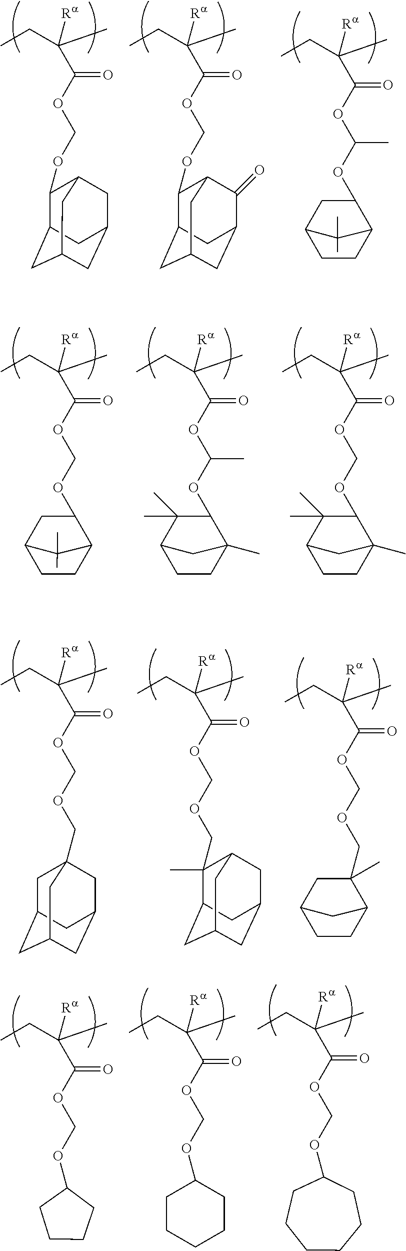

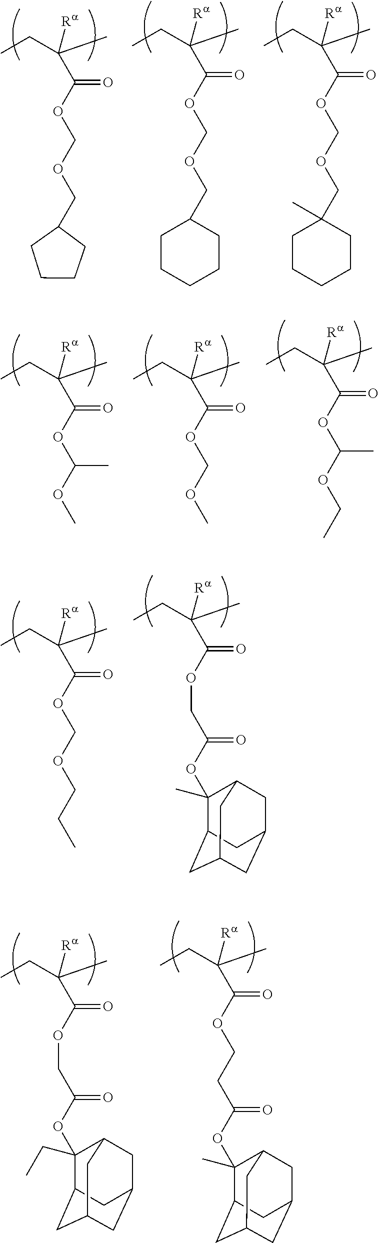

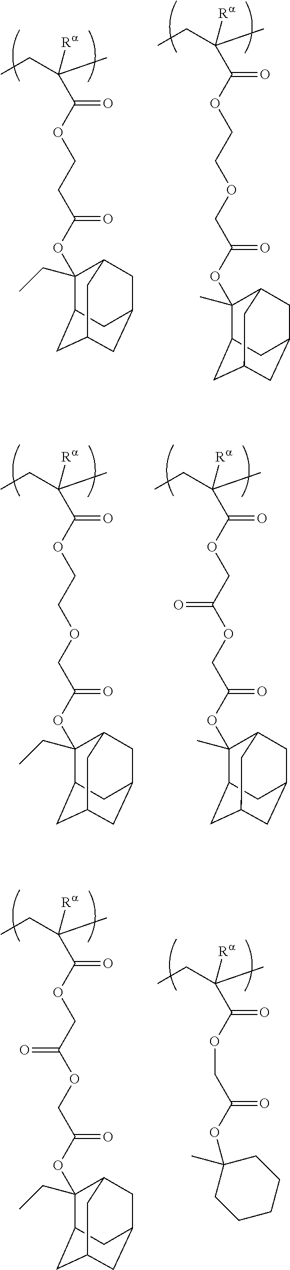

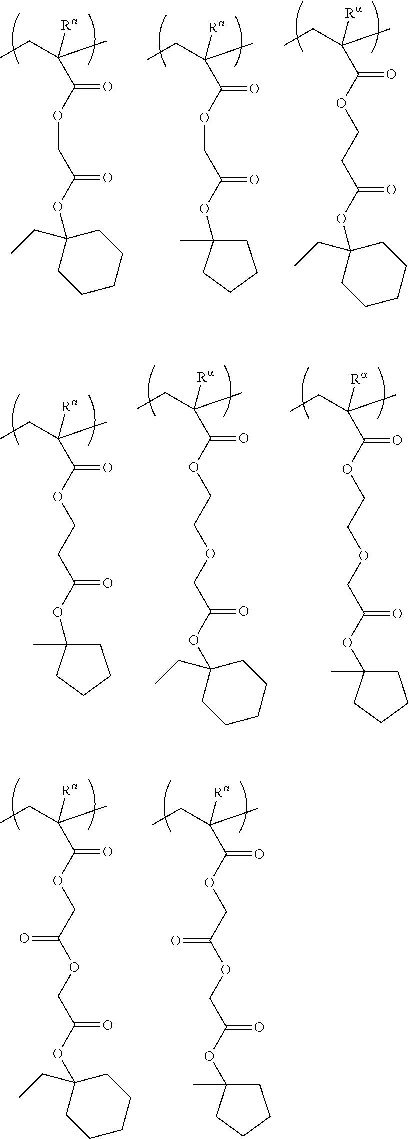

Specific examples of the constitutional unit represented by General Formula (a1-2) are shown below.

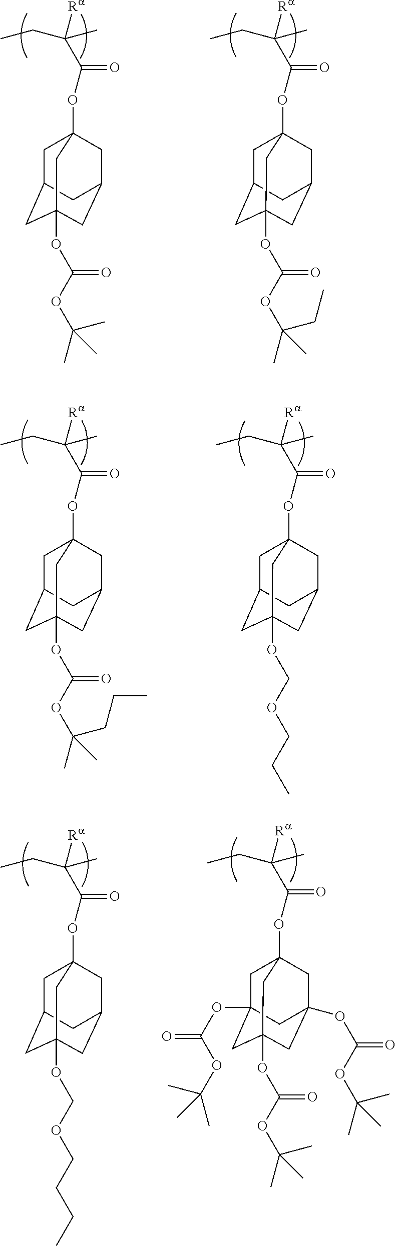

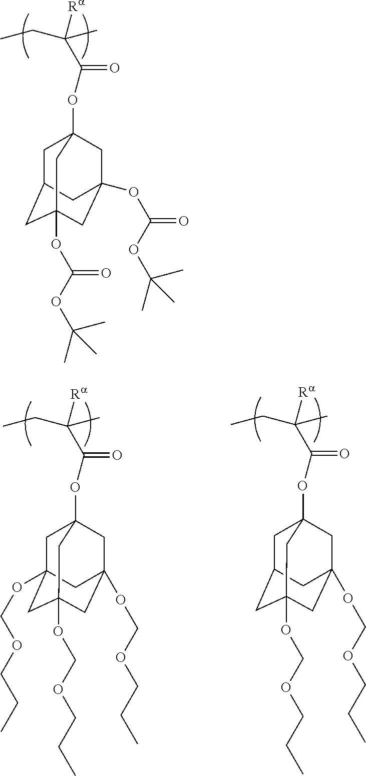

The constitutional unit (a1) contained in the component (A1) may be one kind or may be two or more kinds.

The constitutional unit (a1) is more preferably a constitutional unit represented by General Formula (a1-1) since the characteristics (sensitivity, CDU, shape, and the like) in lithography using ultraviolet rays such as a g-line and an i-line or a KrF excimer laser can be more easily enhanced.

Among these, the constitutional unit (a1) particularly preferably includes a constitutional unit represented by General Formula (a1-1-1) shown below.

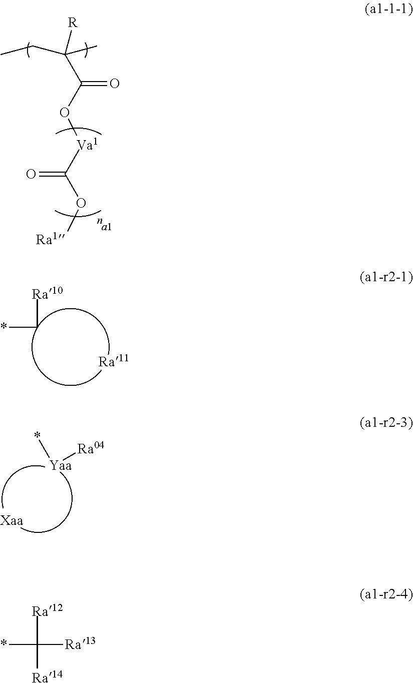

[In the formula, R^{a1}″ is an acid dissociable group represented by General Formula (a1-r2-1), (a1-r2-3), or (a1-r2-4).]

In General Formula (a1-1-1), R, Va¹, and nₐ₁ are each the same as R, Va¹, and nₐ₁ in General Formula (a1-1).

The description for the acid dissociable group represented by General Formula (a1-r2-1), (a1-r2-3), or (a1-r2-4) is as described above.

Among the above, R^{a1}″ is preferably an acid dissociable group represented by General Formula (a1-r2-1) or (a1-r2-4), and it is more preferably an acid dissociable group in which Ra′¹¹ in General Formula (a1-r2-1) represents an aliphatic hydrocarbon group as a monocyclic group, or an acid dissociable group in which Ra′¹², Ra′¹³, and Ra′¹⁴ in General Formula (a1-r2-4) each independently represents an alkyl group having 1 to 5 carbon atoms.

The proportion of the constitutional unit (a1) in the component (A1) is preferably in a range of 1% to 80% by mole, more preferably in a range of 5% to 70% by mole, and still more preferably in a range of 10% to 65% by mole, with respect to the total (100% by mole) of all constitutional units constituting the component (A1).

In a case where the proportion of the constitutional unit (a1) is set to be equal to or larger than the lower limit value thereof, lithography characteristics such as sensitivity, resolution, and roughness amelioration are improved. In addition, in a case where it is equal to or smaller than the upper limit value thereof, balance with other constitutional units can be obtained, and thus various lithography characteristics are improved.

«Other Constitutional Units»

The component (A1) may have other constitutional units as necessary in addition to the constitutional unit (a1) described above.

Examples of other constitutional units include a constitutional unit (a2) containing a lactone-containing cyclic group, a —SO₂—-containing cyclic group, or a carbonate-containing cyclic group; a constitutional unit (a3) containing a polar group-containing aliphatic hydrocarbon group; a constitutional unit (a4) containing an acid non-dissociable aliphatic cyclic group; and the constitutional unit (a11) derived from a compound containing an aromatic ring (excluding an aromatic ring to which a hydroxy group is bonded) in the side chain.

In regard to constitutional unit (a2):

The component (A1) may further have, as necessary, a constitutional unit (a2) (provided that a group having the constitutional unit (a1) is excluded) containing a lactone-containing cyclic group, a —SO₂—-containing cyclic group, or a carbonate-containing cyclic group, in addition to the constitutional unit (a1).

In a case where the component (A1) is used for forming a resist film, the lactone-containing cyclic group, the —SO₂—-containing cyclic group, or the carbonate-containing cyclic group in the constitutional unit (a2) is effective for improving the adhesiveness of the resist film to the substrate. Further, due to having the constitutional unit (a2), lithography characteristics can be improved, for example, by the effects obtained by properly adjusting the acid diffusion length, increasing the adhesiveness of the resist film to the substrate, and properly adjusting the solubility during development.

The term “lactone-containing cyclic group” indicates a cyclic group that contains a ring (lactone ring) containing a —O—C(═O)— in the ring skeleton. In a case where the lactone ring is counted as the first ring and the group contains only the lactone ring, the group is referred to as a monocyclic group. Further, in a case where the group has other ring structures, the group is referred to as a polycyclic group regardless of the structures. The lactone-containing cyclic group may be a monocyclic group or a polycyclic group.

The lactone-containing cyclic group for the constitutional unit (a2) is not particularly limited, and any lactone-containing cyclic group may be used. Specific examples thereof include groups each represented by General Formulae (a2-r-1) to (a2-r-7) shown below.

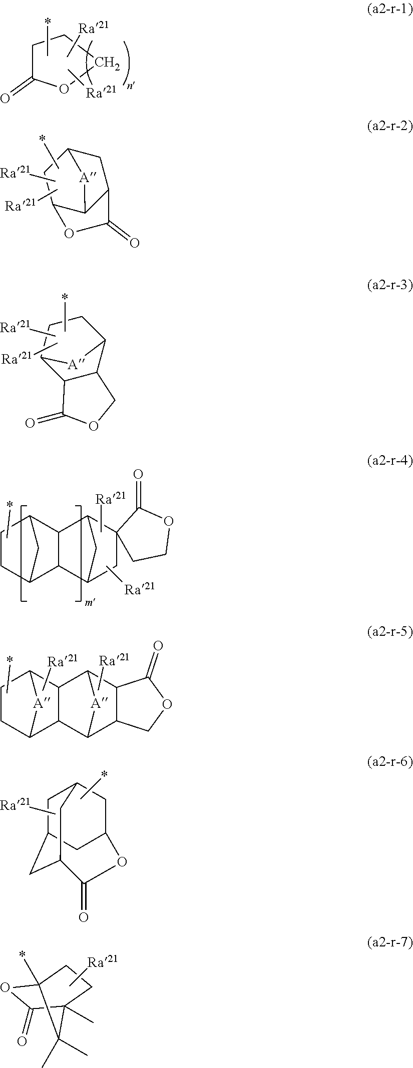

[In the formulae, each Ra′²¹ independently represents a hydrogen atom, an alkyl group, an alkoxy group, a halogen atom, a halogenated alkyl group, a hydroxyl group, —COOR″, —OC(═O)R″, a hydroxyalkyl group, or a cyano group; R″ represents a hydrogen atom, an alkyl group, a lactone-containing cyclic group, a carbonate-containing cyclic group, or a —SO₂—-containing cyclic group; A″ represents an oxygen atom, a sulfur atom, or an alkylene group having 1 to 5 carbon atoms, which may contain an oxygen atom (—O—) or a sulfur atom (—S—); and n′ represents an integer in a range of 0 to 2, and m′ is 0 or 1.]

In General Formulae (a2-r-1) to (a2-r-7), the alkyl group as Ra′²¹ is preferably an alkyl group having 1 to 6 carbon atoms. The alkyl group is preferably a linear alkyl group or a branched alkyl group. Specific examples thereof include a methyl group, an ethyl group, a propyl group, an isopropyl group, an n-butyl group, an isobutyl group, a tert-butyl group, a pentyl group, an isopentyl group, a neopentyl group, and a hexyl group. Among these, a methyl group or ethyl group is preferable, and a methyl group is particularly preferable.

The alkoxy group as Ra′²¹ is preferably an alkoxy group having 1 to 6 carbon atoms. Further, the alkoxy group is preferably a linear or branched alkoxy group. Specific examples of the alkoxy groups include a group formed by linking the above-described alkyl group mentioned as the alkyl group represented by Ra′²¹ to an oxygen atom (—O—).

Examples of the halogen atom as Ra′²¹ include a fluorine atom, a chlorine atom, a bromine atom, and an iodine atom. Among these, a fluorine atom is preferable.

Examples of the halogenated alkyl group as Ra′²¹ include a group obtained by substituting part or all of hydrogen atoms in the above-described alkyl group as Ra′²¹ with the above-described halogen atoms. The halogenated alkyl group is preferably a fluorinated alkyl group and particularly preferably a perfluoroalkyl group.

In —COOR″ and —OC(═O)R″ as Ra′²¹, R″ represents a hydrogen atom, an alkyl group, a lactone-containing cyclic group, a carbonate-containing cyclic group, or a —SO₂—-containing cyclic group.

The alkyl group as R″ may be linear, branched, or cyclic, and preferably has 1 to carbon atoms.

In a case where R″ represents a linear or branched alkyl group, it is preferably an alkyl group having 1 to 10 carbon atoms, more preferably an alkyl group having 1 to 5 carbon atoms, and particularly preferably a methyl group or an ethyl group.

In a case where R″ represents a cyclic alkyl group, the cyclic alkyl group preferably has 3 to 15 carbon atoms, more preferably 4 to 12 carbon atoms, and most preferably 5 to 10 carbon atoms. Specific examples thereof include a group obtained by removing one or more hydrogen atoms from a monocycloalkane, which may be or may not be substituted with a fluorine atom or a fluorinated alkyl group; and a group obtained by removing one or more hydrogen atoms from a polycycloalkane such as bicycloalkane, tricycloalkane, or tetracycloalkane. More specific examples thereof include a group obtained by removing one or more hydrogen atoms from a monocycloalkane such as cyclopentane or cyclohexane; and a group obtained by removing one or more hydrogen atoms from a polycycloalkane such as adamantane, norbornane, isobornane, tricyclodecane, or tetracyclododecane.

Examples of the lactone-containing cyclic group as R″ include the same ones as those each represented by General Formulae (a2-r-1) to (a2-r-7).

The carbonate-containing cyclic group as R″ has the same definition as that for the carbonate-containing cyclic group described below. Specific examples of the carbonate-containing cyclic group include groups each represented by General Formulae (ax3-r-1) to (ax3-r-3).

The —SO₂—-containing cyclic group as R″ is the same as —SO₂—-containing cyclic group described below. Specific examples thereof include a group represented by each of General Formulae (a5-r-1) to (a5-r-4).

The hydroxyalkyl group as Ra′²¹ preferably has 1 to 6 carbon atoms, and specific examples thereof include a group obtained by substituting at least one hydrogen atom in the alkyl group as Ra′²¹ with a hydroxyl group.

In General Formulae (a2-r-2), (a2-r-3) and (a2-r-5), as the alkylene group having 1 to 5 carbon atoms as A″, a linear or branched alkylene group is preferable, and examples thereof include a methylene group, an ethylene group, an n-propylene group, and an isopropylene group. Specific examples of the alkylene groups that contain an oxygen atom or a sulfur atom include a group obtained by interposing —O— or —S— in the terminal of the alkylene group or between the carbon atoms of the alkylene group, and examples thereof include O—CH₂—, —CH₂—O—CH₂—, —S—CH₂—, and —CH₂—S—CH₂—. A″ is preferably an alkylene group having 1 to 5 carbon atoms or —O—, more preferably an alkylene group having 1 to 5 carbon atoms, and most preferably a methylene group.

Specific examples of the groups each represented by General Formulae (a2-r-1) to (a2-r-7) are shown below.

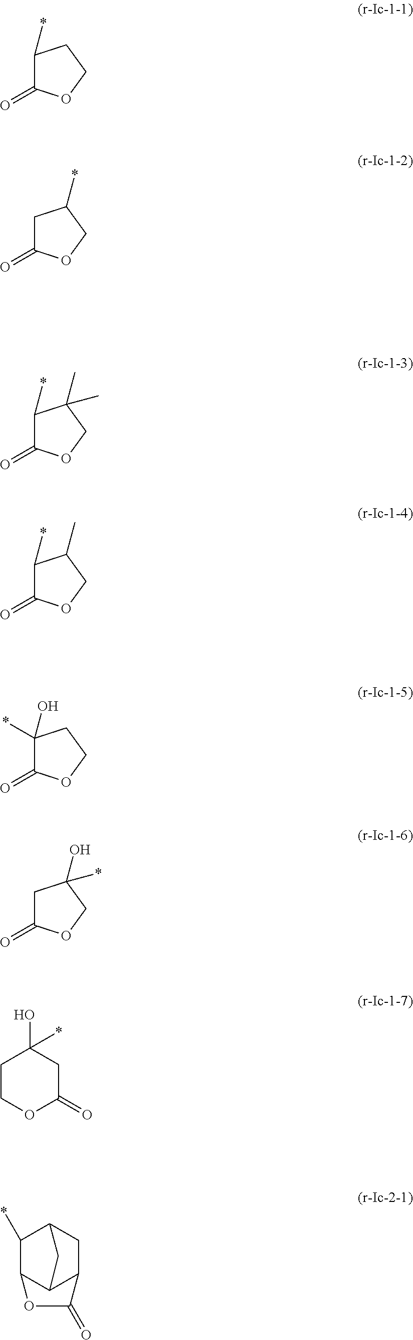

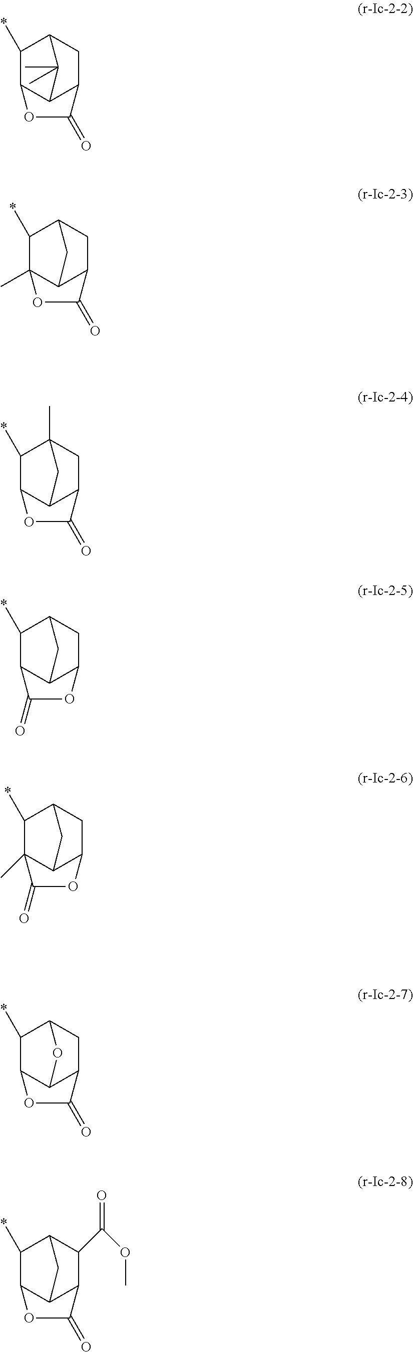

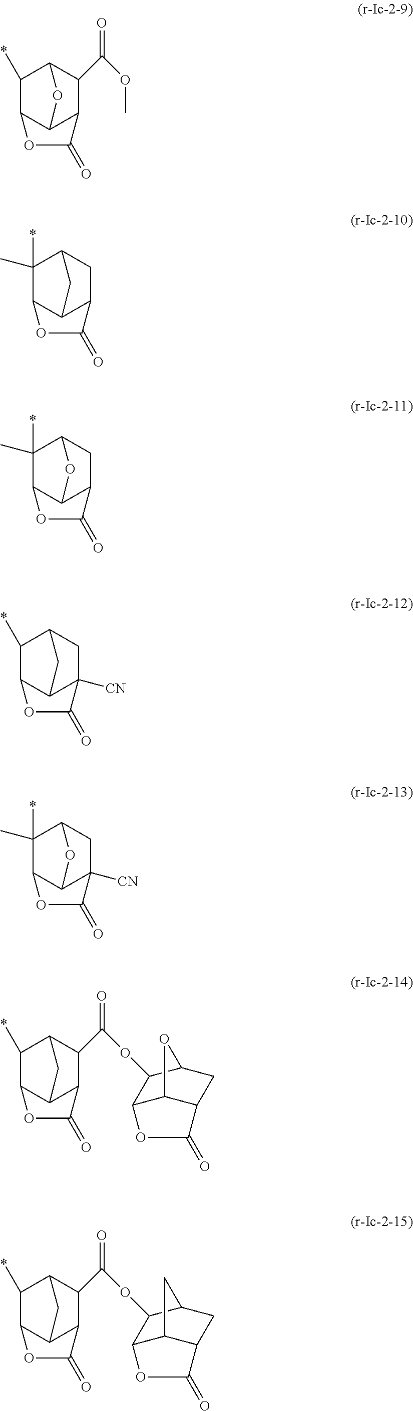

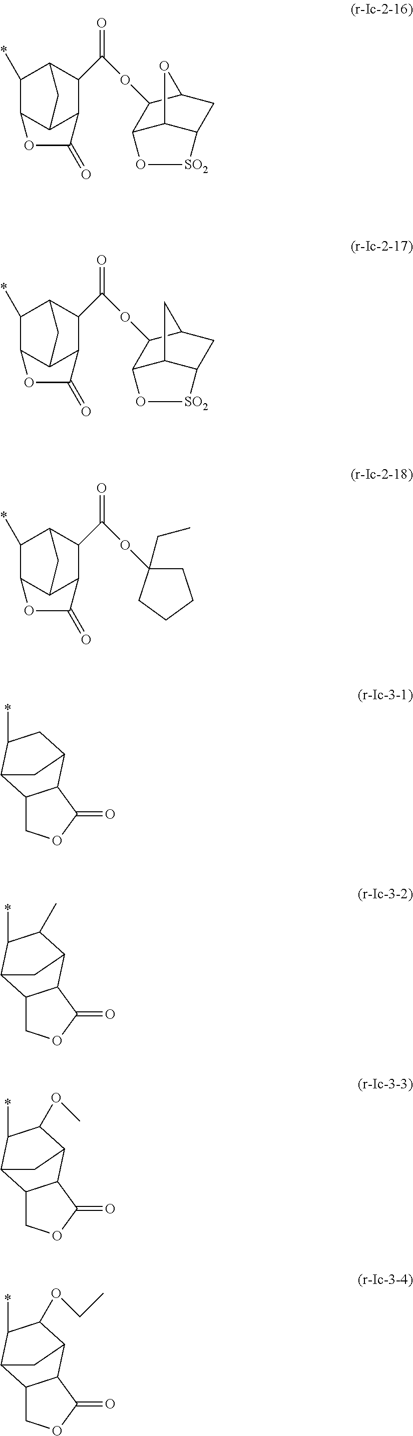

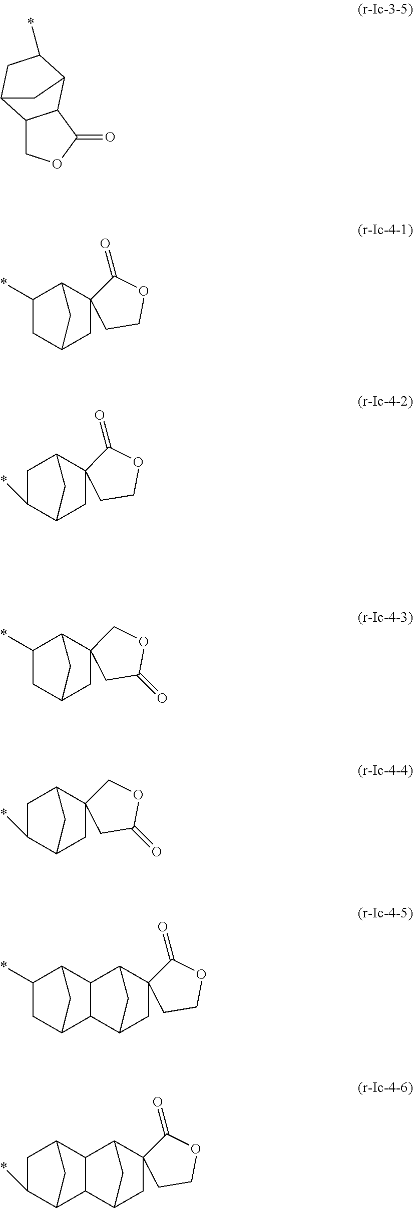

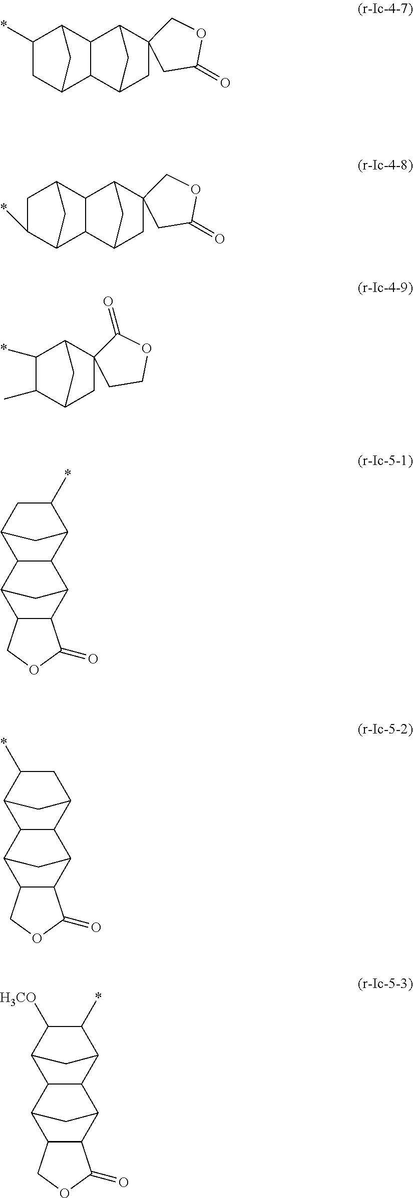

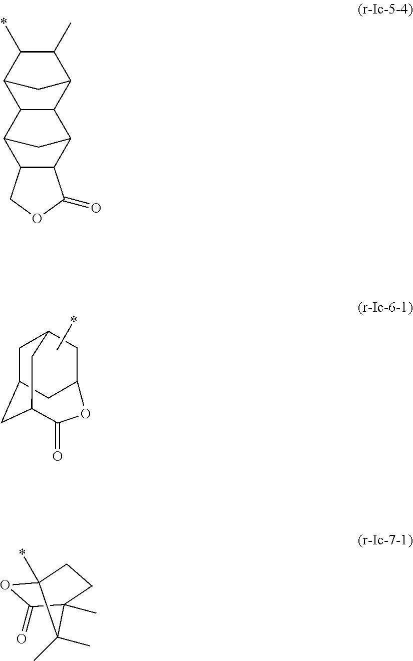

The “—SO₂—-containing cyclic group” indicates a cyclic group having a ring containing —SO₂— in the ring skeleton thereof. Specifically, the —SO₂—-containing cyclic group is a cyclic group in which the sulfur atom (S) in —SO₂— forms a part of the ring skeleton of the cyclic group. In a case where a ring containing —SO₂— in the ring skeleton thereof is counted as the first ring and the group contains only the ring, the group is referred to as a monocyclic group. In a case where the group further has other ring structures, such a group is referred to as a polycyclic group regardless of the structures. The —SO₂—-containing cyclic group may be a monocyclic group or a polycyclic group.

Particularly, the —SO₂—-containing cyclic group is preferably a cyclic group containing —O—SO₂— in the ring skeleton thereof, in other words, a cyclic group containing a sultone ring in which —O—S— in the —O—SO₂— group forms a part of the ring skeleton thereof.

More specific examples of the —SO₂—-containing cyclic group include groups each represented by General Formulae (a5-r-1) to (a5-r-4) shown below.

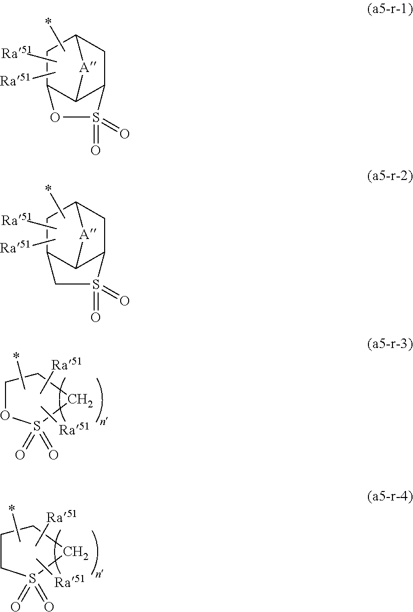

[In the formulae, each Ra′⁵¹ independently represents a hydrogen atom, an alkyl group, an alkoxy group, a halogen atom, a halogenated alkyl group, a hydroxyl group, —COOR″, —OC(═O)R″, a hydroxyalkyl group, or a cyano group; R″ represents a hydrogen atom, an alkyl group, a lactone-containing cyclic group, a carbonate-containing cyclic group, or a —SO₂—-containing cyclic group; A″ represents an oxygen atom, a sulfur atom, or an alkylene group having 1 to 5 carbon atoms, which may contain an oxygen atom or a sulfur atom; and n′ represents an integer in a range of 0 to 2.]

In General Formulae (a5-r-1) and (a5-r-2), A″ has the same definition as that for A″ in General Formulae (a2-r-2), (a2-r-3) and (a2-r-5).

Examples of the alkyl group, the alkoxy group, the halogen atom, the halogenated alkyl group, —COOR″, —OC(═O)R″, and the hydroxyalkyl group, as Ra′⁵¹, include the same ones as those mentioned in the explanation of Ra′²¹ in General Formulae (a2-r-1) to (a2-r-7).

Specific examples of the groups each represented by General Formulae (a5-r-1) to (a5-r-4) are shown below. In the formulae shown below, “Ac” represents an acetyl group.

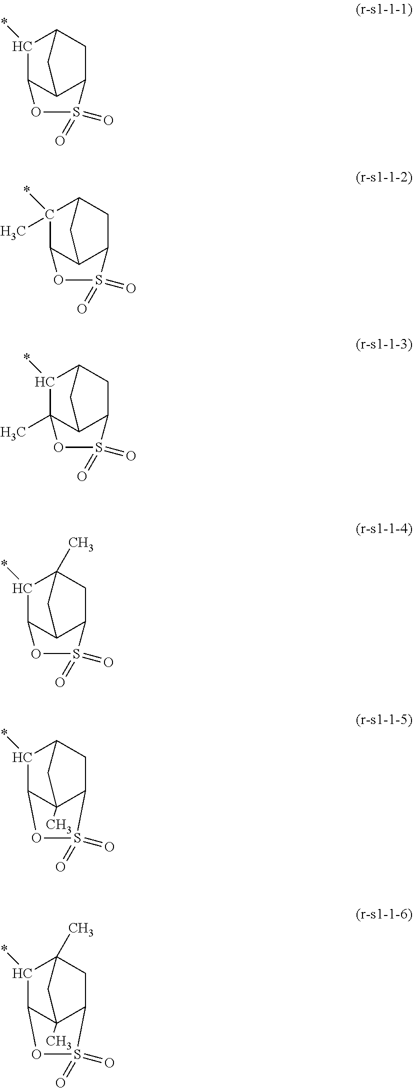

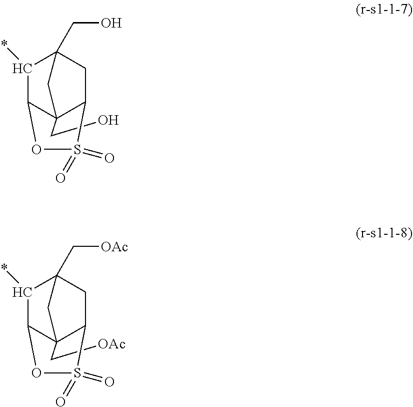

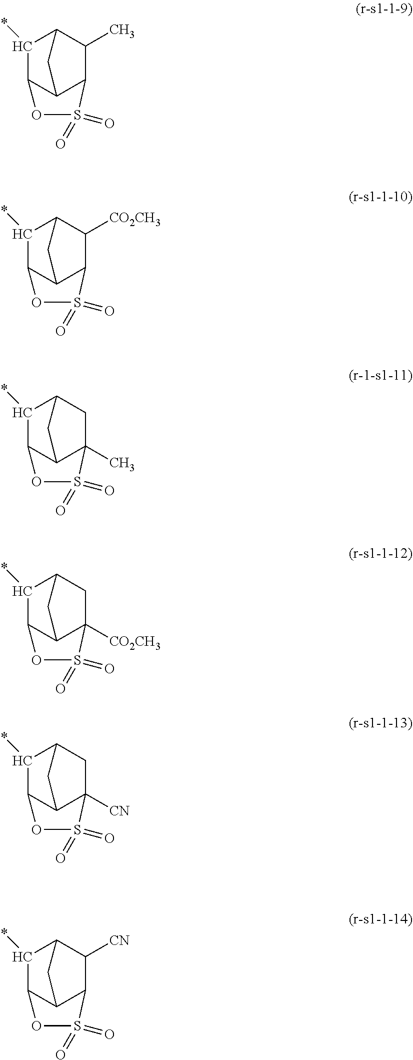

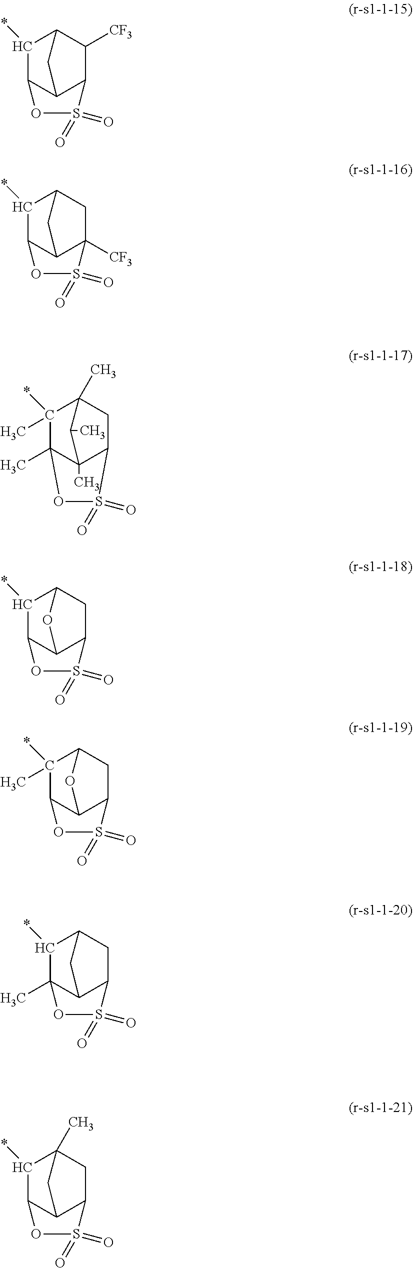

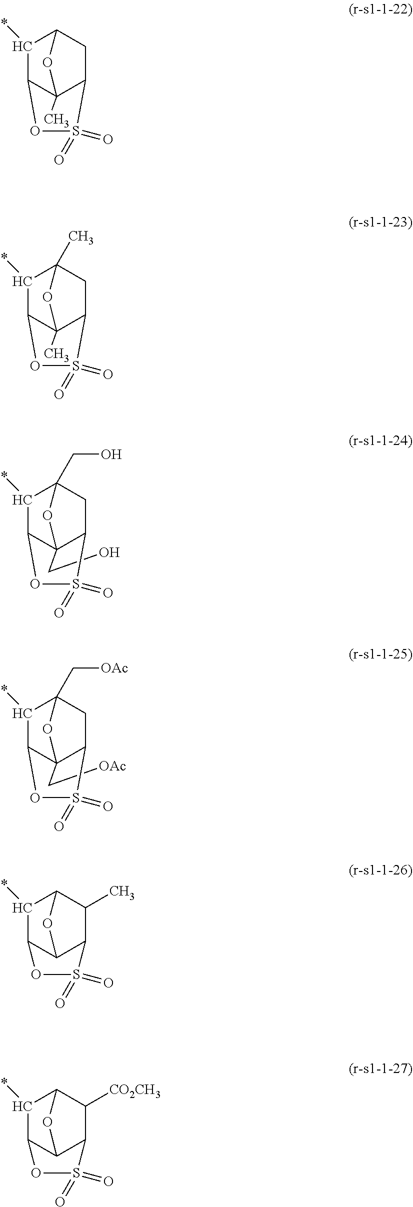

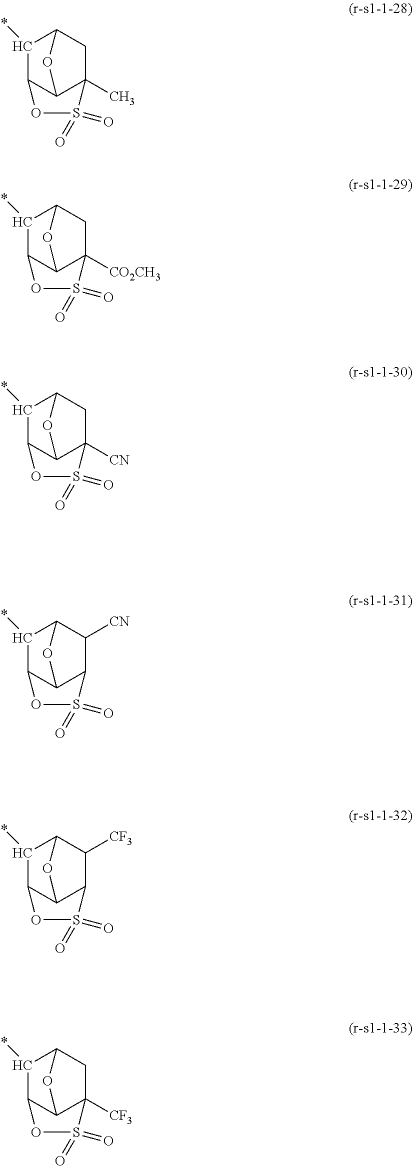

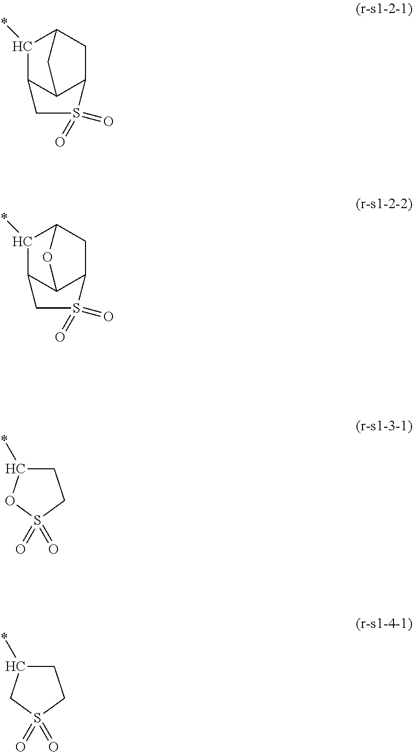

The “carbonate-containing cyclic group” indicates a cyclic group having a ring (a carbonate ring) containing —O—C(═O)—O— in the ring skeleton thereof. In a case where the carbonate ring is counted as the first ring and the group contains only the carbonate ring, the group is referred to as a monocyclic group. Further, in a case where the group has other ring structures, the group is referred to as a polycyclic group regardless of the structures. A carbonate-containing cyclic group may be a monocyclic group or a polycyclic group.

The carbonate ring-containing cyclic group is not particularly limited, and any carbonate ring-containing cyclic group may be used. Specific examples thereof include groups each represented by General Formulae (ax3-r-1) to (ax3-r-3) shown below.

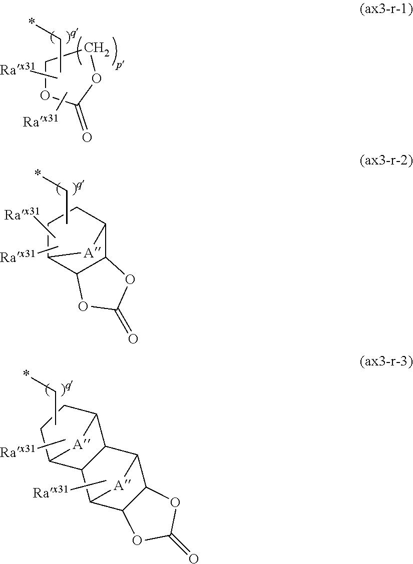

[In the formulae, Ra′^{x31}s independently represent a hydrogen atom, an alkyl group, an alkoxy group, a halogen atom, a halogenated alkyl group, a hydroxyl group, —COOR″, —OC(═O)R″, a hydroxyalkyl group, or a cyano group; R″ represents a hydrogen atom, an alkyl group, a lactone-containing cyclic group, a carbonate-containing cyclic group, or a —SO₂—-containing cyclic group; A″ represents an oxygen atom, a sulfur atom, or an alkylene group having 1 to 5 carbon atoms, which may contain an oxygen atom or a sulfur atom; and p′ represents an integer in a range of 0 to 3, and q′ is 0 or 1.]

In General Formulae (ax3-r-2) and (ax3-r-3), A″ has the same definition as that for A″ in General Formulae (a2-r-2), (a2-r-3), and (a2-r-5).

Examples of the alkyl group, the alkoxy group, the halogen atom, the halogenated alkyl group, —COOR″, —OC(═O)R″, and the hydroxyalkyl group, as Ra′³¹, include the same ones as those described in the explanation Ra′²¹ in General Formulae (a2-r-1) to (a2-r-7).

Specific examples of groups each represented by General Formulae (ax3-r-1) to (ax3-r-3) are shown below.

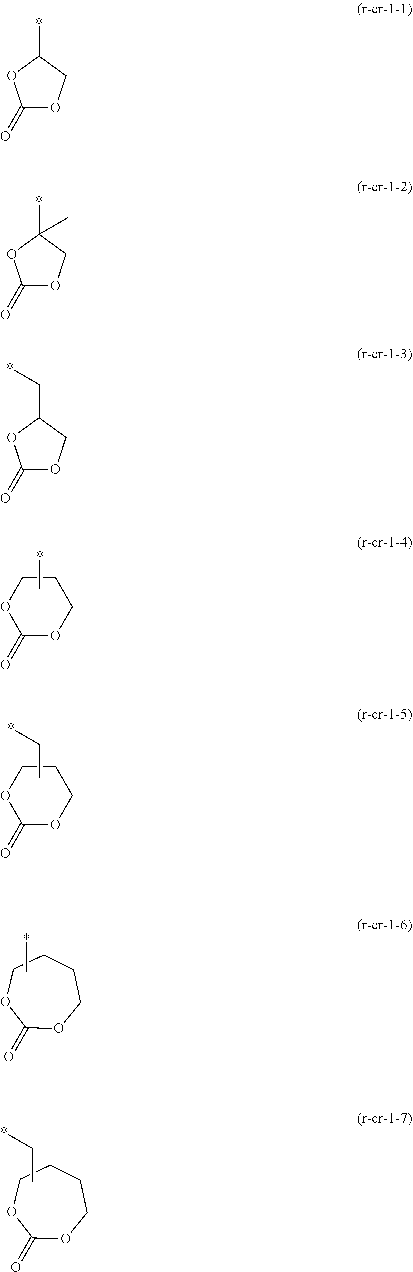

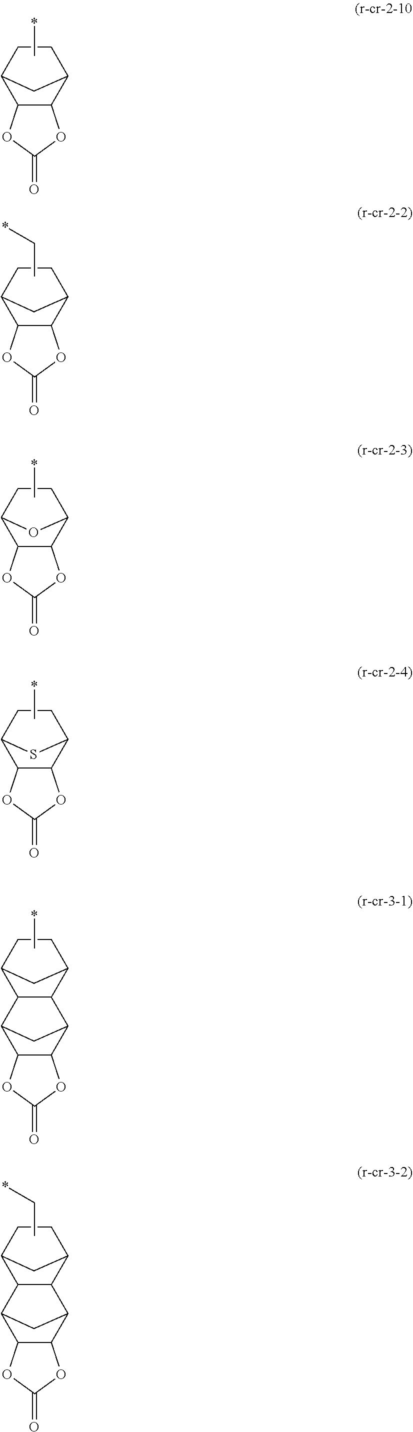

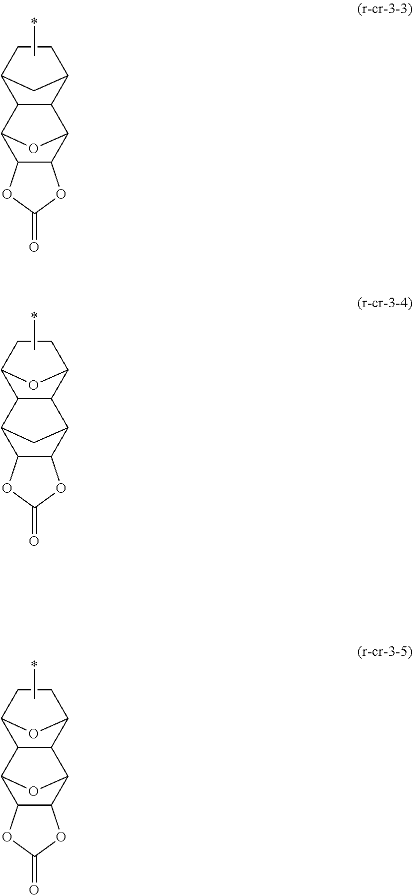

Among them, the constitutional unit (a2) is preferably a constitutional unit derived from acrylic acid ester in which the hydrogen atom bonded to the carbon atom at the α-position may be substituted with a substituent.

The constitutional unit (a2) is preferably a constitutional unit represented by General Formula (a2-1).

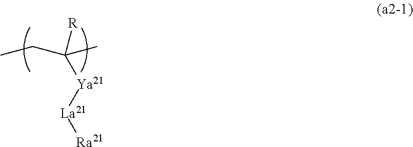

[In the formula, R represents a hydrogen atom, an alkyl group having 1 to 5 carbon atoms, or a halogenated alkyl group having 1 to 5 carbon atoms. Ya²¹ represents a single bond or a divalent linking group. La²¹ represents —O—, —COO—, —CON(R′)—, —OCO—, —CONHCO— or —CONHCS—, and R′ represents a hydrogen atom or a methyl group. However, in a case where La²¹ represents —O—, Ya²¹ does not represent —CO—. Ra²¹ represents a lactone-containing cyclic group, a carbonate-containing cyclic group, or a —SO₂—-containing cyclic group.]

In General Formula (a2-1), R has the same definition as described above. R is preferably a hydrogen atom, an alkyl group having 1 to 5 carbon atoms, or a fluorinated alkyl group having 1 to 5 carbon atoms, and particularly preferably a hydrogen atom or a methyl group in terms of industrial availability.

In General Formula (a2-1), the divalent linking group as Ya²¹ is not particularly limited, and suitable examples thereof include a divalent hydrocarbon group which may have a substituent and a divalent linking group having a hetero atom.
Divalent hydrocarbon group which may have substituent:

In a case where Ya²¹ represents a divalent hydrocarbon group which may have a substituent, the hydrocarbon group may be an aliphatic hydrocarbon group or an aromatic hydrocarbon group.
Aliphatic hydrocarbon group as Ya²¹

The aliphatic hydrocarbon group indicates a hydrocarbon group that has no aromaticity. The aliphatic hydrocarbon group may be saturated or unsaturated. In general, it is preferable that the aliphatic hydrocarbon group is saturated.

Examples of the aliphatic hydrocarbon group include a linear or branched aliphatic hydrocarbon group, and an aliphatic hydrocarbon group containing a ring in the structure thereof.
Linear or branched aliphatic hydrocarbon group

The linear aliphatic hydrocarbon group preferably has 1 to 10 carbon atoms, more preferably 1 to 6 carbon atoms, still more preferably 1 to 4 carbon atoms, and most preferably 1 to 3 carbon atoms.

The linear aliphatic hydrocarbon group is preferably a linear alkylene group, and specific examples thereof include a methylene group [—CH₂—], an ethylene group [—(CH₂)₂—], a trimethylene group [—(CH₂)₃—], a tetramethylene group [—(CH₂)₄—], and a pentamethylene group [—(CH₂)₅—].

The branched aliphatic hydrocarbon group has preferably 2 to 10 carbon atoms, more preferably 3 to 6 carbon atoms, still more preferably 3 or 4 carbon atoms, and most preferably 3 carbon atoms.

The branched aliphatic hydrocarbon group is preferably a branched alkylene group, and specific examples thereof include alkylalkylene groups, for example, alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)—, and —C(CH₂CH₃)₂—; alkylethylene groups such as —CH(CH₃)CH₂—, —CH(CH₃)CH(CH₃)—, —C(CH₃)₂CH₂—, —CH(CH₂CH₃)CH₂—, and —C(CH₂CH₃)₂—CH₂—; alkyltrimethylene groups such as —CH(CH₃)CH₂CH₂—, and —CH₂CH(CH₃)CH₂—; and alkyltetramethylene groups such as —CH(CH₃)CH₂CH₂CH₂—, and —CH₂CH(CH₃)CH₂CH₂—. The alkyl group in the alkylalkylene group is preferably a linear alkyl group having 1 to 5 carbon atoms.

The linear or branched aliphatic hydrocarbon group may or may not have a substituent. Examples of the substituent include a fluorine atom, a fluorinated alkyl group having 1 to 5 carbon atoms, which has been substituted with a fluorine atom, and a carbonyl group.
Aliphatic hydrocarbon group containing ring in structure thereof

Examples of the aliphatic hydrocarbon group containing a ring in the structure thereof include a cyclic aliphatic hydrocarbon group which may contain a substituent containing a hetero atom in the ring structure thereof (a group obtained by removing two hydrogen atoms from an aliphatic hydrocarbon ring), a group obtained by bonding a cyclic aliphatic hydrocarbon group to the terminal of a linear or branched aliphatic hydrocarbon group, and a group obtained by interposing a cyclic aliphatic hydrocarbon group in a linear or branched aliphatic hydrocarbon group. Examples of the linear or branched aliphatic hydrocarbon group include the same ones as those described above.

The cyclic aliphatic hydrocarbon group preferably has 3 to 20 carbon atoms and more preferably 3 to 12 carbon atoms.

The cyclic aliphatic hydrocarbon group may be a polycyclic group or a monocyclic group. The monocyclic alicyclic hydrocarbon group is preferably a group obtained by removing two hydrogen atoms from a monocycloalkane. The monocycloalkane preferably has 3 to 6 carbon atoms, and specific examples thereof include cyclopentane and cyclohexane. The polycyclic alicyclic hydrocarbon group is preferably a group obtained by removing two hydrogen atoms from a polycycloalkane, and the polycycloalkane is preferably a group having 7 to 12 carbon atoms. Specific examples of the polycyclic alicyclic hydrocarbon group include adamantane, norbornane, isobornane, tricyclodecane, and tetracyclododecane.

A cyclic aliphatic hydrocarbon group may or may not have a substituent. Examples of the substituent include an alkyl group, an alkoxy group, a halogen atom, a halogenated alkyl group, a hydroxyl group, and a carbonyl group.

The alkyl group as the substituent is preferably an alkyl group having 1 to 5 carbon atoms, and more preferably a methyl group, an ethyl group, a propyl group, an n-butyl group, or a tert-butyl group.

The alkoxy group as the substituent is preferably an alkoxy group having 1 to 5 carbon atoms, more preferably a methoxy group, an ethoxy group, an n-propoxy group, an iso-propoxy group, an n-butoxy group, or a tert-butoxy group, and still more preferably a methoxy group or an ethoxy group.

Examples of the halogen atom for the substituent include a fluorine atom, a chlorine atom, a bromine atom, and an iodine atom, and a fluorine atom is preferable.

Examples of the halogenated alkyl group as the substituent include a group obtained by substituting part or all of hydrogen atoms in the above-described alkyl group with the above-described halogen atom.

In the cyclic aliphatic hydrocarbon group, part of carbon atoms constituting the ring structure thereof may be substituted with a substituent containing a hetero atom. The substituent containing a hetero atom is preferably —O—, —C(═O)—O—, —S—, —S(═O)₂—, or —S(═O)₂—O—.
Aromatic hydrocarbon group as Ya²¹

The aromatic hydrocarbon group is a hydrocarbon group having at least one aromatic ring.

The aromatic ring is not particularly limited as long as it is a cyclic conjugated system having (4n+2) π electrons, and may be monocyclic or polycyclic. The aromatic ring preferably has 5 to 30 carbon atoms, more preferably 5 to 20 carbon atoms, still more preferably 6 to 15 carbon atoms, and particularly preferably 6 to 12 carbon atoms. However, the number of carbon atoms in the substituent is not included in the number of carbon atoms.

Specific examples of the aromatic ring include aromatic hydrocarbon rings such as benzene, naphthalene, anthracene, and phenanthrene; and an aromatic heterocyclic ring obtained by substituting part of carbon atoms constituting the above-described aromatic hydrocarbon ring with a hetero atom. Examples of the hetero atom in the aromatic heterocyclic rings include an oxygen atom, a sulfur atom, and a nitrogen atom. Specific examples of the aromatic heterocyclic ring include a pyridine ring and a thiophene ring.

Specific examples of the aromatic hydrocarbon group include a group (an arylene group or a heteroarylene group) obtained by removing two hydrogen atoms from the above-described aromatic hydrocarbon ring or the above-described aromatic heterocyclic ring; a group obtained by removing two hydrogen atoms from an aromatic compound having two or more aromatic rings (such as biphenyl or fluorene); and a group (for example, a group obtained by further removing one hydrogen atom from an aryl group in arylalkyl groups such as a benzyl group, a phenethyl group, a 1-naphthylmethyl group, a 2-naphthylmethyl group, a 1-naphthylethyl group, or a 2-naphthylethyl group) obtained by substituting one hydrogen atom of a group (an aryl group or a heteroaryl group) obtained by removing one hydrogen atom from the above aromatic hydrocarbon ring or the above aromatic heterocyclic ring, with an alkylene group. The alkylene group bonded to the aryl group or the heteroaryl group preferably has 1 to 4 carbon atoms, more preferably 1 or 2 carbon atoms, and particularly preferably 1 carbon atom.

With respect to the aromatic hydrocarbon group, the hydrogen atom contained in the aromatic hydrocarbon group may be substituted with a substituent. For example, the hydrogen atom bonded to the aromatic ring in the aromatic hydrocarbon group may be substituted with a substituent. Examples of substituents include an alkyl group, an alkoxy group, a halogen atom, a halogenated alkyl group, and a hydroxyl group.

The alkyl group as the substituent is preferably an alkyl group having 1 to 5 carbon atoms, and more preferably a methyl group, an ethyl group, a propyl group, an n-butyl group, or a tert-butyl group.

Examples of the alkoxy group, the halogen atom, and the halogenated alkyl group, as the substituent, include the same groups as those exemplified as the substituent that is substituted for a hydrogen atom contained in the cyclic aliphatic hydrocarbon group.
Divalent linking group containing hetero atom:

In a case where Ya²¹ represents a divalent linking group containing a hetero atom, preferred examples of the linking group include —O—, —C(═O)—O—, —O—C(═O)—, —C(═O)—, —O—C(═O)—O—, —C(═O)—NH—, —NH—, —NH—C(═NH)-(H may be substituted with a substituent such as an alkyl group, an acyl group, or the like), —S—, —S(═O)₂—, —S(═O)₂—O—, and a group represented by General Formula —Y²¹—O—Y²²—, —Y²¹—O—, —Y²¹—O—, —Y²¹—C(═O)—O—, —C(═O)—O—Y²¹—, —[Y²¹—C(═O)—O]_{m″}—Y²²—, —Y²¹—O—C(═O)—Y²²— or Y²¹—S(═O)₂—O—Y²²— [in the formulae, Y²¹ and Y²² each independently represent a divalent hydrocarbon group which may have a substituent, 0 represents an oxygen atom, and m″ represents an integer in a range of 0 to 3].

In a case where the divalent linking group containing a hetero atom is —C(═O)—NH—, —C(═O)—NH—C(═O)—, —NH—, or —NH—C(═NH)—, H may be substituted with a substituent such as an alkyl group, an acyl group, or the like. The substituent (an alkyl group, an acyl group, or the like) preferably has 1 to 10 carbon atoms, more preferably 1 to 8 carbon atoms, and particularly preferably 1 to 5 carbon atoms.

In General Formulae Y²¹—O—Y²²—, —Y²¹—O—, —Y²¹—C(═O)—O—, —C(═O)—O—Y²¹—, —[Y²¹—C(═O)—O]_{m″}—Y²², —Y²¹—O—C(═O)—Y²²—, and —Y²¹—S(═O)₂—O—Y²²—, Y²¹, and Y²² each independently represent a divalent hydrocarbon group which may have a substituent. Examples of the divalent hydrocarbon group include the same one as “the divalent hydrocarbon groups which may have a substituent”, described in the explanation of the above-described divalent linking group as Ya²¹.

Y²¹ is preferably a linear aliphatic hydrocarbon group, more preferably a linear alkylene group, still more preferably a linear alkylene group having 1 to 5 carbon atoms, and particularly preferably a methylene group or an ethylene group.

Y²² is preferably a linear or branched aliphatic hydrocarbon group and more preferably a methylene group, an ethylene group, or an alkylmethylene group. The alkyl group in the alkylmethylene group is preferably a linear alkyl group having 1 to 5 carbon atoms, more preferably a linear alkyl group having 1 to 3 carbon atoms, and most preferably a methyl group.

In the group represented by General Formula —[Y²¹—C(═O)—O]_{m″}—Y²²—, m″ represents an integer in a range of 0 to 3, preferably an integer in a range of 0 to 2, more preferably 0 or 1, and particularly preferably 1. In other words, it is particularly preferable that the group represented by General Formula —[Y²¹—C(═O)—O]ₘ⁻—Y²²— represents a group represented by General Formula —Y²¹—C(═O)—O—Y²²—. Among these, a group represented by General Formula —(CH₂)_{a′}—C(═O)—O—(CH₂)_{b′}— is preferable. In the formula, a′ represents an integer in a range of 1 to 10, preferably an integer in a range of 1 to 8, more preferably an integer in a range of 1 to 5, still more preferably 1 or 2, and most preferably 1. b′ represents an integer in a range of 1 to 10, preferably an integer in a range of 1 to 8, more preferably an integer in a range of 1 to 5, still more preferably 1 or 2, and most preferably 1.

Among the above, Ya²¹ is preferably a single bond, an ester bond [—C(═O)—O—], an ether bond (—O—), a linear or branched alkylene group, or a combination thereof.

In General Formula (a2-1), Ra²¹ represents a lactone-containing cyclic group, a —SO₂—-containing cyclic group, or a carbonate-containing cyclic group.

Suitable examples of the lactone-containing cyclic group, the —SO₂—-containing cyclic group, and the carbonate-containing cyclic group as Ra²¹ include groups each represented by General Formulae (a2-r-1) to (a2-r-7), groups each represented by General Formulae (a5-r-1) to (a5-r-4), and groups each represented by General Formulae (ax3-r-1) to (ax3-r-3) described above.

Among them, a lactone-containing cyclic group or a —SO₂—-containing cyclic group is preferable, and any one of groups each represented by General Formula (a2-r-1), (a2-r-2), (a2-r-6), or (a5-r-1) is more preferable. Specifically, any one of groups each represented by Chemical Formulae (r-1c-1-1) to (r-1c-1-7), (r-1c-2-1) to (r-1c-2-18), (r-1c-6-1), (r-s1-1-1), and (r-s1-1-18) are more preferable.

The constitutional unit (a2) contained in the component (A1) may be one kind or may be two or more kinds.

In a case where the component (A1) has the constitutional unit (a2), the proportion of the constitutional unit (a2) in the component (A1) is preferably in a range of 5% to 60% by mole, more preferably in a range of 10% to 60% by mole, still more preferably in a range of 20% to 55% by mole, and particularly preferably in a range of 30% to 50% by mole with respect to the total (100% by mole) of all constitutional units constituting the component (A1).

In a case where the proportion of the constitutional unit (a2) is set to be equal to or larger than the preferred lower limit value of the above-described preferred range, the effect obtained by allowing the component (A1) to contain the constitutional unit (a2) can be sufficiently achieved by the effect described above. In a case where the proportion of the constitutional unit (a2) is equal to or smaller than the upper limit value of the above-described preferred range, balance with other constitutional units can be obtained, and various lithography characteristics are improved.

In regard to constitutional unit (a3):

The component (A1) may further have, as necessary, a constitutional unit (a3) (provided that a constitutional unit corresponding to the constitutional unit (a1) or the constitutional unit (a2) is excluded) containing a polar group-containing aliphatic hydrocarbon group, in addition to the constitutional unit (a1). In a case where the component (A1) has the constitutional unit (a3), the hydrophilicity of the component (A) is increased, which contributes to an improvement in resolution. Further, acid diffusion length can be properly adjusted.

Examples of the polar group include a hydroxyl group, a cyano group, a carboxy group, or a hydroxyalkyl group obtained by substituting part of hydrogen atoms of the alkyl group with a fluorine atom, and the polar group is particularly preferably a hydroxyl group.

Examples of the aliphatic hydrocarbon group include a linear or branched hydrocarbon group (preferably an alkylene group) having 1 to 10 carbon atoms, and a cyclic aliphatic hydrocarbon group (a cyclic group). The cyclic group may be a monocyclic group or a polycyclic group. For example, these cyclic groups can be appropriately selected from a large number of groups that have been proposed in resins for a resist composition for an ArF excimer laser.

In a case where the cyclic group is a monocyclic group, the monocyclic group more preferably has 3 to 10 carbon atoms. Among them, a constitutional unit derived from an acrylic acid ester that includes an aliphatic monocyclic group containing a hydroxyl group, cyano group, carboxy group, or a hydroxyalkyl group obtained by substituting part of hydrogen atoms of the alkyl group with a fluorine atom is more preferable. Examples of the monocyclic group include a group obtained by removing two or more hydrogen atoms from a monocycloalkane. Specific examples of the monocyclic group include a group obtained by removing two or more hydrogen atoms from a monocycloalkane such as cyclopentane, cyclohexane, or cyclooctane. Among these monocyclic groups, a group obtained by removing two or more hydrogen atoms from cyclopentane or a group obtained by removing two or more hydrogen atoms from cyclohexane are industrially preferable.

In a case where the cyclic group is a polycyclic group, the polycyclic group more preferably has 7 to 30 carbon atoms. Among them, a constitutional unit derived from an acrylic acid ester that includes an aliphatic polycyclic group containing a hydroxyl group, cyano group, carboxy group, or a hydroxyalkyl group obtained by substituting part of hydrogen atoms of the alkyl group with a fluorine atom is more preferable. Examples of the polycyclic group include a group obtained by removing two or more hydrogen atoms from a bicycloalkane, a tricycloalkane, a tetracycloalkane, or the like. Specific examples thereof include a group obtained by removing two or more hydrogen atoms from a polycycloalkane such as adamantane, norbornane, isobornane, tricyclodecane, or tetracyclododecane. Among these polycyclic groups, a group obtained by removing two or more hydrogen atoms from adamantane, a group obtained by removing two or more hydrogen atoms from norbornane, or a group obtained by removing two or more hydrogen atoms from tetracyclododecane are industrially preferable.

The constitutional unit (a3) is not particularly limited, and any constitutional unit may be used as long as the constitutional unit contains a polar group-containing aliphatic hydrocarbon group.

The constitutional unit (a3) is preferably a constitutional unit derived from an acrylic acid ester in which the hydrogen atom bonded to the carbon atom at the α-position may be substituted with a substituent, where the constitutional unit contains a polar group-containing aliphatic hydrocarbon group.

In a case where the hydrocarbon group in the polar group-containing aliphatic hydrocarbon group is a linear or branched hydrocarbon group having 1 to 10 carbon atoms, the constitutional unit (a3) is preferably a constitutional unit derived from a hydroxyethyl ester of acrylic acid.

Further, as the constitutional unit (a3), in a case where the hydrocarbon group in the polar group-containing aliphatic hydrocarbon group is a polycyclic group, a constitutional unit represented by General Formula (a3-1), a constitutional unit represented by General Formula (a3-2), or a constitutional unit represented by General Formula (a3-3) is preferable, and in a case where the hydrocarbon group is a monocyclic group, a constitutional unit represented by General Formula (a3-4) is preferable.

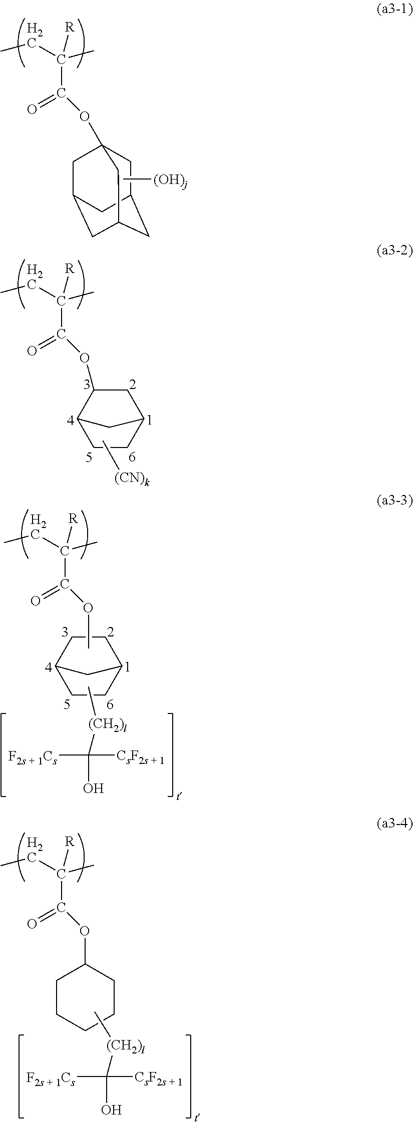

[In the formulae, R has the same definition as described above, j represents an integer in a range of 1 to 3, k represents an integer in a range of 1 to 3, t′ represents an integer in a range of 1 to 3, 1 represents an integer in a range of 0 to 5, and s represents an integer in a range of 1 to 3.]

In General Formula (a3-1), j preferably represents 1 or 2 and more preferably 1. In a case where j represents 2, it is preferable that the hydroxyl groups are bonded to the 3-position and 5-position of the adamantyl group. In a case where j represents 1, it is preferable that the hydroxyl group is bonded to the 3-position of the adamantyl group.

It is preferable that j represents 1, and it is particularly preferable that the hydroxyl group is bonded to the 3-position of the adamantyl group.

In General Formula (a3-2), k preferably represents 1. The cyano group is preferably bonded to the 5-position or 6-position of the norbornyl group.

In General Formula (a3-3), it is preferable that t′ represents 1. It is preferable that 1 represents 1. It is preferable that s represents 1. Further, it is preferable that a 2-norbornyl group or 3-norbornyl group is bonded to the terminal of the carboxy group of the acrylic acid. It is preferable that the fluorinated alkyl alcohol is bonded to the 5-position or 6-position of the norbornyl group.

In General Formula (a3-4), it is preferable that t′ represents 1 or 2. 1 is preferably 0 or 1. It is preferable that s represents 1. It is preferable that the fluorinated alkyl alcohol is bonded to the 3-position or 5-position of the cyclohexyl group.

The constitutional unit (a3) contained in the component (A1) may be one kind or may be two or more kinds.

In a case where the component (A1) has the constitutional unit (a3), the proportion of the constitutional unit (a3) is preferably in a range of 1% to 30% by mole, more preferably in a range of 2% to 25% by mole, and still more preferably in a range of 5% to 20% by mole, with respect to the total (100% by mole) of all constitutional units constituting the component (A1).

In a case where the proportion of the constitutional unit (a3) is set to be equal to or larger than the lower limit value of the preferred range, the effect obtained by allowing the constitutional unit (a3) to be contained can be sufficiently achieved by the effect described above. In a case where it is set to be equal to or smaller than the upper limit value of the preferred range, the balance with other constitutional units can be obtained, and various lithography characteristics are improved.

In regard to constitutional unit (a4):

The component (A1) may further have, in addition to the constitutional unit (a1), a constitutional unit (a4) containing an acid non-dissociable aliphatic cyclic group.

In a case where the component (A1) has the constitutional unit (a4), the dry etching resistance of the formed resist pattern is improved. Further, the hydrophobicity of the component (A) increases. The improvement in hydrophobicity contributes to the improvement in resolution, a resist pattern shape, and the like, particularly in the case of a solvent developing process.

The “acid non-dissociable cyclic group” in the constitutional unit (a4) is a cyclic group that remains in the constitutional unit without being dissociated even when an acid acts in a case where the acid is acid generated upon exposure in the resist composition (for example, in a case where acid is generated from the constitutional unit or the component (B) that generates acid upon exposure).

Examples of the constitutional unit (a4) preferably include a constitutional unit derived from an acrylic acid ester including an acid non-dissociable aliphatic cyclic group. As the cyclic group, many cyclic groups known in the related art as the cyclic groups used as a resin component of a resist composition for ArF excimer laser, KrF excimer laser (preferably KrF excimer laser), or the like can be used.

The cyclic group is particularly preferably at least one selected from a cyclohexyl group, a tricyclodecyl group, an adamantyl group, a tetracyclododecyl group, an isobornyl group, and a norbornyl group, from the viewpoint of industrial availability. These cyclic groups may have, as a substituent, a linear or branched alkyl group having 1 to 5 carbon atoms.

Specific examples of the constitutional unit (a4) include constitutional units each represented by General Formulae (a4-1) to (a4-8).

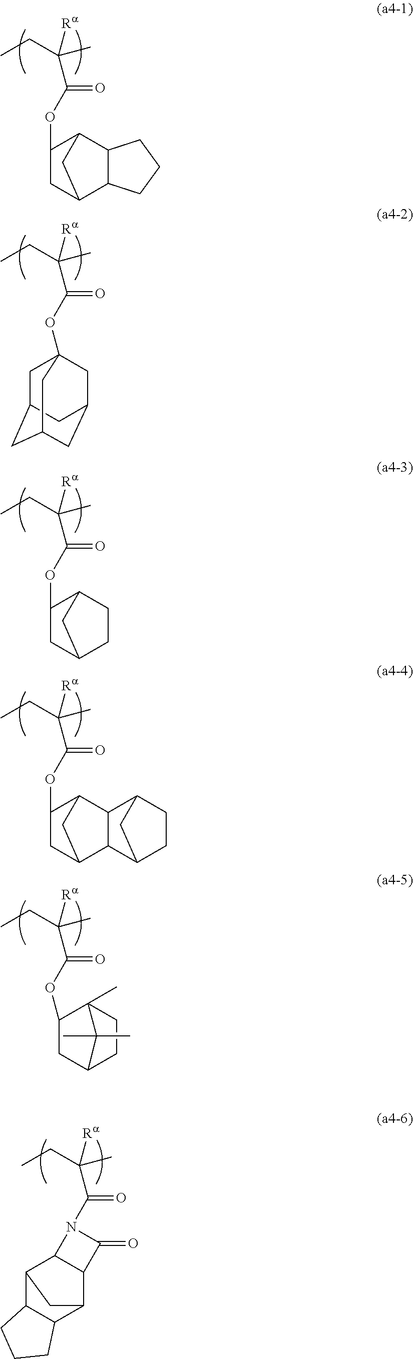

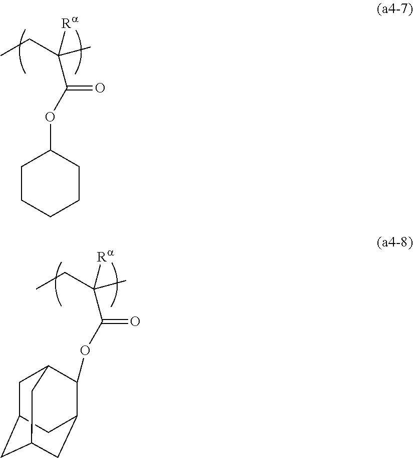

[In the formula, R^{α} is the same as above.]

The constitutional unit (a4) contained in the component (A1) may be one kind or may be two or more kinds.

In a case where the component (A1) has the constitutional unit (a4), the proportion of the constitutional unit (a4) is preferably in a range of 20% to 80% by mole, more preferably in a range of 25% to 75% by mole, and still more preferably in a range of 30% to 70% by mole, with respect to the total (100% by mole) of all constitutional units constituting the component (A1).

In a case where the proportion of the constitutional unit (a4) is set to be equal to or larger than the lower limit value of the preferred range, the effect that is obtained by allowing the constitutional unit (a4) to be contained can be sufficiently achieved. In a case where the proportion of the constitutional unit (a4) is set to be equal to or smaller than the upper limit value of the preferred range, the balance with other constitutional units is obtained easily.

In regard to constitutional unit (a11):

The constitutional unit (a11) is a constitutional unit derived from a compound containing an aromatic ring (excluding an aromatic ring to which a hydroxy group is bonded) in the side chain.

Suitable examples of the compound containing an aromatic ring (excluding an aromatic ring to which a hydroxy group is bonded) in the side chain include a compound represented by General Formula (a11-1).

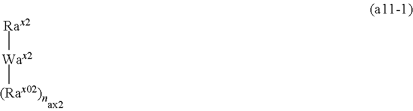

[In General Formula (a11-1), Ra^{x2} represents a polymerizable group-containing group. Wa^{x2} represents an (nₐₓ₂+1)-valent aromatic hydrocarbon group. However, Ra^{x2} and Wa^{x2} may form a condensed ring structure. Ra^{x02} represents a substituent that is substituted for a hydrogen atom constituting Wa^{x2} (an aromatic hydrocarbon group). nₐₓ₂ represents an integer in a range of 0 to 3. In a case where nₐₓ₂ represents 2 or more, a plurality of Ra^{x02}'s may be bonded together to form a ring structure.]

In General Formula (a11-1), Ra^{x2} represents a polymerizable group-containing group.

The “polymerizable group” as Ra^{x2} is a group that enables a compound having the polymerizable group to be polymerized by radical polymerization or the like, and includes a group containing a multiple bond between carbon atoms, such as an ethylenic double bond.

Examples of the polymerizable group include a vinyl group, an allyl group, acryloyl group, a methacryloyl group, a fluorovinyl group, a difluorovinyl group, a difluorovinyl group, a difluorotrifluoromethylvinyl group, a trifluoroallyl group, a perfluoroallyl group, a trifluoromethylacryloyl group, a nonylfluorobutylacryloyl group, a vinyl ether group, a fluorine-containing vinyl ether group, an allyl ether group, a fluorine-containing allyl ether group, a styryl group, and a vinylnaphthyl group, a fluorine-containing styryl group, a fluorine-containing vinylnaphthyl group, a norbornyl group, a fluorine-containing norbornyl group, and a silyl group.

The “polymerizable group-containing group” may be a group composed of only a polymerizable group, or a group composed of a polymerizable group and a group other than the polymerizable group. Examples of the group other than the polymerizable group include a divalent hydrocarbon group which may have a substituent and a divalent linking group containing a hetero atom.

Suitable examples of Ra^{x2} include a group represented by a chemical formula: CH₂═C(R)—Ya^{x0}-. In this chemical formula, R represents a hydrogen atom, an alkyl group having 1 to 5 carbon atoms, or a halogenated alkyl group having 1 to 5 carbon atoms, and Ya^{x0} represents a divalent linking group.

In General Formula (a11-1), Wa^{x2} represents a (nₐₓ₂+1)-valent aromatic hydrocarbon group, and examples thereof include the same one as Wa^{x1} in (a10-1) described above.

However, Ra^{x2} and Wa^{x2} may form a condensed ring structure.

In a case where Ra^{x2} and Wa^{x2} form a condensed ring structure, the condensed ring structure includes an aromatic ring derived from Wa^{x2}. In addition, the multiple bond between carbon atoms of the polymerizable group derived from Ra^{x2} is cleaved to form the main chain of the component (A1). That is, part of carbon atoms constituting the condensed ring constitute the main chain of component (A1).

In General Formula (a11-1), Ra^{x02} represents a substituent that is substituted for a hydrogen atom constituting Wa^{x2} (an aromatic hydrocarbon group).

Examples of the substituent as Ra^{x02} include an alkyl group, an alkoxy group, and an acyloxy group.

The alkyl group as a substituent as Ra^{x02} is preferably an alkyl group having 1 to carbon atoms, and it is more preferably a methyl group, an ethyl group, a propyl group, an n-butyl group, or a tert-butyl group.

The alkoxy group a substituent as Ra^{x02} is preferably an alkoxy group having 1 to 5 carbon atoms, more preferably a methoxy group, an ethoxy group, an n-propoxy group, an iso-propoxy group, an n-butoxy group, or a tert-butoxy group, and particularly preferably a methoxy group or an ethoxy group.

The acyloxy group as a substituent as Ra^{x02} preferably has 2 to 6 carbon atoms, more preferably CH₃C(═O)—O— (an acetoxy group), C₂H₅C(═O)—O—, and particularly preferably CH₃C(═O)—O— (an acetoxy group).

In General Formula (a11-1), nₐₓ₂ represents an integer in a range of 0 to 3, preferably 0,1, or 2, and more preferably 0 or 1.

In a case where nₐₓ₂ represents 2 or more, a plurality of Ra^{x02}'s may be bonded together to form a ring structure. The ring structure formed here may be a hydrocarbon ring or a heterocyclic ring. Examples of the ring structure include a ring structure formed by two Ra^{x02} bonded to the same aromatic ring in Wa^{x2} and one side (a bond between carbon atoms) of this aromatic ring (Wa^{x2}) to which the two Ra⁰²'s are bonded.

Suitable examples of such a constitutional unit (a11) include constitutional units each represented by General Formulae (a11-u1-1) to (a11-u1-6).

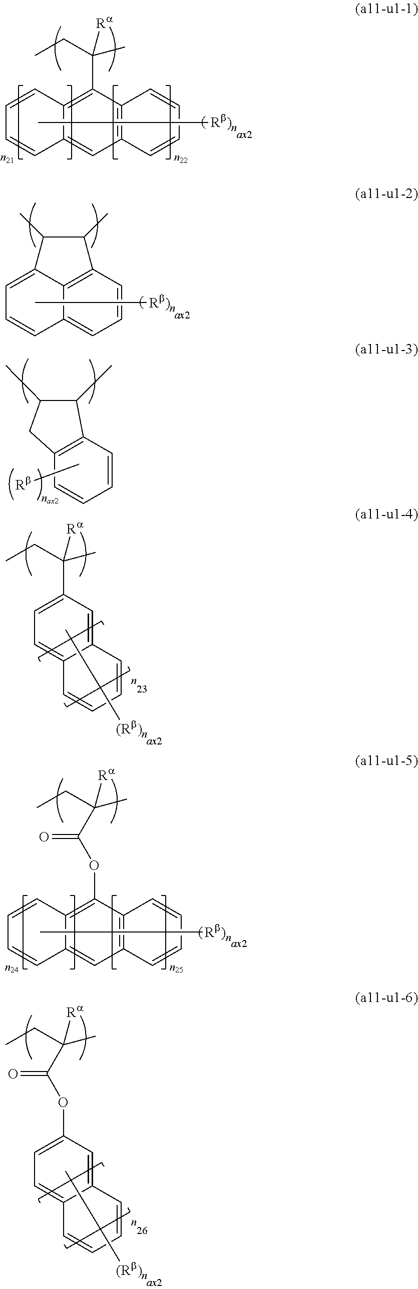

[In the formula, R^{α} represents a hydrogen atom, a methyl group, or a trifluoromethyl group. R^{β} represents an alkyl group, an alkoxy group, or an acyloxy group. nₐₓ₂ represents an integer in a range of 0 to 3. In a case where nₐₓ₂ represents 2 or more, a plurality of les may be bonded together to form a ring structure. n₂₁, n₂₂, n₂₄, and n₂₅ each independently represent 0 or 1. n₂₃ and n₂₆ each independently represent 1 or 2.]

In General Formulae (a11-u1-1) to (a11-u1-6) described above, the alkyl group, alkoxy group, and acyloxy group as Ware the same as the alkyl group, the alkoxy group, and the acyloxy group, which are exemplified as the substituents as Ra^{x02} in General Formula (a11-1).

Specific examples of the constitutional unit (the constitutional unit (a11)) derived from the compound represented by General Formula (a11-1) are shown below.

In the formulae shown below, R^{α} represents a hydrogen atom, a methyl group, or a trifluoromethyl group.

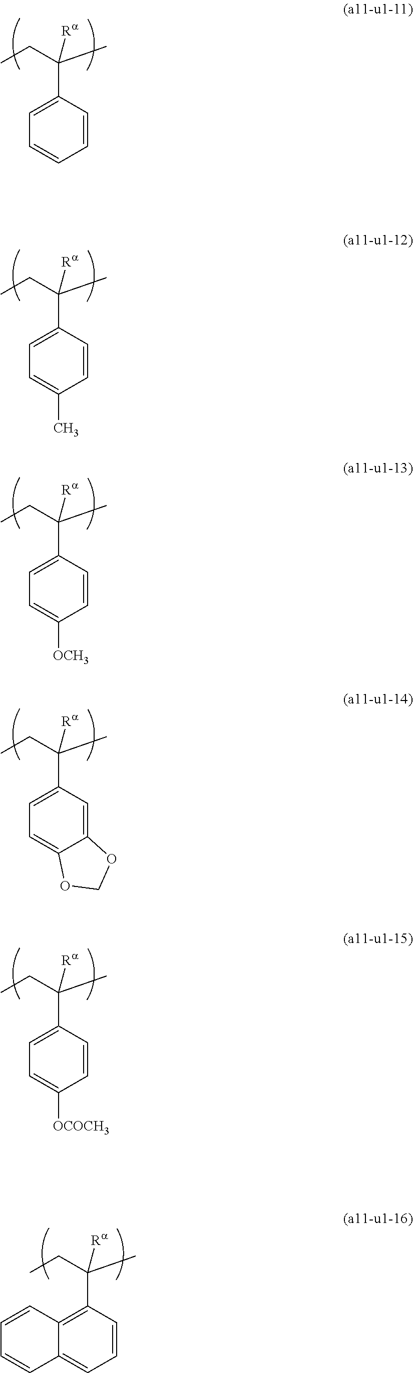

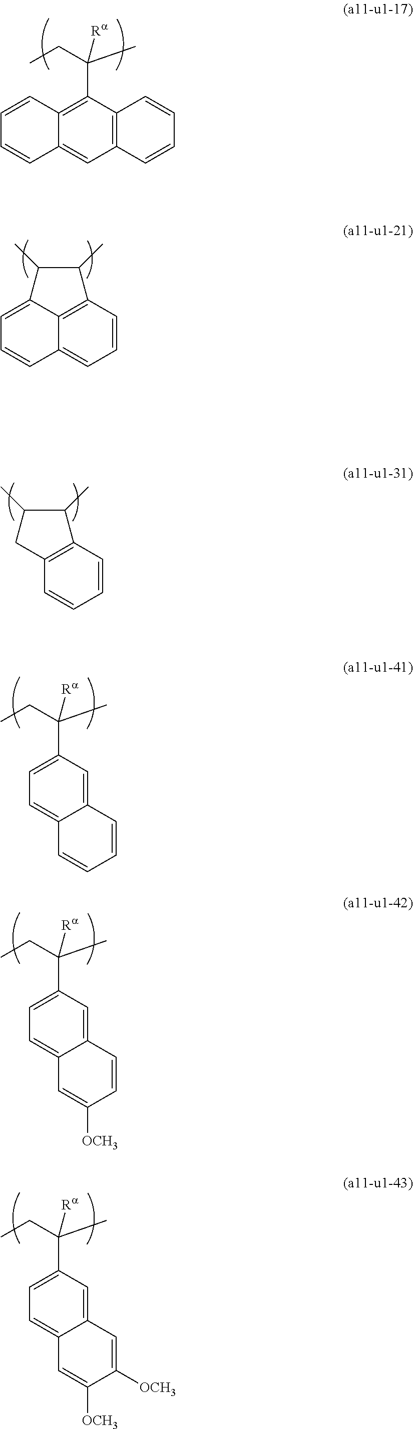

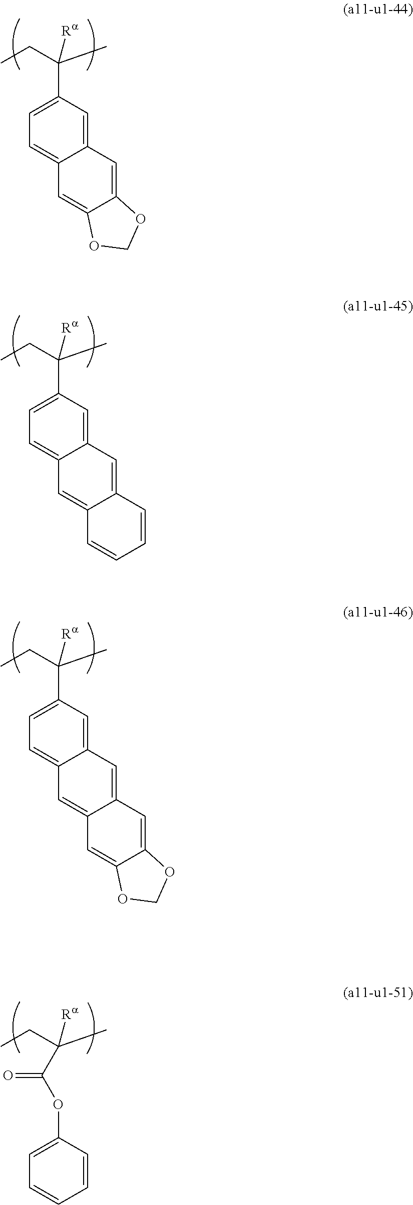

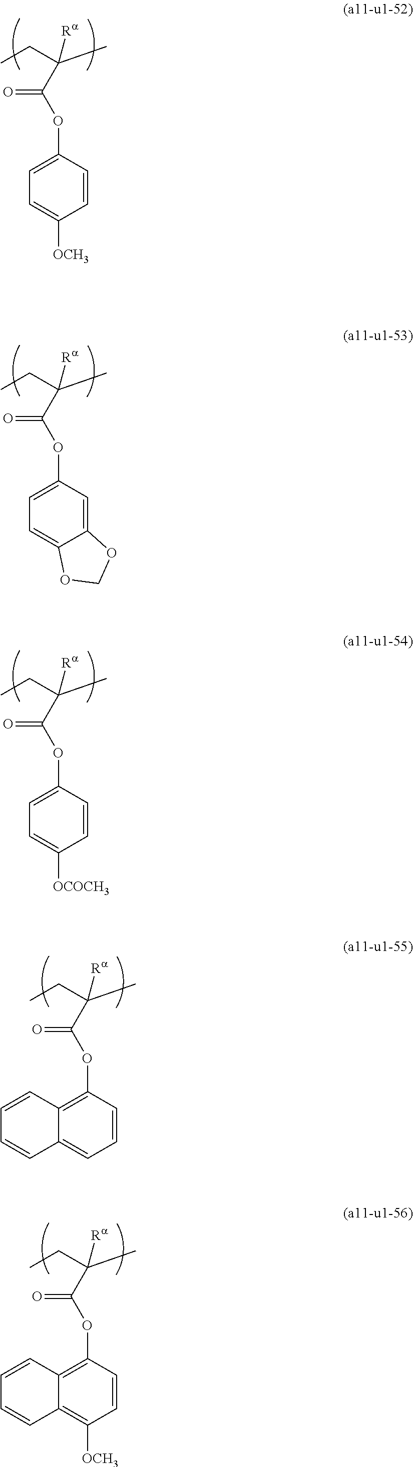

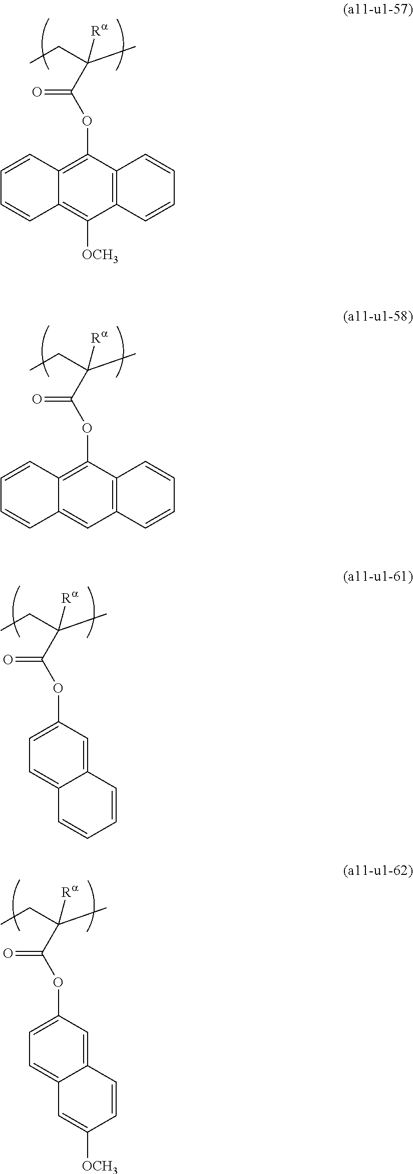

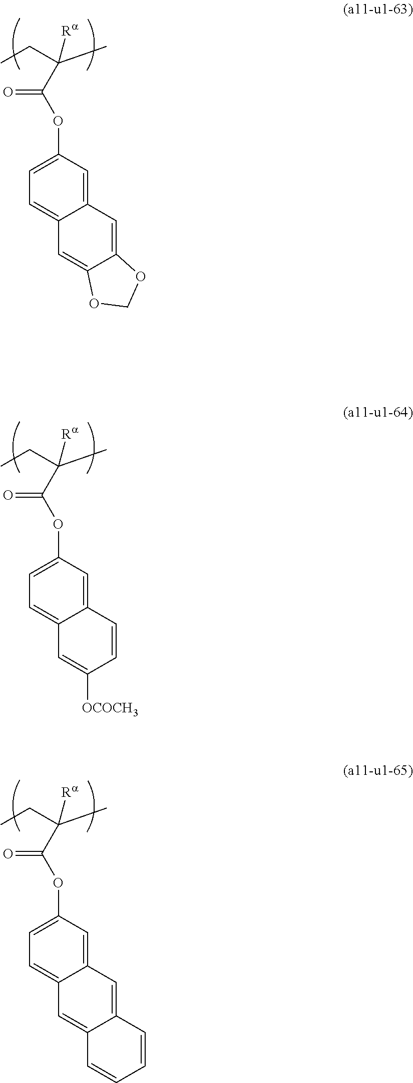

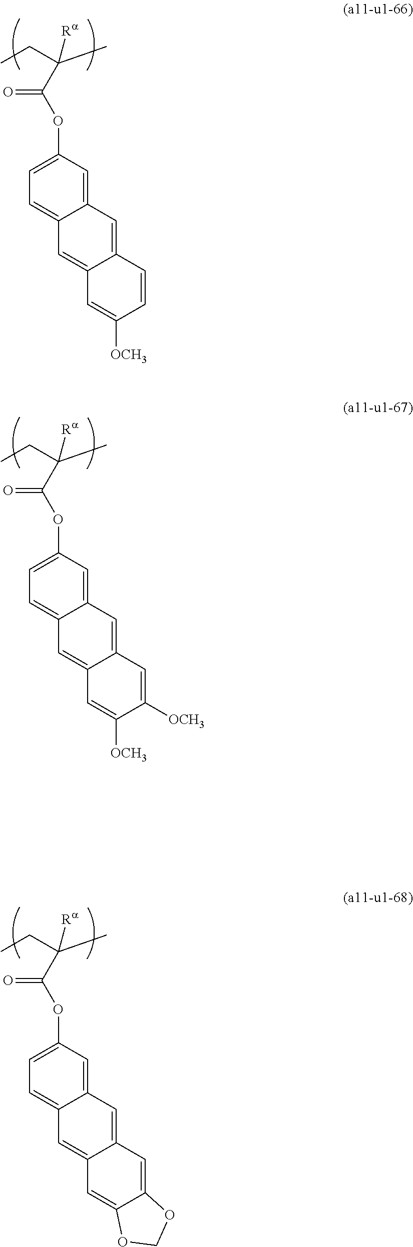

Among those exemplified above, the constitutional unit (a11) is preferably at least one selected from the group consisting of constitutional units each represented by General Formulae (a11-u1-1) to (a11-u1-3) and more preferably constitutional units each represented by General Formula (a11-u1-1).

Among these, the constitutional unit (a11) 1) is preferably a constitutional unit represented by any one of Chemical Formulae (a11-u1-11), (a11-u1-21), or (a11-u1-31), and more preferably a constitutional unit represented by Chemical Formula (a11-u1-11). The constitutional unit (a11) contained in the component (A1) may be one kind or may be two or more kinds.

In a case where the component (A1) has the constitutional unit (a11), the proportion of the constitutional unit (a11) in the component (A1) is preferably in a range of 1% to 30% by mole, more preferably in a range of 1% to 25% by mole, and still more preferably in a range of 1% to 20% by mole, with respect to the total (100% by mole) of all constitutional units constituting the component (A1).

In a case where the proportion of the constitutional unit (a11) is set to be equal to or larger than the lower limit value, lithography characteristics are improved easily. On the other hand, in a case where it is set to be equal to or smaller than the upper limit value, the throughput at the time of etching is further improved, and the balance with other constitutional units is obtained easily.

In the resist composition according to the present embodiment, the component (A) contains the resin component (A1) (the component (A1)) having the constitutional unit (a10).

Examples of the preferred component (A1) include a polymeric compound having at least the constitutional unit (a10) and the constitutional unit (a1). Specific suitable examples of the component (A1) include a polymeric compound having a repeating structure of the constitutional unit (a10), the constitutional unit (a1), and the constitutional unit (a4), and a polymeric compound having a repeating structure of the constitutional unit (a10), the constitutional unit (a1), and the constitutional unit (a11).

The weight average molecular weight (Mw) (in terms of the polystyrene equivalent value determined by gel permeation chromatography (GPC)) of the component (A1), which is not particularly limited, is preferably in a range of 500 to more preferably in a range of 1,000 to 30,000, and still more preferably in a range of 2,000 to 20,000.

In a case where Mw of the component (A1) is equal to or smaller than the upper limit value of this preferred range, the sufficient solubility in the resist solvent is exhibited in a case of being used as a resist. On the other hand, in a case where Mw thereof is equal to or larger than the lower limit value of this preferred range, the dry etching resistance and the cross-sectional shape of the resist pattern become more excellent.

The dispersity (Mw/Mn) of the component (A1) is not particularly limited; however, it is preferably in a range of 1.0 to 4.0, more preferably in a range of 1.0 to 3.0, and particularly preferably in a range of 1.0 to 2.5. In addition, Mn shows a number average molecular weight.

The component (A1) can be produced by dissolving, in a polymerization solvent, each monomer from which the constitutional unit is derived, adding thereto a radical polymerization initiator such as azobisisobutyronitrile (AIBN) or dimethyl azobisisobutyrate (for example, V-601) to carry out polymerization.

Alternatively, the component (A1) can be produced by dissolving, in a polymerization solvent, a monomer from which the constitutional unit (a10) is derived and, as necessary, a monomer from which a constitutional unit other than the constitutional unit (a10) is derived, adding thereto a radical polymerization initiator such as described above to carry out polymerization, and then carrying out a deprotection reaction.

Further, a —C(CF₃)₂—OH group may be introduced into the terminal thereof during the polymerization using a chain transfer agent such as HS—CH₂—CH₂—CH₂—C(CF₃)₂—0H in combination. As described above, a copolymer into which a hydroxyalkyl group, formed by substitution of part of hydrogen atoms in the alkyl group with fluorine atoms, has been introduced is effective for reducing development defects and reducing line edge roughness (LER: uneven irregularities of a line side wall).

In addition, the component (A1) can be produced according to an anionic polymerization method by using, as a polymerization initiator, an organic alkali metal such as n-butyl lithium, s-butyl lithium, t-butyl lithium, ethyl lithium, ethyl sodium, 1,1-diphenylhexyl lithium, or 1,1-diphenyl-3-methylpentyl lithium.
In regard to component (A2)

In the resist composition according to the present embodiment, a base material component (hereinafter, referred to as a “component (A2)”) that exhibits changed solubility in a developing solution under action of acid, which does not correspond to the component (A1), may be used in combination as the component (A).

The component (A2) is not particularly limited and may be freely selected and used from a large number of base material components for the chemical amplification-type resist composition, which are known in the related art.

As the component (A2), a polymeric compound or a low molecular weight compound may be used alone or in a combination of two or more kinds thereof.

The proportion of the component (A1) in the component (A) is preferably 25% by mass or more, more preferably 50% by mass or more, still more preferably 75% by mass or more, and may be 100% by mass with respect to the total mass of the component (A). In a case where the proportion is 25% by mass or more, a resist pattern having various excellent lithography characteristics such as high sensitivity, resolution, and roughness amelioration can be easily formed.

The content of the component (A) in the resist composition according to the present embodiment may be adjusted depending on the resist film thickness to be formed.

<Component (B)>
In regard to component (B0)

The component (B) is an acid generator component that generates acid upon exposure. The component (B) in the resist composition according to the present embodiment contains at least a compound (B0) represented by General Formula (b0-1) (hereinafter, also referred to as a “component (B0)”).

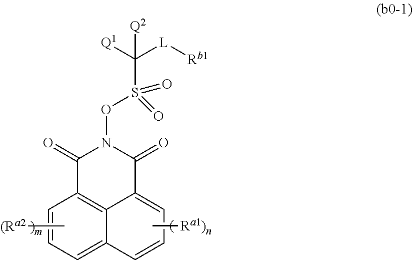

[In the formula, R^{b1} represents a hydrocarbon group having 1 or more and 30 or less carbon atoms; in a case where the hydrocarbon group as R^{b1} contains one or more methylene groups, at least part of the methylene groups may be substituted with a group selected from the group consisting of —O—, —S—, —CO—, —OO—O—, —SO—, —SO₂—, —CR^{b4}R^{b}5—, and —NR^{b6}—; in a case where the hydrocarbon group as R^{b1} contains a hydrocarbon ring, at least one of carbon atoms constituting the hydrocarbon ring may be substituted with a hetero atom selected from the group consisting of N, O, P, S, and Se, or an atomic group containing the hetero atom; R^{b4} and R^{b5} each independently represent a hydrogen atom or a halogen atom, at least one of R^{b4} and R^{b5} represents a halogen atom, and R^{b6} represents a hydrogen atom or a hydrocarbon group having 1 or more and 6 or less carbon atoms; n and m of (R^{a1})n and (Ra²)m represent an integer in a range of 0 to 3, R^{a1} and Rat each independently represent a hydrogen atom or an organic group; Q¹ and Q² each independently represent a fluorine atom or a perfluoroalkyl group having 1 or more and 6 or less carbon atoms; and L represents an ester bond.]

In General Formula (b0-1), specific examples of the organic group as Ra i- and Ra², include a cyclic group which may have a substituent, a chain-like alkyl group which may have a substituent, and a chain-like alkenyl group which may have a substituent.

Cyclic group which may have substituent:

The cyclic group is preferably a cyclic hydrocarbon group, and the cyclic hydrocarbon group may be an aromatic hydrocarbon group or an aliphatic hydrocarbon group. The aliphatic hydrocarbon group indicates a hydrocarbon group that has no aromaticity. The aliphatic hydrocarbon group may be saturated or unsaturated. In general, it is preferable that the aliphatic hydrocarbon group is saturated.

The aromatic hydrocarbon group as R^{a1} and Ra² represents a hydrocarbon group having an aromatic ring. The aromatic hydrocarbon group preferably has 3 to 30 carbon atoms, more preferably 5 to 30, still more preferably 5 to 20, particularly preferably 6 to and most preferably 6 to 10. However, the number of carbon atoms in a substituent is not included in the number of carbon atoms.

Specific examples of the aromatic ring contained in the aromatic hydrocarbon group as R^{a1} and Ra² include benzene, fluorene, naphthalene, anthracene, phenanthrene, biphenyl, and an aromatic heterocyclic ring obtained by substituting part of carbon atoms constituting one of these aromatic rings with a hetero atom. Examples of the hetero atom in the aromatic heterocyclic rings include an oxygen atom, a sulfur atom, and a nitrogen atom.

Specific examples of the aromatic hydrocarbon group as R^{a1} and Ra² include a group (an aryl group such as a phenyl group or a naphthyl group) obtained by removing one hydrogen atom from the above-described aromatic ring and a group (an arylalkyl group such as a benzyl group, a phenethyl group, a 1-naphthylmethyl group, a 2-naphthylmethyl group, 1-naphthylethyl group, or a 2-naphthylethyl group) obtained by substituting one hydrogen atom in the aromatic ring with an alkylene group. The alkylene group (an alkyl chain in the arylalkyl group) preferably has 1 to 4 carbon atoms, more preferably 1 or 2 carbon atoms, and particularly preferably 1 carbon atom.

Examples of the cyclic aliphatic hydrocarbon group as Rei and Ra′² include aliphatic hydrocarbon groups containing a ring in the structure thereof.

Examples of the aliphatic hydrocarbon group containing a ring in the structure thereof include an alicyclic hydrocarbon group (a group obtained by removing one hydrogen atom from an aliphatic hydrocarbon ring), a group obtained by bonding the alicyclic hydrocarbon group to the terminal of a linear or branched aliphatic hydrocarbon group, and a group obtained by interposing the alicyclic hydrocarbon group is in a linear or branched aliphatic hydrocarbon group.

The alicyclic hydrocarbon group preferably has 3 to 20 carbon atoms and more preferably 3 to 12 carbon atoms.

The alicyclic hydrocarbon group may be a polycyclic group or a monocyclic group. The monocyclic alicyclic hydrocarbon group is preferably a group obtained by removing one or more hydrogen atoms from a monocycloalkane. The monocycloalkane preferably has 3 to 6 carbon atoms, and specific examples thereof include cyclopentane and cyclohexane. The polycyclic alicyclic hydrocarbon group is preferably a group obtained by removing one or more hydrogen atoms from a polycycloalkane, and the polycycloalkane preferably has 7 to 30 carbon atoms. Among the above, the polycycloalkane is more preferably a polycycloalkane having a bridged ring-based polycyclic skeleton, such as adamantane, norbornane, isobornane, tricyclodecane, or tetracyclododecane; or a polycycloalkane having a condensed ring-based polycyclic skeleton, such as a cyclic group having a steroid skeleton.

The linear aliphatic hydrocarbon group which may be bonded to the alicyclic hydrocarbon group preferably has 1 to 10 carbon atoms, more preferably 1 to 6 carbon atoms, still more preferably 1 to 4 carbon atoms, and most preferably 1 to 3 carbon atoms. The linear aliphatic hydrocarbon group is preferably a linear alkylene group, and specific examples thereof include a methylene group [—CH₂—], an ethylene group [—(CH₂)₂—], a trimethylene group [—(CH₂)₃—], a tetramethylene group [—(CH₂)₄—], and a pentamethylene group [—(CH₂)₅—].

The branched aliphatic hydrocarbon group which may be bonded to the alicyclic hydrocarbon group preferably has 2 to 10 carbon atoms, more preferably 3 to 6 carbon atoms, still more preferably 3 or 4 carbon atoms, and most preferably 3 carbon atoms. The branched aliphatic hydrocarbon group is preferably a branched alkylene group, and specific examples thereof include alkyl alkylene groups, for example, alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)—, and —C(CH₂CH₃)₂—; alkylethylene groups such as —CH(CH₃)CH₂—, —CH(CH₃)CH(CH₃)—, —C(CH₃)₂CH₂—, —CH(CH₂CH₃)CH₂—, and —C(CH₂CH₃)₂—CH₂—; alkyltrimethylene groups such as —CH(CH₃)CH₂CH₂—, and —CH₂CH(CH₃)CH₂—; and alkyltetramethylene groups such as —CH(CH₃)CH₂CH₂CH₂—, and —CH₂CH(CH₃)CH₂CH₂—. The alkyl group in the alkylalkylene group is preferably a linear alkyl group having 1 to 5 carbon atoms.

The cyclic hydrocarbon group as R^{a1} and R^{a2} may contain a hetero atom such as a heterocyclic ring. Specific examples thereof include lactone-containing cyclic groups each represented by General Formulae (a2-r-1) to (a2-r-7), —SO₂—-containing cyclic groups each represented by General Formulae (a5-r-1) to (a5-r-4), and other heterocyclic groups each represented by Chemical Formulae (r-hr-1) to (r-hr-16). In the formulae, * represents a bonding site for bonding to the aromatic ring in General Formula (b0-1).

Chain-like alkyl group which may have substituent:

The chain-like alkyl group as Ra′ and Ra² may be linear or branched.

The linear alkyl group preferably has 1 to 20 carbon atoms, more preferably 1 to carbon atoms, and most preferably 1 to 10 carbon atoms. Specific examples thereof include a methyl group, an ethyl group, a propyl group, a butyl group, a pentyl group, a hexyl group, a heptyl group, an octyl group, a nonyl group, a decanyl group, an undecyl group, a dodecyl group, a tridecyl group, an isotridecyl group, a tetradecyl group, a pentadecyl group, a hexadecyl group, an isohexadecyl group, a heptadecyl group, an octadecyl group, a nonadecil group, an icosyl group, a henicosyl group, and a docosyl group.

The branched alkyl group preferably has 3 to 20 carbon atoms, more preferably 3 to 15, and most preferably 3 to 10. Specific examples thereof include a 1-methylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group, and a 4-methylpentyl group.

Chain-like alkenyl group which may have substituent:

A chain-like alkenyl group as R^{a1} and Ra² may be linear or branched, and the chain-like alkenyl group preferably has 2 to 10 carbon atoms, more preferably 2 to 5 carbon atoms, still more preferably 2 to 4 carbon atoms, and particularly preferably 3 carbon atoms. Examples of the linear alkenyl group include a vinyl group, a propenyl group (an allyl group), and a butynyl group. Examples of the branched alkenyl group include a 1-methylvinyl group, a 2-methylvinyl group, a 1-methylpropenyl group, and a 2-methylpropenyl group.

Among the above, the chain-like alkenyl group is preferably a linear alkenyl group, more preferably a vinyl group or a propenyl group, and particularly preferably a vinyl group.

In General Formula (b0-1), in a case where the aliphatic hydrocarbon group as R^{a1} and Ra² contains one or more methylene groups, at least part of the methylene groups may be substituted with a group selected from the group consisting of —O—, —S—, —CO—, —CO—O—, —SO—, —SO₂—, and —NR^{a5}—.

R^{a5} represents a hydrogen atom or a hydrocarbon group having 1 to 6 carbon atoms. The hydrocarbon group having 1 to 6 carbon atoms, as R^{a5}, may be an aliphatic hydrocarbon group, may be an aromatic hydrocarbon group, or may be a combination thereof. The aliphatic hydrocarbon group may be linear, may be branched, may be cyclic, or it may have a combination of these structures.

Examples of the aliphatic hydrocarbon group include alkyl groups such as a methyl group, an ethyl group, an n-propyl group, an isopropyl group, an n-butyl group, an isobutyl group, a sec-butyl group, a tert-butyl group, an n-pentyl group, and an n-hexyl group.

Examples of the aromatic hydrocarbon group include a phenyl group.

The organic group as R^{a1} and Ra² may be a group represented by —Ra³—Ra⁴.

R^{a3} represents a methylene group, —O—, —CO—, —CO—O—, —SO—, —SO₂—, or —NR^{a6}—.

R^{a6} represents a hydrogen atom or a hydrocarbon group having 1 to 6 carbon atoms.

R^{a4} is an aromatic group having 5 to 20 ring-constituting atoms, which may have a substituent, a perfluoroalkyl group having 1 or more and 6 or less carbon atoms, an aralkyl group having 7 or more and 20 or less carbon atom atoms, which may have a substituent, or a heteroarylalkyl group containing an aromatic heterocyclic group having 5 or more and 20 or less ring-constituting atoms, which may have a substituent.

As R^{a4}, the aromatic group having 5 or more and 20 or less ring-constituting atoms, which may have a substituent, is the same as the aromatic hydrocarbon group, which may have a substituent, where the aromatic hydrocarbon group has been described for R^{a1} and Ra².

The perfluoroalkyl group having 1 to 6 carbon atoms as R^{a4} include CF₃—, CF₃CF₂—, (CF₃)₂CF—, CF₃CF₂CF₂—, CF₃CF₂CF₂CF₂—, and (CF₃)₂CFCF₂—, CF₃CF₂(CF₃)CF—, (CF₃)₃C—.

Specific examples of the aralkyl group as R^{a4} having 7 or more and 20 or less carbon atoms, which may have a substituent, include a benzyl group, a phenethyl group, an α-naphthylmethyl group, β-naphthylmethyl group, a 2-α-naphthylethyl group, and a 2-β-naphthylethyl group.

In General Formula (b0-1), the heteroarylalkyl group is a group in which part of carbon atoms constituting the aromatic hydrocarbon ring in the arylalkyl group are substituted with a hetero atom such as N, O, or S. Specific examples of the heteroarylalkyl group as R^{a4} containing an aromatic heterocyclic group having 5 or more and 20 or less ring-constituting atoms, which may have a substituent include a pyridin-2-yl methyl group, a pyridin-3-yl methyl group, and a pyridin-4-yl methyl group.

The hydrocarbon group having 1 or more and 6 or less carbon atoms, as R^{a6}, is the same as the hydrocarbon group having 1 or more and 6 or less carbon atoms, which has been described for Ra⁵.

In General Formula (b0-1), Ra¹ and Ra² are, among the above, preferably a chain-like alkyl group in which at least part of methylene groups may be substituted with a group selected from the group consisting of —O—, —S—, —CO—, —CO—O—, —SO—, —SO₂—, and —NR^{a5}—, more preferably a linear alkyl group having 1 to 10 carbon atoms or a group represented by —R^{a3}—R^{a4}—, and still more preferably a linear alkyl group having 1 to 5 carbon atoms.

In General Formula (b0-1), m and n each independently represent an integer in a range of 0 to 3, and they are preferably 0 or 1. It is more preferable that one of m and n is 0 and the other is 1.

In General Formula (b0-1), the hydrocarbon group having 1 or more and 30 or less carbon atoms, as R^{b1}, may be an aliphatic hydrocarbon group, may be an aromatic hydrocarbon group, or may be a combination thereof. The aliphatic hydrocarbon group may be linear, may be branched, may be cyclic, or it may have a combination of these structures.

Examples of the hydrocarbon group having 1 or more and 30 or less carbon atoms, as R^{b1}, include the same groups as the hydrocarbon groups as R^{a1} and Ra². Specific examples of the aliphatic hydrocarbon group include chain-like aliphatic hydrocarbon groups such as a methyl group, an ethyl group, an n-propyl group, an isopropyl group, an n-butyl group, an isobutyl group, a sec-butyl group, a tert-butyl group, an n-pentyl group, and an n-hexyl group, and cyclic aliphatic hydrocarbon groups (hydrocarbon rings) such as a cyclopropyl group, a cyclobutyl group, a cyclopentyl group, a cyclohexyl group, an adamantyl group, and a norbornyl group.

Examples of the aromatic hydrocarbon group include a phenyl group and a naphthyl group.

Examples of the group in which an aliphatic hydrocarbon group and an aromatic hydrocarbon group are combined include a benzyl group, a phenethyl group, and a furylmethyl group.

In a case where the hydrocarbon group as R^{b1} contains a hydrocarbon ring, examples of the atomic group containing a hetero atom that substitutes at least one of carbon atoms constituting the hydrocarbon ring include —CO—, —CO—O—, —SO—, —SO₂—, —SO₂—O—, and —P(═O)—(OR^{b7})₃.

R^{b7} represents a hydrocarbon group having 1 or more and 6 or less carbon atoms. The hydrocarbon group having 1 or more and 6 or less carbon atoms, as R^{b7}, may be an aliphatic hydrocarbon group, may be an aromatic hydrocarbon group, or may be a combination thereof. The aliphatic hydrocarbon group may be linear, may be branched, may be cyclic, or it may have a combination of these structures.

Examples of the aliphatic hydrocarbon group include alkyl groups such as a methyl group, an ethyl group, an n-propyl group, an isopropyl group, an n-butyl group, an isobutyl group, a sec-butyl group, a tert-butyl group, an n-pentyl group, and an n-hexyl group.

Examples of the aromatic hydrocarbon group include a phenyl group.

In General Formula (b0-1), specific examples of the halogen atom as R^{b4} and R^{b5} include a chlorine atom, a fluorine atom, a bromine atom, and an iodine atom.

In General Formula (b0-1), the hydrocarbon group having 1 to 6 carbon atoms, as R^{b6}, is the same as the hydrocarbon group having 1 or more and 6 or less carbon atoms, as R^{b7}.

In General Formula (b0-1), R^{b1} is preferably, among the above, a linear or branched alkyl group, a group obtained by removing one or more hydrogen atoms from a monocycloalkane, a group obtained by removing one or more hydrogen atoms from a polycycloalkane, or each of —SO₂—-containing cyclic groups represented by General Formulae (a5-r-1) to (a5-r-4), more preferably a linear or branched alkyl group having 1 to 5 carbon atoms, a cyclohexylalkyl group, an adamantylalkyl group, or each of —SO₂—-containing cyclic groups represented by General Formulae (a5-r-1) to (a5-r-4), and still more preferably a methyl group, a cyclohexylethyl group, an adamantylethyl group, or each of —SO₂—-containing cyclic groups represented by General Formulae (a5-r-1) to (a5-r-4).

In General Formula (b0-1), the perfluoroalkyl group having 1 or more and 6 or less carbon atoms as Q¹ and Q² include CF₃—, CF₃CF₂—, (CF₃)₂CF—, CF₃CF₂CF₂—, CF₃CF₂CF₂CF₂—, and (CF₃)₂CFCF₂—, CF₃CF₂(CF₃)CF—, (CF₃)₃C—.

In the compound represented by General Formula (b0-1), the orientation of the ester bond as L is not particularly limited, and thus any one of —CO—O— or —O—CO— may be adopted.

The component (B0) is preferably a compound represented by General Formula (b0-1-1).

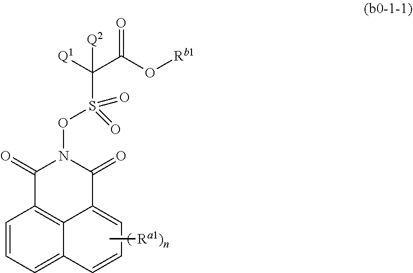

[In General Formula (b0-1-1), R^{b1}, R^{a1}, Q¹, and Q² are the same as R^{b1}, Ra¹, Q¹, and Q² in General Formula (b0-1).]

The component (B0) can be produced by the following method for producing an N-organosulfonyloxy compound.

The method for producing an N-organosulfonyloxy compound, which makes it possible to produce the component (B0), is a method for producing an N-organosulfonyloxy compound, which includes reacting an N-hydroxy compound (B0-A′) with a sulfonic acid fluoride compound (B0-B′) in the presence of a basic compound (B0-D′), where the method for producing an N-organosulfonyloxy compound is characterized in that a silylating agent (B0-C′) is present in the system in reacting the N-hydroxy compound (B0-A′) with the sulfonic acid fluoride compound (B0-B′), a sulfonic acid fluoride compound (B′) is represented by General Formula (B0-B′-1), and the silylating agent (B0-C′) can convert the hydroxy group on the nitrogen atom contained in the N-hydroxy compound (B0-A′) to a silyloxy group represented by General Formula (B0-c1).

—O—Si(R^{c1})₃ (B0-c1)

(In General Formula (B0-c1), Rd each independently represents a hydrocarbon group having 1 or more and 10 or less carbon atoms.)

R^{b1}-L-CQ¹Q²-SO₂—F (B0-B′1)

(In General Formula (B0-B′-1), R^{b1}, L, Q¹, and Q² are each the same as R^{b1}, L, Q¹, and Q² in General Formula (b0-1).)

In addition, the method for producing an N-organosulfonyloxy compound capable of producing the component (B0) is a method for producing an N-organosulfonyloxy compound, which includes a silylation step of silylating the N-hydroxy compound (B0-A′) with the silylating agent (B0-C′) and a condensation step of condensing a silylated product of the N-hydroxy compound (B0-A′) generated in the silylation step with the sulfonic acid fluoride compound (B0-B′) in the presence of the basic compound (B0-D′), where a sulfonic acid fluoride compound (B0-B′) is represented by General Formula (B0-B′-1), and the silylating agent can convert the hydroxy group on the nitrogen atom contained in the N-hydroxy compound (B0-A′) to a silyloxy group represented by General Formula (B0-c1).

The N-hydroxy compound (B0-A′) is a compound represented by General Formula (B0-A′-1).

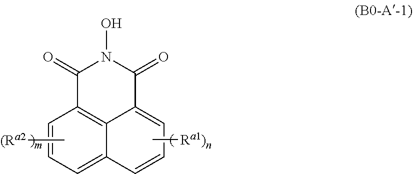

[In General Formula (B0-A′-1), R^{b1}, R^{a1}, m, and n are the same as R^{b1}, R^{a1}, m, and n in General Formula (b0-1).]

The N-hydroxy compound (B0-A′) can be synthesized according to a conventional method, for example, a method disclosed in PCT International Publication No. WO2014/084269 or Published Japanese Translation No. 2017-535595 of the PCT

International Publication. For example, a compound represented by General Formula (b0-1-1) in which Ra² is a hydrogen atom can be synthesized by converting a bromo group on a naphthalic acid anhydride to R^{a1} by a reaction represented by the following formula in which a commercially available bromide is used as a starting material and then causing a hydroxylamine compound such as hydroxylamine hydrochloride to act on an acid anhydride group so that it undergoes N-hydroxyimidation. In addition, a commercially available product may also be used as the N-hydroxy compound (B0-A′).

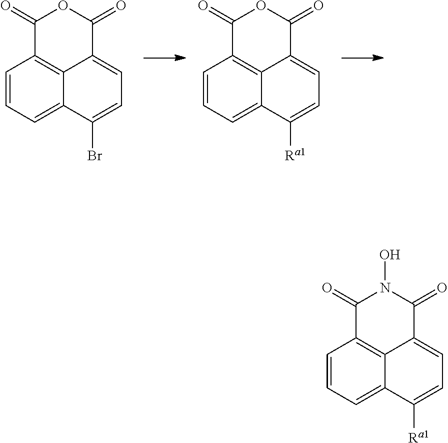

The sulfonic acid fluoride compound (B0-B′) can be synthesized according to a conventional method. For example, in (B0-B′-1), a compound in which Q¹ and Q² are a fluorine atom can be synthesized according to the reaction represented by the following formula. In addition, a commercially available product may also be used as the sulfonic acid fluoride compound (B0-B′).

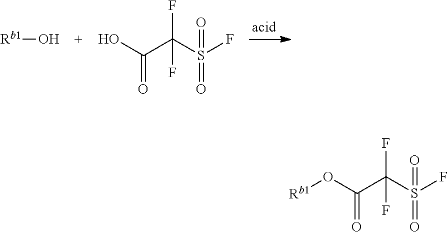

In General Formula (B0-c1), the hydrocarbon group having 1 or more and 10 or less carbon atoms, as R^{c1}, may be an aliphatic hydrocarbon group, may be an aromatic hydrocarbon group, or may be a combination thereof. The aliphatic hydrocarbon group may be linear, may be branched, may be cyclic, or it may have a combination of these structures.

Examples of the aliphatic hydrocarbon group include alkyl groups such as a methyl group, an ethyl group, an n-propyl group, an isopropyl group, an n-butyl group, an isobutyl group, a sec-butyl group, a tert-butyl group, an n-pentyl group, an n-hexyl group, an n-heptyl group, an n-octyl group, a 2-ethylhexyl group, an n-nonyl group, and an n-decyl group.

Examples of the aromatic hydrocarbon group include a phenyl group and a naphthyl group.

Preferred specific examples of the component (B0) are shown below.

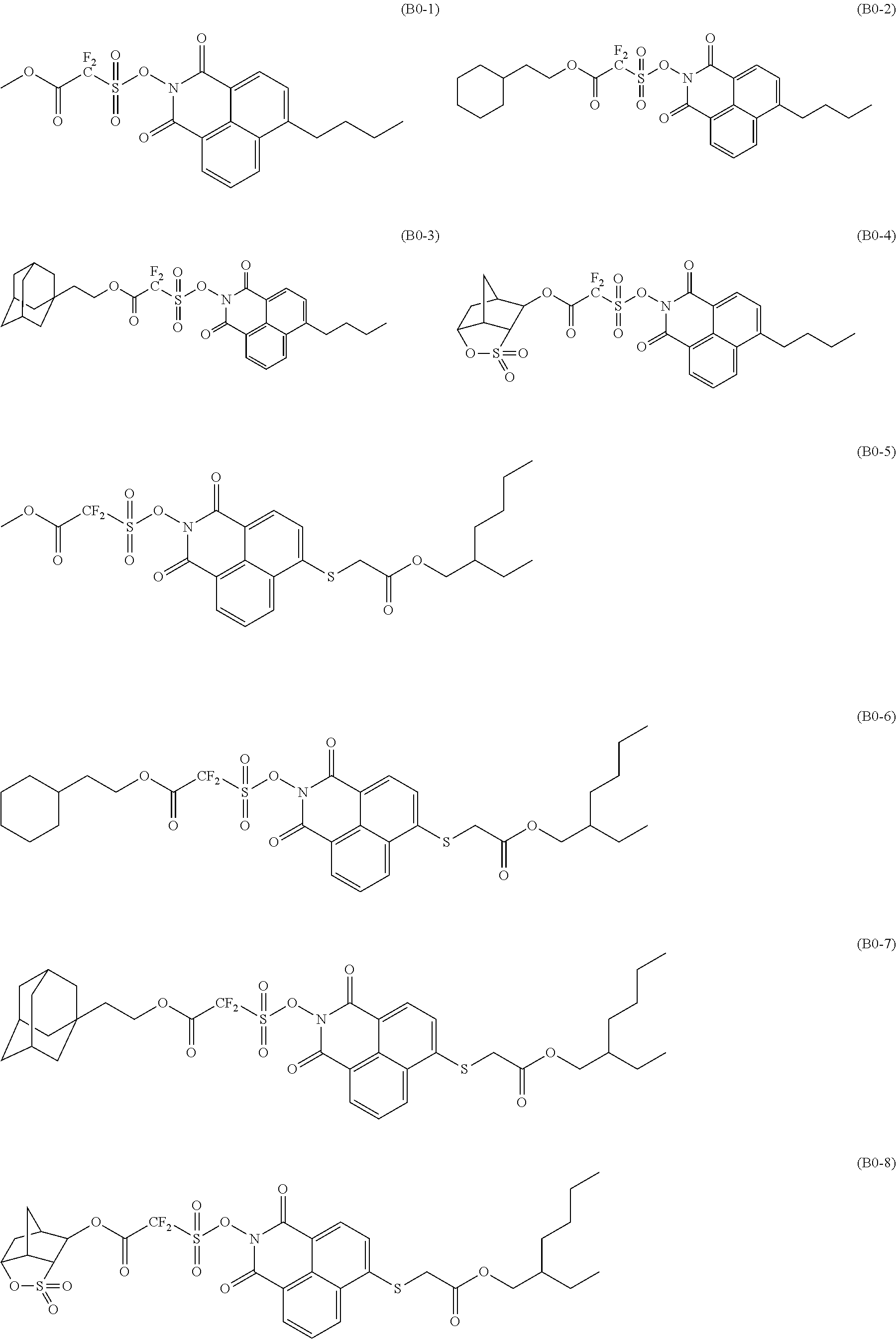

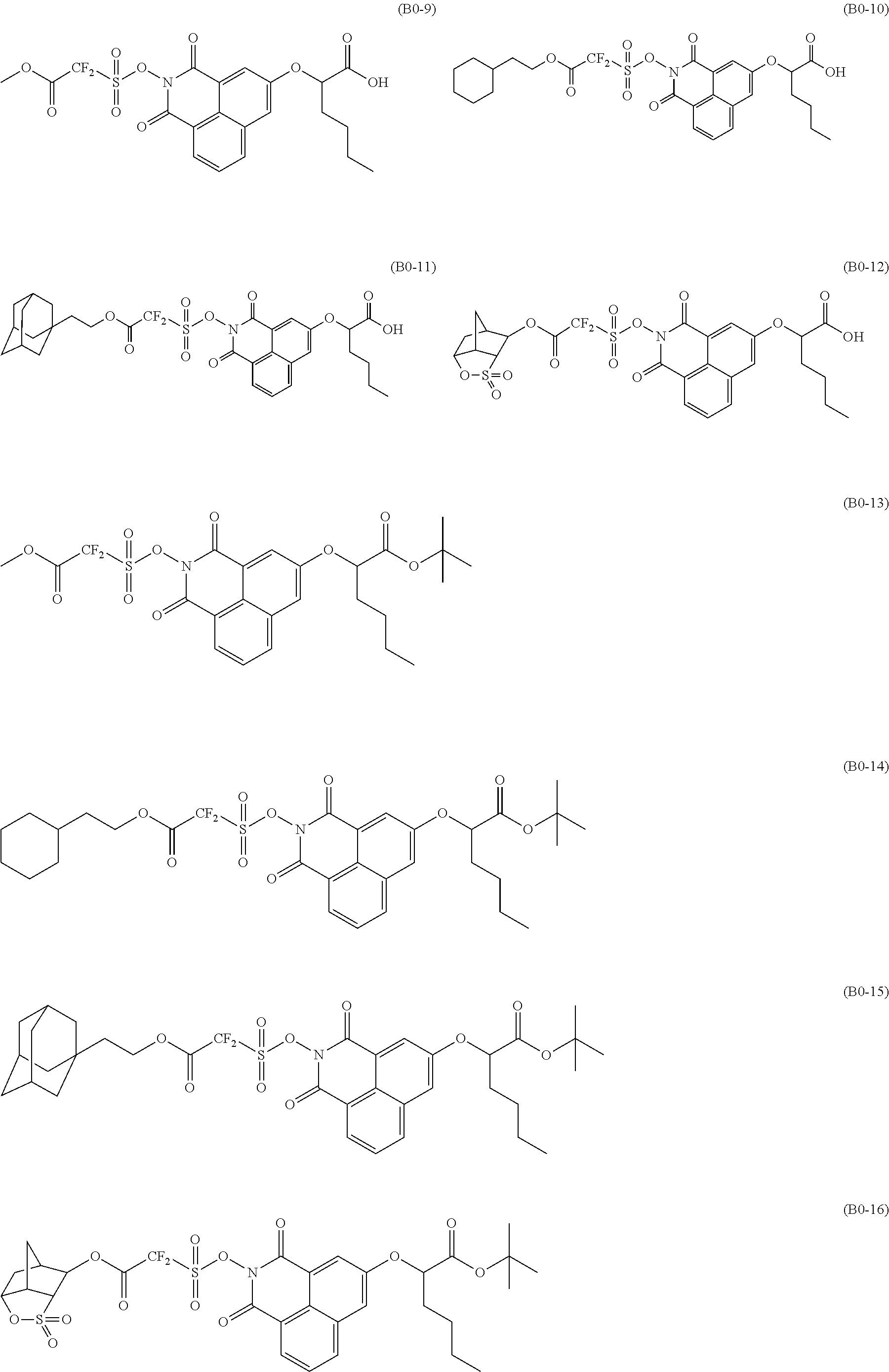

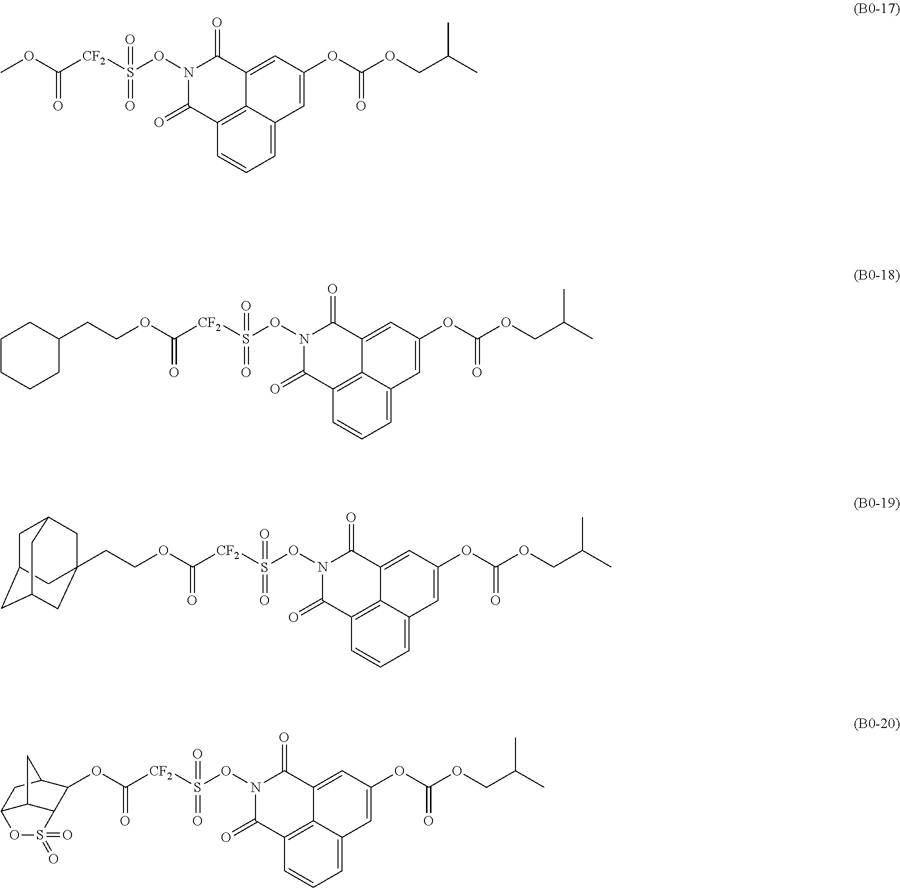 [SMILES: COC(=O)C(F)(F)S(=O)(=O)ON1C(=O)c2cccc3cc(OC(=O)OCC(C)C)cc(c23)C1=O ; CC(C)COC(=O)Oc1cc2c3c(cccc3c1)C(=O)N(OS(=O)(=O)C(F)(F)C(=O)OCCC1CCCCC1)C2=O ; CC(C)COC(=O)Oc1cc2c3c(cccc3c1)C(=O)N(OS(=O)(=O)C(F)(F)C(=O)OCCC13CC4CC(CC(C4)C1)C3)C2=O ; CC(C)COC(=O)Oc1cc2c3c(cccc3c1)C(=O)N(OS(=O)(=O)C(F)(F)C(=O)OC1C3CC4OS(=O)(=O)C1C4C3)C2=O]

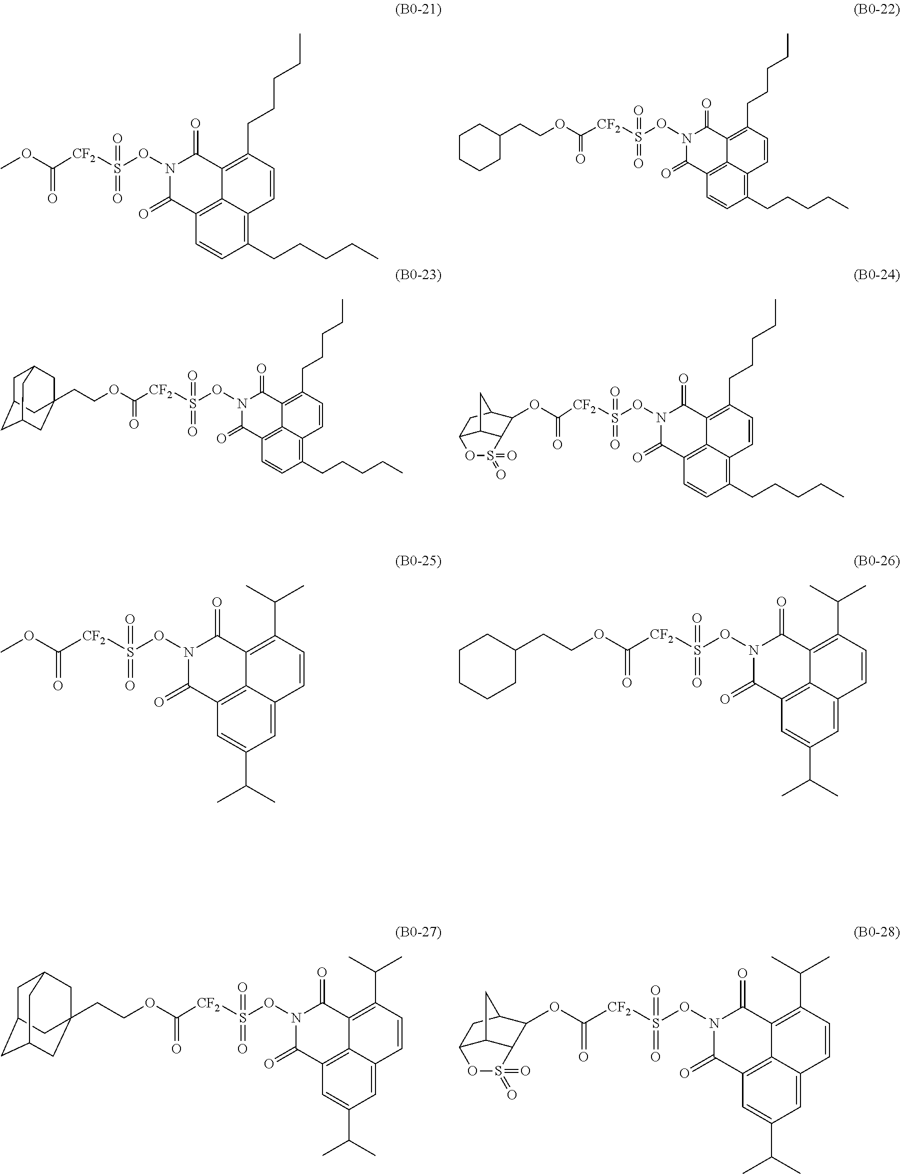

The component (B0) contained in the resist composition according to the present embodiment may be used alone or in a combination of two or more kinds thereof.

The content of the component (B0) in the resist composition according to the present embodiment is preferably in a range of 0.1 to 50 parts by mass, more preferably in a range of 0.1 to 40 parts by mass, still more preferably in a range of 0.1 to 30 parts by mass, and particularly preferably in a range of 0.1 to 20 parts by mass, with respect to 100 parts by mass of the component (A).

In a case where the content of the component (B0) is set to be within the above-described preferred range, pattern formation can be sufficiently carried out, and lithography characteristics such as CDU are likely to be improved. Further, in a case where each component of the resist composition is dissolved in an organic solvent, the above range is preferable since a homogeneous solution is easily obtained and the storage stability of the resist composition is improved.

In regard to component (B1) The resist composition according to the present embodiment may further contain an acid generator (hereinafter, referred to as a “component (B1)”) other than the component (B0).

The component (B1) is not particularly limited, and those which have been proposed so far as an acid generator for a chemical amplification-type resist composition in the related art can be used.

Examples of these acid generators are numerous and include onium salt-based acid generators such as an iodonium salt and a sulfonium salt; oxime sulfonate-based acid generators; diazomethane-based acid generators such as bisalkyl or bisaryl sulfonyl diazomethanes and poly(bis-sulfonyl)diazomethanes; nitrobenzyl sulfonate-based acid generators; and disulfonate-based acid generators.

Examples of the onium salt-based acid generator include a compound represented by General Formula (b-1) (hereinafter, also referred to as a “component (b-1)”), a compound represented by General Formula (b-2) (hereinafter, also referred to as a “component (b-2)”), and a compound represented by General Formula (b-3) (hereinafter, also referred to as a “component (b-3)”).

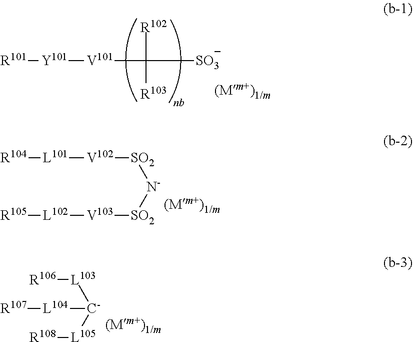

[In the formulae, R¹⁰¹ each independently represent a cyclic group which may have a substituent, a chain-like alkyl group which may have a substituent, or a chain-like alkenyl group which may have a substituent. R¹⁰⁴ and R¹⁰⁵ may be bonded to each other to form a ring. R¹⁰² and R¹⁰³ each independently represent a hydrogen atom, an alkyl group having 1 to 5 carbon atoms, a fluorine atom, or a fluorinated alkyl group having 1 to 5 carbon atoms. nb represents 0 or 1. Y¹⁰¹ represents a single bond or a divalent linking group containing an oxygen atom. V¹⁰¹ to V¹⁰³ each independently represent a single bond, an alkylene group, or a fluorinated alkylene group. L¹⁰¹ and L¹⁰² each independently represent a single bond or an oxygen atom. L¹⁰³ to L¹⁰⁵ each independently represent a single bond, —CO— or —SO₂—. m represents an integer of 1 or more, and M′^{m+} represents an m-valent onium cation.]

In General Formula (b-1), R¹⁰¹ is preferably a cyclic group which may have a substituent, and more preferably a cyclic hydrocarbon group which may have a substituent. More specifically, it is preferably a group obtained by removing one or more hydrogen atoms from a phenyl group, a naphthyl group, a polycycloalkane; a group obtained by removing one or more hydrogen atoms from camphor; each of lactone-containing cyclic groups represented by General Formulae (a2-r-1) and (a2-r-3) to (a2-r-7); or each of —SO₂—-containing cyclic groups represented by General Formulae (a5-r-1) to (a5-r-4) (any group may have a substituent).

In General Formula (b-1), Y¹⁰¹ is preferably a single bond, a divalent linking group containing an ester bond, or a divalent linking group containing an ether bond.

In General Formula (b-1), V¹⁰¹ is preferably a single bond or a fluorinated alkylene group having 1 to 4 carbon atoms.

In General Formula (b-1), R¹⁰² is preferably a hydrogen atom, a fluorine atom, or a perfluoroalkyl group having 1 to 5 carbon atoms.

In General Formula (b-2), R¹⁰⁴ and R¹⁰⁵ each independently represent a cyclic group which may have a substituent, a chain-like alkyl group which may have a substituent, or a chain-like alkenyl group which may have a substituent, and examples thereof each include the same one as R¹⁰¹ in General Formula (b-1). However, R¹⁰⁴ and R¹⁰⁵ may be bonded to each other to form a ring.

R¹⁰⁴ and R¹⁰⁵ are preferably a chain-like alkyl group which may have a substituent and more preferably a linear or branched alkyl group or a linear or branched fluorinated alkyl group.

In General Formula (b-2), V¹⁰² and V¹⁰³ each independently represent a single bond, an alkylene group, or a fluorinated alkylene group, and examples thereof each include the same ones as V¹⁰¹ in General Formula (b-1).

In General Formula (b-2), L¹⁰¹ and L¹⁰² each independently represent a single bond or an oxygen atom.

In General Formula (b-3), R¹⁰⁶ to R¹⁰⁸ each independently represent a cyclic group which may have a substituent, a chain-like alkyl group which may have a substituent, or a chain-like alkenyl group which may have a substituent, and examples thereof include the same one as R¹⁰¹ in General Formula (b-1).

L¹⁰³ to L¹⁰⁵ each independently represent a single bond, —CO—, or —SO₂—.]

In General Formulae (b-1), (b-2), and (b-3), m represents an integer of 1 or more. M′^{m+} represents an m-valent onium cation and suitable examples thereof include a sulfonium cation and an iodonium cation.

In the resist composition according to the present embodiment, the component (B1) may be used alone or in a combination of two or more kinds thereof.

In a case where the resist composition contains the component (B1), the content of the component (B1) in the resist composition is preferably 50 parts by mass or less, more preferably in a range of 0.1 to 40 parts by mass, still more preferably in a range of 0.1 to 30 parts by mass, and particularly preferably in a range of 0.1 to 20 parts by mass, with respect to 100 parts by mass of the component (A).

<Optional Component>

«Component (D)»

The resist composition in the present embodiment may further contain an acid diffusion controlling agent component (hereinafter, also referred to as a “component (D)”), in addition to the component (A) and the component (B). The component (D) acts as a quencher (an acid diffusion controlling agent) which traps the acid generated upon exposure in the resist composition.

Examples of the component (D) include a nitrogen-containing organic compound (D1) (hereinafter, referred to as a “component (D1)”) and a photodecomposable base (D2) (hereinafter, referred to as a “component (D2)”) which does not correspond to the component (D1) and has an acid diffusion controllability that is lost by the decomposition upon exposure.

In a case where a resist composition containing the component (D) is obtained, the contrast between the exposed portions and unexposed portions of the resist film can be further improved at the time of forming a resist pattern.
In regard to component (D1)

The component (D1) is a base component and is a nitrogen-containing organic compound component that acts as an acid diffusion controlling agent in the resist composition.

The component (D1) is not particularly limited as long as it acts as an acid diffusion controlling agent, and examples thereof include aliphatic amines and an aromatic amines.

Among the aliphatic amines, a secondary aliphatic amine or a tertiary aliphatic amines is preferable.

The aliphatic amine is preferably an amine having one or more aliphatic groups, where the aliphatic group has 1 to 12 carbon atoms.

Examples of these aliphatic amines include an amine in which at least one hydrogen atom of ammonia (NH₃) has been substituted with an alkyl group or hydroxyalkyl group having 12 or less carbon atoms (alkyl amines or alkyl alcohol amines) and a cyclic amine.

Specific examples of the alkyl amine and the alkyl alcohol amine include monoalkyl amines such as n-hexyl amine, n-heptyl amine, n-octyl amine, n-nonyl amine, and n-decyl amine; dialkyl amines such as diethyl amine, di-n-propyl amine, di-n-heptyl amine, di-n-octyl amine, and dicyclohexyl amine; trialkyl amines such as trimethyl amine, triethyl amine, tri-n-propyl amine, tri-n-butyl amine, tri-n-pentyl amine, tri-n-hexyl amine, tri-n-heptyl amine, tri-n-octyl amine, tri-n-nonyl amine, tri-n-decyl amine, and tri-n-dodecyl amine; and alkyl alcohol amines such as diethanol amine, triethanol amine, diisopropanol amine, triisopropanol amine, di-n-octanol amine, and tri-n-octanol amine. Among these, trialkyl amines of 5 to 10 carbon atoms are preferable, and tri-n-pentyl amine and tri-n-octyl amine are particularly preferable.

Examples of the cyclic amine include heterocyclic compounds containing a nitrogen atom as a hetero atom. The heterocyclic compound may be a monocyclic compound (aliphatic monocyclic amine), or a polycyclic compound (aliphatic polycyclic amine).

Specific examples of the aliphatic monocyclic amine include piperidine and piperazine.

The aliphatic polycyclic amine preferably has 6 to 10 carbon atoms, and specific examples thereof include 1, 5-diazabicyclo[4.3.0]-5-nonene, 1,8-diazabicyclo[5.4.0]-17-undecene, hexamethylenetetramine, and 1,4-diazabicyclo[2.2.2]octane.

Examples of other aliphatic amines include tris(2-methoxymethoxyethyl)amine, tris{2-(2-methoxyethoxy)ethyl}amine, tris{2-(2-methoxyethoxymethoxy)ethyl}amine, tris{2-(1-methoxyethoxy)ethyl}amine, tris{2-(1-ethoxyethoxy)ethyl}amine, tris{2-(1-ethoxypropoxy)ethyl}amine, tris[2-{2-(2-hydroxyethoxy)ethoxy}ethyl]amine and triethanol amine triacetate, and triethanol amine triacetate is preferable.

Examples of aromatic amines include 4-dimethylaminopyridine, pyrrole, indole, pyrazole, imidazole, and derivatives thereof, tribenzylamine, an aniline compound, and N-tert-butoxycarbonylpyrrolidine.

The component (D1) may be used alone or in a combination of two or more kinds thereof.

Among them, the component (D1) is preferably an aromatic amine and more preferably an aniline compound. Examples of aniline compound include 2,6-diisopropylaniline, N,N-dimethylaniline, N,N-dibutylaniline, and N,N-dihexylaniline

In a case where the resist composition contains the component (D1), the component (D1) in the resist composition is typically in a range of 0.01 to 5 parts by mass with respect to 100 parts by mass of the component (A).

In a case where the content of the component (D1) is equal to or larger than the preferred lower limit value, excellent lithography characteristics and an excellent resist pattern shape are easily obtained. On the other hand, in a case where it is equal to or smaller than the upper limit value thereof, balance with other components can be obtained, and thus various lithography characteristics are improved.
In regard to component (D2)

The component (D2) is not particularly limited as long as it is decomposed upon exposure and loses the acid diffusion controllability. The component (D2) is preferably one or more compounds selected from the group consisting of a compound represented by General Formula (d2-1) (hereinafter, referred to as a “component (d2-1)”) and a compound represented by General Formula (d2-2) (hereinafter, referred to as a “component (d2-2)”).

At exposed portions of the resist film, the components (d2-1) and (d2-2) are decomposed and then lose the acid diffusion controllability (basicity), and thus they cannot act as a quencher, whereas they act as a quencher at unexposed portions of the resist film.

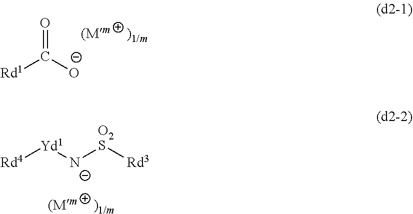

[In the formulae, Rd¹, Rd³, and Rd⁴ each independently represent a cyclic group which may have a substituent, a chain-like alkyl group which may have a substituent, or a chain-like alkenyl group which may have a substituent. Yd¹ represents a single bond or a divalent linking group. m represents an integer of 1 or more, and each M′^{m+} independently represents an m-valent onium cation.]

In General Formula (d2-1), Rd¹ is preferably an aromatic hydrocarbon group which may have a substituent, an aliphatic cyclic group which may have a substituent, or a chain-like alkyl group which may have a substituent.

In General Formula (d2-2), Rd³ is preferably a cyclic group containing a fluorine atom, a chain-like alkyl group, or a chain-like alkenyl group.

In General Formula (d2-2), Rd⁴ is preferably an alkyl group, an alkoxy group, an alkenyl group, or a cyclic group, which may have a substituent.

In General Formula (d2-2), Yd¹ is preferably a carbonyl group, an ester bond, an amide bond, an alkylene group, or a combination thereof.

In General Formulae (d2-1) and (d2-2), m is an integer of 1 or more. M′^{m+} is an m-valent onium cation, and suitable examples thereof include a sulfonium cation and an iodonium cation.

As the component (D2), only one of the above-described components (d2-1) and (d2-2) or a combination of two or more kinds thereof may be used.

In a case where the resist composition contains the component (D2), the content of the component (D2) in the resist composition is preferably less than 0.5 to 35 parts by mass, more preferably in a range of 1 to 25 parts by mass, still more preferably in a range of 2 to 20 parts by mass, and particularly preferably in a range of 3 to 15 parts by mass, with respect to 100 parts by mass of the component (A).

In a case where the content of the component (D2) is equal to or larger than the preferred lower limit value, excellent lithography characteristics and an excellent resist pattern shape are easily obtained. On the other hand, in a case where it is equal to or smaller than the upper limit value thereof, balance with other components can be obtained, and thus various lithography characteristics are improved.

Method of producing component (D2):

The method for producing the components (d2-1) described above is not particularly limited, and the component (d1-1) can be produced by a conventionally known method.

Further, the method for producing the component (d2-2) is not particularly limited, and the component (d2-2) can be produced in the same manner as disclosed in United States Patent Application, Publication No. 2012-0149916.

<(Z) Component>

The resist composition in the present embodiment may further contain a polyether compound (hereinafter, also referred to as a “component (Z)”), in addition to the component (A) and the component (B). The component (Z) is not particularly limited as long as it is a polyether compound, and examples thereof include compounds having a partial structure represented by General Formula (z-1).

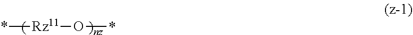

[In the formula, Rz¹¹ represents an alkylene group which may have a substituent. nz represents an integer of 1 or more.]

In General Formula (z-1), Rz¹¹ represents an alkylene group which may have a substituent. Although the number of carbon atoms in the alkylene group is not particularly limited, it is preferably in a range of 1 to 15, more preferably in a range of 2 to 8, and still more preferably in a range of 2 to 4. Although the substituent is not particularly limited, it is preferably an alkyl group (preferably having 1 to 10 carbon atoms).

In General Formula (z-1), * represents a bonding site.

The mass average molecular weight (Mw) of the compound represented by General Formula (z-1) (in terms of the polystyrene equivalent value determined by gel permeation chromatography (GPC)) is preferably in a range of 200 to 25,000, more preferably in a range of Mw of 250 to 24,000, and still more preferably in a range of Mw of 300 to 23,000.

The component (Z) is preferably a compound represented by General Formula (z-1-1).

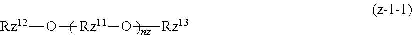

[In the formula, Rz¹¹ represents an alkylene group which may have a substituent. Rz¹² and Rz¹³ each independently represent a hydrogen atom or an alkyl group. nz represents an integer of 1 or more.]

The definition, specific examples, and preferred aspect of Rz¹¹ in General Formula (z-1-1) are the same as those of Rz¹¹ in General Formula (1).

In General Formula (z-1-1), Rz¹² and Rz¹³ each independently represent a hydrogen atom or an alkyl group. Although the number of carbon atoms in the alkyl group is not particularly limited, it is preferably in a range of 1 to 15. Among the above, Rz¹² and Rz¹³ re preferably a hydrogen atom.

The mass average molecular weight (Mw) of the compound represented by General Formula (z-1-1) (in terms of the polystyrene equivalent value determined by gel permeation chromatography (GPC)) is preferably in a range of 200 to 25,000, more preferably in a range of Mw of 250 to 24,000, and still more preferably in a range of Mw of 300 to 23,000.

Among the above, the component (Z) is more preferably at least one selected from the group consisting of a compound represented by General Formula (z-1-11), a compound represented by General Formula (z-1-12), and a compound represented by General Formula (z-1-13).

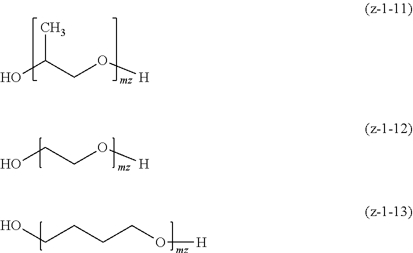

The mass average molecular weight (Mw) of (Z) (in terms of the polystyrene equivalent value determined by gel permeation chromatography (GPC)) is preferably in a range of 200 to 25,000, more preferably in a range of 250 to 24,000, and still more preferably in a range of 300 to 23,000.

In a case where the mass average molecular weight (Mw) of (Z) is equal to or larger than the lower limit value of the above-described preferred range, it is easy to form a pattern having good wet etching resistance. On the other hand, in a case where the mass average molecular weight (Mw) of (Z) is equal to or smaller than the upper limit value of the above-described preferred range, the solubility of the resist film in a developing solution tends to be good, and a pattern having good resolution is easily formed.

The component (BZ) contained in the resist composition according to the present embodiment may be used alone or in a combination of two or more kinds thereof.

In the resist composition according to the present embodiment, the content of component (Z) is preferably less than 50 parts by mass, more preferably 40 parts by mass or less, still more preferably 35 parts by mass or less, even still more preferably 30 parts by mass or less, and particularly preferably less than 20 parts by mass, with respect to 100 parts by mass of component (A1).

The lower limit value of the content of component (Z) is not particularly limited; however, it is preferably 0.1 parts by mass or more, more preferably 0.2 parts by mass or more, and still more preferably 0.5 parts by mass or more, with respect to 100 parts by mass of component (A1).

In a case where the content of the component (Z) is equal to or smaller than the upper limit value of the above-described preferred range, it is easy to form a pattern having better resolution.

In a case where the content of the component (Z) is equal to or larger than the lower limit value of the above-described preferred range, it is easy to form a pattern having better throughput at the time of etching.

«Component (E): at least one compound selected from group consisting of organic carboxylic acid, phosphorus oxo acid, and derivatives thereof»

For the intended purpose of preventing any deterioration in sensitivity and improving the resist pattern shape and the post-exposure temporal stability, the resist composition according to the present embodiment may contain, as an optional component, at least one compound (E) (hereinafter referred to as a component (E)) selected from the group consisting of an organic carboxylic acid, and a phosphorus oxo acid and a derivative thereof.

Examples of the suitable organic carboxylic acid include acetic acid, malonic acid, citric acid, malic acid, succinic acid, benzoic acid, and salicylic acid.

Examples of the phosphorus oxo acid include phosphoric acid, phosphonic acid, and phosphinic acid. Among these, phosphonic acid is particularly preferable.

Examples of the phosphorus oxo acid derivative include an ester obtained by substituting a hydrogen atom in the above-described oxo acid with a hydrocarbon group. Examples of the hydrocarbon group include an alkyl group having 1 to 5 carbon atoms and an aryl group having 6 to 15 carbon atoms.

Examples of the phosphoric acid derivative include a phosphoric acid ester such as di-n-butyl phosphate or diphenyl phosphate.

Examples of the phosphonic acid derivative include phosphonic acid esters such as dimethyl phosphonate, di-n-butyl phosphonate, phenylphosphonic acid, diphenyl phosphonate, and dibenzyl phosphonate.

Examples of the phosphinic acid derivative include phosphinic acid esters and phenylphosphinic acid.

In the resist composition according to the present embodiment, the component (E) may be used alone or in a combination of two or more kinds thereof.

In a case where the resist composition contains the component (E), the content of the component (E) is generally used in a range of 0.01 to 5 parts by mass with respect to 100 parts by mass of the component (A).

«Component (S): organic solvent component»

The resist composition according to the present embodiment may be produced by dissolving the resist materials in an organic solvent component (hereinafter, referred to as a “component (S)”).

The component (S) may be any organic solvent which can dissolve each of the components to be used to obtain a homogeneous solution, and any organic solvent can be appropriately selected from solvents for a chemical amplification-type resist composition, which are known in the related art, and then used.

Examples of the component (S) include lactones such as γ-butyrolactone; ketones such as acetone, methyl ethyl ketone, cyclohexanone, methyl-n-pentyl ketone, methyl isopentyl ketone, and 2-heptanone; polyhydric alcohols, such as ethylene glycol, diethylene glycol, propylene glycol and dipropylene glycol; compounds having an ester bond, such as ethylene glycol monoacetate, diethylene glycol monoacetate, propylene glycol monoacetate, and dipropylene glycol monoacetate; derivatives of polyhydric alcohols such as compounds having an ether bond, such as monoalkyl ethers (such as monomethyl ether, monoethyl ether, monopropyl ether, and monobutyl ether) of the above-described polyhydric alcohols or the above-described compounds having an ester bond, and monophenyl ethers [among these, propylene glycol monomethyl ether acetate (PGMEA) and propylene glycol monomethyl ether (PGME) are preferable]; cyclic ethers such as dioxane; esters such as methyl lactate, ethyl lactate (EL), methyl acetate, ethyl acetate, butyl acetate, methyl pyruvate, ethyl pyruvate, methyl methoxypropionate, and ethyl ethoxypropionate; aromatic organic solvents such as anisole, ethyl benzyl ether, cresyl methyl ether, diphenyl ether, dibenzyl ether, phenetole, butyl phenyl ether, ethyl benzene, diethyl benzene, pentyl benzene, isopropyl benzene, toluene, xylene, cymene and mesitylene; and dimethylsulfoxide (DMSO).

In the resist composition according to the present embodiment, the component (S) may be used alone or as a mixed solvent of two or more kinds thereof.

Among these, PGMEA, PGME, γ-butyrolactone, EL, or cyclohexanone is preferable.

Further, a mixed solvent obtained by mixing PGMEA with a polar solvent is also preferable. The blending ratio (mass ratio) of the mixed solvent can be appropriately determined, taking into consideration the compatibility of the PGMEA with the polar solvent; however, it is preferably in a range of 1:9 to 9:1 and more preferably in a range of 2:8 to 8:2.

More specifically, in a case where EL or cyclohexanone is blended as the polar solvent, the PGMEA:EL or cyclohexanone mass ratio is preferably in a range of 1:9 to 9:1 and more preferably in a range of 2:8 to 8:2. Alternatively, in a case where PGME is blended as the polar solvent, the PGMEA:PGME mass ratio is preferably in a range of 1:9 to 9:1, more preferably in a range of 2:8 to 8:2, and still more preferably in a range of 3:7 to 7:3. Furthermore, a mixed solvent of PGMEA, PGME, and cyclohexanone is also preferable.

Further, the component (S) is also preferably a mixed solvent of at least one selected from PGMEA and EL and γ-butyrolactone. In this case, as the mixing ratio, the mass ratio of the former to the latter is preferably in a range of 70:30 to 95:5.

The amount of the component (S) to be used is not particularly limited and is appropriately set, depending on a thickness of a film to be coated, to a concentration at which the component (S) can be applied onto a substrate or the like. In general, the component (S) is used such that the solid content concentration of the resist composition is preferably 20% by mass or more and more preferably in a range of 20% to 50% by mass.

As desired, other miscible additives can also be added to the resist composition according to the present embodiment. The resist composition may appropriately contain miscible additives such as an additive resin for improving the performance of the resist film, an ionic or non-ionic fluorine-based and/or silicon-based surfactant, a dissolution inhibitor, a plasticizer, a stabilizer, a colorant, a halation prevention agent, and a dye.

After dissolving the resist material in the component (S), the resist composition according to the present embodiment may be subjected to the removal of impurities and the like by using a porous polyimide membrane, a porous polyamide-imide membrane, or the like. For example, the resist composition may be filtered using a filter made of a porous polyimide membrane, a filter made of a porous polyamide-imide membrane, or a filter made of a porous polyimide membrane and a porous polyamide-imide membrane. Examples of the porous polyimide membrane and the porous polyamide-imide membrane include those described in Japanese Unexamined Patent Application, First Publication No. 2016-155121.

The resist composition according to the present embodiment contains the resin component (A1) having the constitutional unit (a10) represented by General Formula (a10-1) and the compound (B0) represented by General Formula (b0-1).

In the resist composition according to the present embodiment, the proportion of the constitutional unit (a10) in the component (A1) is relatively small, that is, more than 5% by mole and less than 45% by mole with respect to the total (100% by mole) of all constitutional units constituting the component (A1), and thus the Ohnishi parameter of the component (A1) can be increased.

Here, the Ohnishi parameter is represented by the following expression.

Ohnishi parameter=Nₜₒₜₐₗ/(N_{carbon}−N_{oxygen})

[In the expression, Nₜₒₜₐₗ is the total number of atoms in the molecule, N_{carbon} is the number of carbon atoms in the molecule, and N_{oxygen} is the number of oxygen atoms in the molecule.]

Since the Ohnishi parameter is proportional to the etching rate, it is meant that the larger the Ohnishi parameter is, the better the throughput at the time of etching is.

On the other hand, in the component (B0), a substituent R^{b1} is introduced at the terminal of the sulfonyloxy group that is bonded to N. Therefore, the component (B0) has a short diffusion length of the acid generated upon exposure, and the acid hardly diffuses into unexposed portions.

Combined with the above effects, it is presumed that the resist composition according to the present embodiment has good throughput at the time of etching and makes it possible to form a resist pattern having good CDU.

(Method for Forming Resist Pattern)

A second aspect according to the present invention is a method for forming a resist pattern, including a step (i) of forming a resist film on a support using the resist composition according to the first aspect described above; a step (ii) of exposing the resist film to light; and a step (iii) of developing the exposed resist film to form a resist pattern.

Examples of one embodiment of such a method for forming a resist pattern include a method for forming a resist pattern carried out as described below.

Step (i):

First, the resist composition of the above-described embodiment is applied onto a support with a spinner or the like, and a baking (post-apply baking (PAB)) treatment is carried out, for example, at a temperature condition in a range of 80° C. to 160° C. for 40 to 200 seconds, preferably for 60 to 150 seconds to form a resist film.

Step (ii):

Next, using a light exposure apparatus, for example, a KrF exposure apparatus or the like, the resist film is subjected to selective light exposure by light exposure through a mask (a mask pattern) having a predetermined pattern formed thereon, and then a baking treatment (post-exposure baking (PEB)) is carried out, for example, under a temperature condition of 80° C. to 150° C. for 40 to 150 seconds and preferably 60 to 120 seconds.

Step (iii):

Next, the resist film is subjected to a developing treatment. The developing treatment is carried out using an alkali developing solution in a case of an alkali developing process, and a developing solution containing an organic solvent (organic developing solution) in a case of a solvent developing process.

After the developing treatment, it is preferable to carry out a rinse treatment. As the rinse treatment, water rinsing using pure water is preferable in a case of an alkali developing process, and rinsing using a rinse liquid containing an organic solvent is preferable in a case of a solvent developing process.

In a case of a solvent developing process, after the developing treatment or the rinse treatment, the developing solution or the rinse liquid remaining on the pattern may be removed by a treatment using a supercritical fluid.

After the developing treatment or the rinse treatment, drying is conducted. As desired, a baking treatment (post-baking) may be carried out following the developing treatment. The baking treatment (post-baking) here is carried out, for example, at a temperature of 80° C. or higher and preferably at a temperature condition of 90° C. to 120° C. for 10 to 120 seconds and preferably 300 to 90 seconds.

In this manner, a resist pattern can be formed.

The support is not specifically limited and a conventionally known support in the related art can be used. For example, substrates for electronic components, and such substrates having a predetermined wiring pattern formed thereon can be used. Specific examples thereof include a silicon wafer, a substrate made of a metal such as copper, chromium, iron, or aluminum; and a glass substrate. Suitable examples of the material for a wiring pattern include copper, aluminum, nickel, and gold.

Further, the support may be such a substrate as described above, on which a film of an inorganic and/or organic film is provided. Examples of the inorganic film include an inorganic antireflection film (an inorganic BARC). Examples of the organic film include an organic antireflection film (organic BARC) and an organic film such as a lower-layer organic film used in a multilayer resist method.

Here, the multilayer resist method is a method in which at least one layer of an organic film (lower-layer organic film) and at least one layer of a resist film (upper-layer resist film) are provided on a substrate, and a resist pattern formed on the upper-layer resist film is used as a mask to conduct patterning of the lower-layer organic film. This method is considered as being capable of forming a pattern with a high aspect ratio. More specifically, in the multilayer resist method, a desired thickness can be ensured by the lower-layer organic film, and as a result, the thickness of the resist film can be reduced, and an extremely fine pattern with a high aspect ratio can be formed.

The multilayer resist method is classified into a method in which a double-layer structure consisting of an upper-layer resist film and a lower-layer organic film is formed (double-layer resist method), and a method in which a multilayer structure having three or more layers consisting of an upper-layer resist film, a lower-layer organic film and one or more intermediate layers (thin metal film or the like) provided between the upper-layer resist film and the lower-layer organic film (triple-layer resist method).

The method for forming a resist pattern according to the embodiment is a method useful at the time of being carried out by forming a thick resist film. Even in a case where the film thickness of the resist film formed in the step (i) is, for example, in a range of 1 to 20 μm, preferably 3 μm or more, more preferably 3.5 μm or more, and still more preferably 5 prn or more, it is possible to stably form a resist pattern is in a good shape.

The wavelength to be used for exposure is not particularly limited and the exposure can be carried out using an ultraviolet ray such as a g-line or an i-line, ArF excimer laser light, KrF excimer laser light, F₂ excimer laser light, an extreme ultraviolet ray (EUV), a vacuum ultraviolet ray (VUV), an electron beam (EB), or radiation such as an X-ray or a soft X-ray.

The resist composition according to the first aspect described above is highly useful for ultraviolet rays such as a g-line and an i-line, KrF excimer laser light, ArF excimer laser light, EB, or EUV, more highly useful for ultraviolet rays such as a g-line and an i-line, KrF excimer laser light, and ArF excimer laser light, and particularly useful for ultraviolet rays such as a g-line and an i-line, and KrF excimer laser light. The method for forming a resist pattern according to the second aspect is a particularly suitable method in a case where the resist film is irradiated with an ultraviolet ray such as a g-line or an i-line, or KrF excimer laser light in the step (ii).

The exposure method for a resist film may be a general exposure (dry exposure) carried out in air or an inert gas such as nitrogen, or liquid immersion lithography.

The liquid immersion lithography is an exposure method in which the region between the resist film and the lens at the lowermost position of the exposure apparatus is pre-filled with a solvent (liquid immersion medium) that has a larger refractive index than the refractive index of air, and the exposure (liquid immersion exposure) is carried out in this state.

The liquid immersion medium is preferably a solvent that exhibits a refractive index larger than the refractive index of air but smaller than the refractive index of the resist film to be exposed. The refractive index of the solvent is not particularly limited as long as it satisfies the above-described requirements.

Examples of the solvent which exhibits a refractive index that is larger than the refractive index of air but smaller than the refractive index of the resist film include water, fluorine-based inert liquids, silicon-based solvents, and hydrocarbon-based solvents.

As the liquid immersion medium, water is preferable in terms of cost, safety, environment, and versatility.

Examples of the alkali developing solution used for a developing treatment in an alkali developing process include a 0.1% to 10% by mass aqueous solution of tetramethylammonium hydroxide (TMAH).

As the organic solvent contained in the organic developing solution, which is used for a developing treatment in a solvent developing process, any organic solvent capable of dissolving the component (A) (the component (A) prior to exposure) may be appropriately selected from the conventionally known organic solvents. Specific examples of the organic solvent include polar solvents such as a ketone-based solvent, an ester-based solvent, an alcohol-based solvent, a nitrile-based solvent, an amide-based solvent, and an ether-based solvent, and hydrocarbon-based solvents.

The ketone-based solvent is an organic solvent containing C—C(═O)—C in the structure thereof. The ester-based solvent is an organic solvent containing C—C(═O)—O—C in the structure thereof. The alcohol-based solvent is an organic solvent containing an alcoholic hydroxyl group in the structure thereof. The “alcoholic hydroxyl group” indicates a hydroxyl group bonded to a carbon atom of an aliphatic hydrocarbon group. The nitrile-based solvent is an organic solvent containing a nitrile group in the structure thereof. The amide-based solvent is an organic solvent containing an amide group in the structure thereof. The ether-based solvent is an organic solvent containing C—O—C in the structure thereof.

Some organic solvents have a plurality of the functional groups which characterize the above-described solvents in the structure thereof. In such a case, the organic solvent can be classified as any type of solvent having a functional group. For example, diethylene glycol monomethyl ether can be classified as an alcohol-based solvent or an ether-based solvent.

The hydrocarbon-based solvent consists of a hydrocarbon which may be halogenated, and it is a hydrocarbon-based solvent that does not have any substituent other than the halogen atom. Examples of the halogen atom include a fluorine atom, a chlorine atom, a bromine atom, and an iodine atom, and a fluorine atom is preferable.

Among the above, the organic solvent contained in the organic developing solution is preferably a polar solvent and more preferably a ketone-based solvent, an ester-based solvent, or a nitrile-based solvent.

Examples of the ketone-based solvent include 1-octanone, 2-octanone, 1-nonanone, 2-nonanone, acetone, 4-heptanone, 1-hexanone, 2-hexanone, diisobutyl ketone, cyclohexanone, methyl cyclohexanone, phenyl acetone, methyl ethyl ketone, methyl isobutyl ketone, acetyl acetone, acetonyl acetone, ionone, diacetonyl alcohol, acetylcarbinol, acetophenone, methyl naphthyl ketone, isophorone, propylene carbonate, γ-butyrolactone and methylamyl ketone (2-heptanone). Among these examples, the ketone-based solvent is preferably methylamyl ketone (2-heptanone).

Examples of the ester-based solvent include methyl acetate, butyl acetate, ethyl acetate, isopropyl acetate, amyl acetate, isoamyl acetate, ethyl methoxyacetate, ethyl ethoxyacetate, propylene glycol monomethyl ether acetate, ethylene glycol monoethyl ether acetate, ethylene glycol monopropyl ether acetate, ethylene glycol monobutyl ether acetate, ethylene glycol monophenyl ether acetate, diethylene glycol monomethyl ether acetate, diethylene glycol monopropyl ether acetate, diethylene glycol monoethyl ether acetate, diethylene glycol monophenyl ether acetate, diethylene glycol monobutyl ether acetate, diethylene glycol monoethyl ether acetate, 2-methoxybutyl acetate, 3-methoxybutyl acetate, 4-methoxybutyl acetate, 3-methyl-3-methoxybutyl acetate, 3-ethyl-3-methoxybutyl acetate, propylene glycol monomethyl ether acetate, propylene glycol monoethyl ether acetate, propylene glycol monopropyl ether acetate, 2-ethoxybutyl acetate, 4-ethoxybutyl acetate, 4-propoxybutyl acetate, 2-methoxypentyl acetate, 3-methoxypentyl acetate, 4-methoxypentyl acetate, 2-methyl-3-methoxypentyl acetate, 3-methyl-3-methoxypentyl acetate, 3-methyl-4-methoxypentyl acetate, 4-methyl-4-methoxypentyl acetate, propylene glycol diacetate, methyl formate, ethyl formate, butyl formate, propyl formate, ethyl lactate, butyl lactate, propyl lactate, ethyl carbonate, propyl carbonate, butyl carbonate, methyl pyruvate, ethyl pyruvate, propyl pyruvate, butyl pyruvate, methyl acetoacetate, ethyl acetoacetate, methyl propionate, ethyl propionate, propyl propionate, isopropyl propionate, methyl 2-hydroxypropionate, ethyl 2-hydroxypropionate, methyl-3-methoxypropionate, ethyl-3-methoxypropionate, ethyl-3-ethoxypropionate, and propyl-3-methoxypropionate. Among these, the ester-based solvent is preferably butyl acetate.

Examples of the nitrile-based solvent include acetonitrile, propionitrile, valeronitrile, and butyronitrile.

As desired, the organic developing solution may have a conventionally known additive blended. Examples of the additive include surfactants. The surfactant is not particularly limited, and for example, an ionic or non-ionic fluorine-based and/or a silicon-based surfactant can be used. The surfactant is preferably a non-ionic surfactant and more preferably a non-ionic fluorine-based surfactant or a non-ionic silicon-based surfactant.

In a case where a surfactant is blended, the blending amount thereof is typically in a range of 0.001% to 5% by mass, preferably in a range of 0.005% to 2% by mass, and more preferably in a range of 0.01% to 0.5% by mass with respect to the total amount of the organic developing solution.

The developing treatment can be carried out by a conventionally known developing method. Examples thereof include a method in which the support is immersed in the developing solution for a predetermined period (a dip method), a method in which the developing solution is cast upon the surface of the support by surface tension and maintained for a predetermined period (a puddle method), a method in which the developing solution is sprayed onto the surface of the support (spray method), and a method in which a developing solution is continuously ejected from a developing solution ejecting nozzle and applied onto a support which is scanned at a constant rate while being rotated at a constant rate (dynamic dispense method).

As the organic solvent contained in the rinse liquid used in the rinse treatment after the developing treatment in a case of a solvent developing process, an organic solvent hardly dissolving the resist pattern can be appropriately selected and used, among the organic solvents mentioned as organic solvents that are used for the organic developing solution. In general, at least one solvent selected from a hydrocarbon-based solvent, a ketone-based solvent, an ester-based solvent, an alcohol-based solvent, an amide-based solvent, and an ether-based solvent is used. Among these, at least one selected from a hydrocarbon-based solvent, a ketone-based solvent, an ester-based solvent, an alcohol-based solvent, and an amide-based solvent is preferable, at least one selected from an alcohol-based solvent and an ester-based solvent is more preferable, and an alcohol-based solvent is particularly preferable.

The alcohol-based solvent used for the rinse liquid is preferably a monohydric alcohol of 6 to 8 carbon atoms, and the monohydric alcohol may be linear, branched, or cyclic. Specific examples thereof include 1-hexanol, 1-heptanol, 1-octanol, 2-hexanol, 2-heptanol, 2-octanol, 3-hexanol, 3-heptanol, 3-octanol, 4-octanol, and benzyl alcohol. Among these, 1-hexanol, 2-heptanol, and 2-hexanol are preferable, and 1-hexanol and 2-hexanol are more preferable.

As the organic solvent, one kind of solvent may be used alone, or two or more kinds of solvents may be used in combination. Further, an organic solvent other than the above-described examples or water may be mixed thereto. However, in consideration of the development characteristics, the blending amount of water in the rinse liquid is preferably 30% by mass or less, more preferably 10% by mass or less, still more preferably 5% by mass or less, and particularly preferably 3% by mass or less with respect to the total amount of the rinse liquid.

A conventionally known additive can be blended with the rinse liquid as necessary. Examples of the additive include surfactants. Examples of the surfactant include the same ones as those described above, the surfactant is preferably a non-ionic surfactant and more preferably a non-ionic fluorine-based surfactant or a non-ionic silicon-based surfactant.

In a case where a surfactant is blended, the blending amount thereof is typically in a range of 0.001% to 5% by mass, preferably in a range of 0.005% to 2% by mass, and more preferably in a range of 0.01% to 0.5% by mass with respect to the total amount of the rinse liquid.

The rinse treatment using a rinse liquid (washing treatment) can be carried out by a conventionally known rinse method. Examples of the rinse treatment method include a method in which the rinse liquid is continuously ejected and applied onto the support while rotating it at a constant rate (rotational coating method), a method in which the support is immersed in the rinse liquid for a predetermined period (dip method), and a method in which the rinse liquid is sprayed onto the surface of the support (spray method).

Since the resist composition according to the first aspect described above is used in the method for forming a resist pattern according to the present embodiment described above, it is presumed that a resist pattern having good throughput at the time of etching and good CDU can be obtained.

### EXAMPLES

Hereinafter, the present invention will be described in more detail based on Examples, but the present invention is not limited to these Examples.

<Production of Polymeric Compound>

Each of polymeric compounds (A-1) to (A-7), (A-11), and (A-12), which were used in present Examples, was obtained by carrying out radical polymerization using monomers from which constitutional units constituting each of the polymeric compounds are derived, at a predetermined molar ratio.

The weight average molecular weight (Mw) and the molecular weight polydispersity (Mw/Mn) of each of the obtained polymeric compounds were determined by GPC measurement (in terms of the standard polystyrene equivalent value).

In addition, the copolymerization composition ratio (the ratio (molar ratio) of each constitutional unit in the structural formula) of each of the obtained polymeric compounds was determined from the carbon 13 nuclear magnetic resonance spectrum (600 MHz_¹³C-NMR).

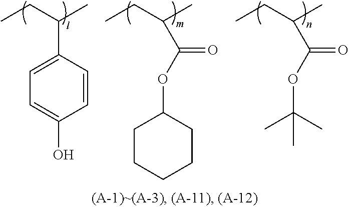

Polymeric compound (A-1): Weight average molecular weight (Mw): 10,000, molecular weight polydispersity (Mw/Mn): 1.24, l/m/n=25/50/25.

Polymeric compound (A-2): Weight average molecular weight (Mw): 10,000, molecular weight polydispersity (Mw/Mn): 1.20, l/m/n=10/65/25.

Polymeric compound (A-3): Weight average molecular weight (Mw): 10,000, molecular weight polydispersity (Mw/Mn): 1.22, l/m/n=40/35/25.

Polymeric compound (A-11): Weight average molecular weight (Mw): 10,000, molecular weight polydispersity (Mw/Mn): 1.22, l/m/n=5/70/25.

Polymeric compound (A-12): Weight average molecular weight (Mw): 10,000, molecular weight polydispersity (Mw/Mn): 1.22, l/m/n=45/30/25.

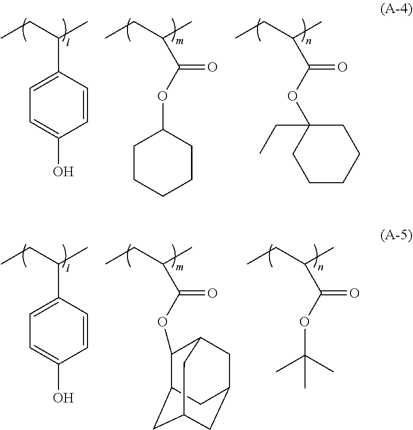

Polymeric compound (A-4): Weight average molecular weight (Mw): 10,000, molecular weight polydispersity (Mw/Mn): 1.35, l/m/n=25/50/25.

Polymeric compound (A-5): Weight average molecular weight (Mw): 10,000, molecular weight polydispersity (Mw/Mn): 1.21, lini/n=25/50/25.

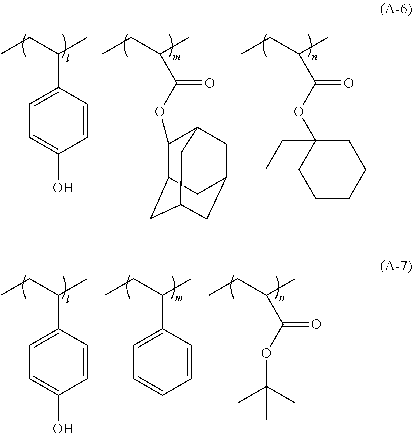

Polymeric compound (A-6): Weight average molecular weight (Mw): 10,000, molecular weight polydispersity (Mw/Mn): 1.35, l/m/n=25/50/25.

Polymeric compound (A-7): Weight average molecular weight (Mw): 10,000, molecular weight polydispersity (Mw/Mn): 1.46, l/m/n=25/15/60.

<Preparation of Resist Composition>

### Examples 1 to 14, Comparative Examples 1 to 4

Each of the components shown in Tables 1 to 3 was mixed and dissolved to prepare a resist composition of each Example (solid content concentration: 35%).

TABLE 1

| | Component | Component | Component | Component |
|---|---|---|---|---|
| | (A) | (B) | (D) | (S) |
| Example 1 | (A)-1 | (B)-1 | (D)-1 | (S)-1 |
| | [100] | [0.5] | [0.05] | [186] |
| Example 2 | (A)-1 | (B)-2 | (D)-1 | (S)-1 |
| | [100] | [0.5] | [0.05] | [186] |
| Example 3 | (A)-1 | (B)-3 | (D)-1 | (S)-1 |
| | [100] | [0.5] | [0.05] | [186] |
| Example 4 | (A)-1 | (B)-4 | (D)-1 | (S)-1 |
| | [100] | [0.5] | [0.05] | [186] |
| Example 5 | (A)-2 | (B)-1 | (D)-1 | (S)-1 |
| | [100] | [0.5] | [0.05] | [186] |
| Example 6 | (A)-3 | (B)-1 | (D)-1 | (S)-1 |
| | [100] | [0.5] | [0.05] | [186] |
| Example 7 | (A)-4 | (B)-1 | (D)-1 | (S)-1 |
| | [100] | [0.5] | [0.05] | [186] |
| Example 8 | (A)-5 | (B)-1 | (D)-1 | (S)-1 |
| | [100] | [0.5] | [0.05] | [186] |
| Example 9 | (A)-6 | (B)-1 | (D)-1 | (S)-1 |
| | [100] | [0.5] | [0.05] | [186] |
| Example 10 | (A)-7 | (B)-1 | (D)-1 | (S)-1 |
| | [100] | [0.5] | [0.05] | [186] |

TABLE 2

| | Component | Component | Component | Component | Component |
|---|---|---|---|---|---|
| | (A) | (B) | (D) | (Z) | (S) |
| Example 11 | (A)-1 | (B)-1 | (D)-1 | (Z)-1 | (S)-1 |
| | [100] | [0.5] | [0.05] | [5.00] | [196] |
| Example 12 | (A)-1 | (B)-2 | (D)-1 | (Z)-1 | (S)-1 |
| | [100] | [0.5] | [0.05] | [5.00] | [196] |
| Example 13 | (A)-1 | (B)-3 | (D)-1 | (Z)-1 | (S)-1 |
| | [100] | [0.5] | [0.05] | [5.00] | [196] |
| Example 14 | (A)-1 | (B)-4 | (D)-1 | (Z)-1 | (S)-1 |
| | [100] | [0.5] | [0.05] | [5.00] | [196] |

TABLE 3

| | Component | Component | Component | Component |
|---|---|---|---|---|
| | (A) | (B) | (D) | (S) |
| Comparative | (A)-11 | (B)-1 | (D)-1 | (S)-1 |
| Example 1 | [100] | [0.5] | [0.05] | [186] |
| Comparative | (A)-12 | (B)-1 | (D)-1 | (S)-1 |
| Example 2 | [100] | [0.5] | [0.05] | [186] |
| Comparative | (A)-1 | (B)-11 | (D)-1 | (S)-1 |
| Example 3 | [100] | [0.5] | [0.05] | [186] |
| Comparative | (A)-12 | (B)-11 | (D)-1 | (S)-1 |
| Example 3 | [100] | [0.5] | [0.05] | [186] |

In Tables 1 to 3, each abbreviation has the following meaning. The numerical values in the brackets are blending amounts (parts by mass).

(A)-1 to (A)-7, (A)-11, and (A)-12: The above-described polymeric compounds (A-1) to (A-7), (A-11), and (A-12).

(B)-1 to (B)-4 and (B)-11: Acid generators consisting of compounds each represented by Chemical Formulae (B-1) to (B-4) and (B-11).

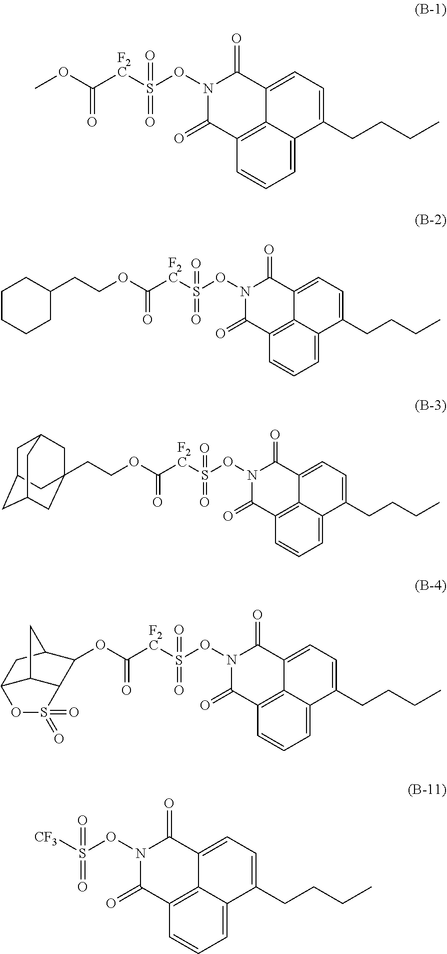 [SMILES: CCCCc1ccc2c3c(cccc13)C(=O)N(OS(=O)(=O)C(F)(F)C(=O)OC)C2=O ; CCCCc1ccc2c3c(cccc13)C(=O)N(OS(=O)(=O)C(F)(F)C(=O)OCCC1CCCCC1)C2=O ; CCCCc1ccc2c3c(cccc13)C(=O)N(OS(=O)(=O)C(F)(F)C(=O)OCCC13CC4CC(CC(C4)C1)C3)C2=O ; CCCCc1ccc2c3c(cccc13)C(=O)N(OS(=O)(=O)C(F)(F)C(=O)OC1C3CC4OS(=O)(=O)C1C4C3)C2=O ; CCCCc1ccc2c3c(cccc13)C(=O)N(OS(=O)(=O)C(F)(F)F)C2=O]

(D)-1: A nitrogen-containing organic compound consisting of a compound represented by Chemical Formula (D-1).

(Z)-1: Polypropylene glycol having a mass average molecular weight (Mw) of 1,000, represented by Chemical Formula (Z-1).

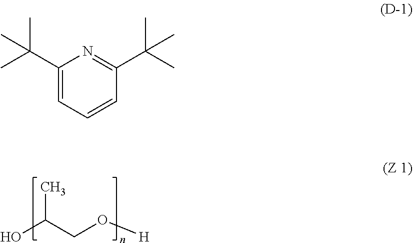

(S)-1: A mixed solvent of propylene glycol monomethyl ether acetate/propylene glycol monomethyl ether=50/50 (in terms of mass ratio)

<Method for Forming Resist Pattern>

Step (i):

The resist composition of each Example was applied onto a silicon substrate which had been subjected to a hexamethyldisilazane (HMDS) treatment using a spinner, the coated wafer was subjected to a post-apply baking (PAB) treatment on a hot plate at 130° C. for 90 seconds so that the coated wafer was dried to form a resist film having a film thickness of 9 μm.

Step (ii):

Next, the resist film was selectively irradiated with a high-pressure mercury lamp (365 nm) by an i-line stepper (reduction projection exposure apparatus: NSR-2205114E (manufactured by Nikon Corporation; numerical aperture (NA)=0.54, σ=0.59)) through a mask pattern.

Thereafter, a post-exposure baking (PEB) treatment was performed on the resist film at 110° C. for 90 seconds.

Step (iii):

Subsequently, alkali development was performed under the conditions of 23° C. and 60 seconds using a 2.38% by mass tetramethylammonium hydroxide (TMAH) aqueous solution “NMD-3” (product name, manufactured by TOKYO OHKA KOGYO CO., LTD.) as a developing solution.

Then, a baking treatment (post-baking) was carried out at 100° C. for 60 seconds.

As a result, an isolated line pattern (hereinafter, referred to as an “IS pattern”) having a space width of 4 μm and a pitch of 24 μm was formed.

[Evaluation of Critical Dimension Uniformity (CDU) of Pattern Size]

400 holes in the CH pattern were observed from above the CH pattern with a critical dimension scanning electron microscope (SEM, acceleration voltage: 500 V, product name: CG5000, manufactured by Hitachi High-Tech Corporation), and the hole diameter (nm) of each hole was measured. Then, the triple value (3σ) of the standard deviation (a) calculated from the measurement result was determined. The obtained results are shown in Tables 4 to 6 as “CDU [nm]”.

The lower the value of 3σ determined as described above is, the higher the critical dimension (CD) uniformity of the plurality of holes formed in the resist film is.

<Evaluation of Dry Etching>

A resist film formed according to the same operation as the step (i) of <Method for forming resist pattern> described above was subjected to dry etching using an etching apparatus manufactured by Tokyo Ohka Kogyo Co., Ltd. under the following conditions.

Conditions:

Kind and flow rate of etching gas; Mixed gas of O₂/CF₄=87.5/12.5

Pressure; 40 Pa

Output; 600 w

Time; 120 seconds

The resist film thickness was measured before and after etching, and the etching rate was calculated from the reduced film thickness.

[Reduced film thickness (μm)]=[film thickness before etching (μm)]−[film thickness after etching (μm)]

[Etching rate (μm/sec)]=[reduced film thickness (m)]/[etching time (120 sec)]

The etching rate of the resist film formed using the resist composition of Comparative Example 2 was set to 100%, and the other examples were set as relative values. The results are shown in Tables 4 to 6 as “E.R. [%]”.

TABLE 4

| | E.R. | CDU |
|---|---|---|
| | [%] | [nm] |
| Example 1 | 120 | 80 |
| Example 2 | 120 | 70 |
| Example 3 | 120 | 60 |
| Example 4 | 120 | 50 |
| Example 5 | 140 | 80 |
| Example 6 | 110 | 65 |
| Example 7 | 120 | 70 |
| Example 8 | 115 | 70 |
| Example 9 | 115 | 60 |
| Example 10 | 120 | 80 |

TABLE 5

| | E.R. | CDU |
|---|---|---|
| | [%] | [nm] |
| Example 11 | 150 | 80 |
| Example 12 | 150 | 70 |
| Example 13 | 150 | 60 |
| Example 14 | 150 | 50 |

TABLE 6

| | E.R. | CDU |
|---|---|---|
| | [%] | [nm] |
| Comparative | 150 | 100 |
| Example 1 | | |
| Comparative | 100 | 60 |
| Example 2 | | |
| Comparative | 120 | 100 |
| Example 3 | | |
| Comparative | 100 | 80 |
| Example 4 | | |

From the results shown in Tables 4 to 6, it has been confirmed that the resist patterns formed using the resist compositions of Examples 1 to 14 have good CDU and good throughput at the time of etching.

While preferred Examples according to the present invention have been described above; however, the present invention is not limited to these Examples. Additions, omissions, substitutions, and other modifications can be made without departing from the gist or scope of the present invention. Accordingly, the present invention is not to be considered as being limited by the foregoing description and is only limited by the scope of the appended claims.

What is claimed is:

1. A resist composition that generates acid upon exposure and exhibits changed solubility in a developing solution under action of acid, the resist composition comprising:
a resin component (A1) exhibiting changed solubility in a developing solution under action of acid; and
an acid generator component (B) generating an acid upon exposure,
wherein the resin component (A1) has a constitutional unit (a10) represented by General Formula (a10-1),
the acid generator component (B) contains a compound (B0) represented by General Formula (b0-1), and
a proportion of the constitutional unit (a10) in the resin component (A1) is more than 5% by mole and less than 45% by mole with respect to a total (100% by mole) of all constitutional units constituting the resin component (A1), 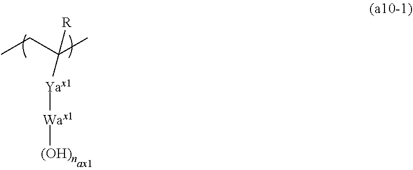
wherein R represents a hydrogen atom, an alkyl group having 1 to 5 carbon atoms, or a halogenated alkyl group having 1 to 5 carbon atoms; Ya^{x1} represents a single bond or a divalent linking group; Wa^{x1} represents an aromatic hydrocarbon group which may have a substituent; and nₐₓ₁ represents an integer of 1 or more, 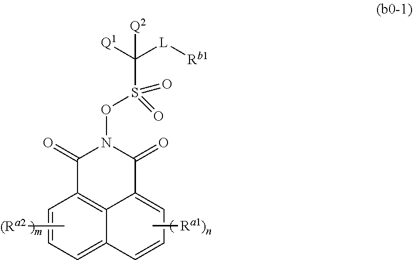
wherein R^{b1} represents a hydrocarbon group having 1 or more and 30 or less carbon atoms; when the hydrocarbon group as R^{b1} contains one or more methylene groups, at least part of the methylene groups may be substituted with a group selected from the group consisting of —O—, —S—, —CO—, —CO—O—, —SO—, —SO₂—, CR^{b4}R^{b5}, and NR^{b6}—; when the hydrocarbon group R^{b1} contains a hydrocarbon ring, at least one of the carbon atoms constituting the hydrocarbon ring may be substituted with a hetero atom selected from the group consisting of N, O, P, S, and Se, or an atomic group containing the hetero atom; R^{b4} and R^{b5} each independently represents a hydrogen atom or a halogen atom, at least one of R^{b4} and R^{b5} represents a halogen atom, and R^{b6} represents a hydrogen atom or a hydrocarbon group having 1 or more and 6 or less carbon atoms; n and m of (R^{a1})n and (R^{a2})m represent an integer in a range of 0 to 3, R^{a1} and R^{a2} each independently represents a hydrogen atom or an organic group; Q¹ and Q² each independently represents a fluorine atom or a perfluoroalkyl group having 1 or more and 6 or less carbon atoms; and L represents an ester bond.

2. The resist composition according to claim 1, wherein a solid content concentration is 20% by mass or more.

3. The resist composition according to claim 1, further comprising a polyether compound (Z).

4. A method for forming a resist pattern, comprising:
forming a resist film on a support using the resist composition according to claim 1;
exposing the resist film; and
developing the exposed resist film to form a resist pattern.

5. The method for forming a resist pattern according to claim 4, wherein a film thickness of the resist film is 5 μm or more.
